(19) United States
(12) Patent Application Publication
(10) Pub. No.: US 2026/0282849 A1
(43) Pub. Date: Sep. 17, 2026

(54) SYSTEM AND METHOD FOR ADAPTIVE SEMICONDUCTOR PROCESS CONTROL

(71) Applicant: QOMPLX LLC, Reston, VA (US)

(72) Inventors: Jason Crabtree, Vienna, VA (US); Richard Kelley, Woodbridge, VA (US); Jason Hopper, Halifax (CA); David Park, Fairfax, VA (US)

(21) Appl. No.: 19/078,225

(22) Filed: Mar. 12, 2025

(51) Int. Cl. H01L 21/66; G05B 13/02; G05B 13/04; H01L 21/67

(52) U.S. Cl. CPC H10P 74/277; G05B 13/0265; G05B 13/042; H10P 72/0604; H10P 72/0616; H10P 74/203

(57) ABSTRACT

A system and method for adaptive semiconductor process control integrates multi-modal sensor data, predictive modeling, and real-time optimization to dynamically manage semiconductor manufacturing processes. The system includes sensors collecting diverse process data, a processor that maintains a state model using particle-based estimation techniques, a knowledge graph for representing process relationships and economic factors, and a controller that adaptively adjusts manufacturing equipment. The processor generates topology-aware features from the state model by computing persistent homology at multiple scales and performing feature matching with confidence scoring. An upper confidence tree (UCT) optimization algorithm with super-exponential regret bounds dynamically adjusts exploration factors based on risk-weighted calculations. The system incorporates economic factors such as wafer value, energy costs, and maintenance costs while implementing just-in-context, just-in-time, and just-in-place measurement strategies. This enables comprehensive process monitoring and control while optimizing both technical performance and economic outcomes.

### CROSS-REFERENCE TO RELATED APPLICATIONS

Priority is claimed in the application data sheet to the following patents or patent applications, each of which is expressly incorporated herein by reference in its entirety:

None.

### BACKGROUND OF THE INVENTION

### Field of the Art

The present invention relates to the field of semiconductor manufacturing control systems, and more specifically to adaptive process control using AI-enhanced, in particular neuro-symbolic, architectures for real-time multi-modal optimization.

### Discussion of the State of the Art

Semiconductor manufacturing has advanced significantly in recent years, driven by the increasing demand for higher performance, smaller feature sizes, and more complex device architectures. These advancements, however, have introduced substantial challenges for control systems tasked with maintaining precision and efficiency in increasingly sophisticated processes. Current control systems used in semiconductor manufacturing primarily rely on static or semi-adaptive mechanisms for optimizing critical processes such as lithography, deposition, and etching. While these systems can address well-defined scenarios, they typically operate within fixed constraints, such as predefined field sizes and static process windows. This rigidity limits their ability to adapt dynamically to real-time variations in the manufacturing environment, resulting in significant trade-offs between throughput, process stability, and product quality. Additionally, as device architectures become more intricate, the inability of current systems to handle simultaneous multi-variable optimization amplifies production inefficiencies and defect risks.

Many existing systems continue to depend heavily on manual interventions or predefined rule sets for process optimization. While effective in simpler environments, these approaches fall short in coping with the increasing complexity of modern semiconductor processes. Variables such as thermal fluctuations, mechanical stresses, and overlay alignment now require highly precise and coordinated control strategies that are beyond the capabilities of traditional methods. Furthermore, the limited integration across sensor modalities—such as thermal, optical, and positional sensors—restricts the ability of these systems to provide holistic process monitoring and control. This lack of adaptability and comprehensive integration creates bottlenecks in achieving consistently high yield, minimizing defect rates, and addressing variability across manufacturing runs.

What is needed is an advanced semiconductor manufacturing control system that integrates multi-modal sensor data, leverages AI-enhanced architectures for real-time optimization, and dynamically adapts to process variations while maintaining high throughput and quality to comprehensively manage processes, predict outcomes, and optimize economic factors in modern semiconductor manufacturing.

### SUMMARY OF THE INVENTION

Accordingly, the inventor has conceived and reduced to practice a system and method for adaptive semiconductor process control that integrates multi-modal sensor data, predictive modeling, and real-time optimization to dynamically manage semiconductor manufacturing processes. The system comprises a plurality of sensors for collecting diverse process data, a processor configured to maintain a state model using particle-based estimation techniques, a knowledge graph for representing process relationships and economic factors, and a controller that adaptively adjusts manufacturing equipment based on control signals generated by an upper confidence tree (UCT) optimization algorithm.

According to a preferred embodiment, the system generates topology-aware features from the state model by computing persistent homology at multiple scales and performing feature matching with confidence scoring. This hierarchical approach enhances the system's ability to integrate and analyze diverse data sources in real-time.

According to another preferred embodiment, the UCT optimization algorithm dynamically adjusts exploration factors and tree width progression based on risk-weighted value calculations, enabling robust decision-making even under uncertain conditions.

According to an aspect of an embodiment, the knowledge graph supports advanced functionality, including vector similarity searches and graph traversal through hybrid retrieval strategies, to provide context-aware insights for process optimization. Additionally, the dynamic measurement strategy incorporates just-in-context, just-in-time, and just-in-place techniques to enhance process control by tailoring measurements to specific conditions in real-time.

According to another aspect of an embodiment, the economic factors integrated into the optimization algorithm include wafer value, energy costs, and maintenance costs, ensuring that the system not only optimizes process parameters but also aligns with operational cost constraints and market demands.

According to a further aspect of an embodiment, the multi-modal sensor data collected by the system includes thermal, positional, and optical measurements, enabling comprehensive monitoring and control of semiconductor manufacturing processes.

### BRIEF DESCRIPTION OF THE DRAWING FIGURES

FIG. 1 is a block diagram illustrating exemplary architecture of adaptive neurosymbolic semiconductor process control platform.

FIG. 2 is a block diagram illustrating exemplary architecture of data integration system.

FIG. 3 is a block diagram illustrating exemplary architecture of model management subsystem.

FIG. 4 is a block diagram illustrating exemplary architecture of process optimization subsystem.

FIG. 5 is a method diagram illustrating the process parameter adjustments of adaptive neurosymbolic semiconductor process control platform.

FIG. 6 is a method diagram illustrating the UCT optimization of adaptive neurosymbolic semiconductor process control platform.

FIG. 7 is a method diagram illustrating the multi-modal data integration of adaptive neurosymbolic semiconductor process control platform.

FIG. 8 is a method diagram illustrating the model management method of adaptive neurosymbolic semiconductor process control platform.

FIG. 9 is a method diagram illustrating the economic optimization method of adaptive neurosymbolic semiconductor process control platform.

FIG. 10 is a method diagram illustrating manufacturing integration method of adaptive neurosymbolic semiconductor process control platform.

FIG. 11 illustrates an exemplary computing environment on which an embodiment described herein may be implemented.

FIG. 12 is a block diagram illustrating exemplary architecture of the digital twin and virtual metrology framework, in an embodiment.

FIG. 13 is a block diagram illustrating exemplary architecture of an explainable artificial intelligence (XAI) subsystem for semiconductor manufacturing control, in an embodiment.

FIG. 14 is a block diagram illustrating exemplary architecture of an energy-aware sensor orchestration system for adaptive power management and contextual activation in semiconductor manufacturing, in an embodiment.

FIG. 15 is a block diagram illustrating exemplary architecture of an AI-driven composable chiplet store and automated EDA pipeline system designed to improve modularity, composability, and interoperability in semiconductor packaging, particularly for chiplet-based designs and advanced packaging applications, in an embodiment.

FIG. 16 is a block diagram illustrating exemplary architecture of an intelligent sensor orchestration subsystem designed for dynamic sensor management in semiconductor manufacturing environments, in an embodiment.

FIG. 17 is a block diagram illustrating exemplary architecture of a wafer-level smart tag system architecture designed for real-time identification, data capture, and lifecycle tracking within a semiconductor manufacturing environment, in an embodiment.

FIG. 18 is a block diagram illustrating exemplary architecture of a modular “app store” architecture designed for integrating third-party process control extensions into a semiconductor manufacturing platform, in an embodiment.

FIG. 19 is a block diagram illustrating exemplary architecture of an enhanced smart tag system architecture for semiconductor wafer tracking and process optimization, in an embodiment.

FIG. 20 is a block diagram illustrating exemplary architecture of a temporal dynamics and multi-model integration system for semiconductor process control, implementing an advanced architecture that combines multiple data streams, expert systems, and adaptive learning mechanisms, in an embodiment.

FIG. 21 is a block diagram illustrating exemplary architecture of a persistent homology optimization system for semiconductor manufacturing, implementing a multi-layered approach to topology-aware feature extraction and analysis, in an embodiment.

FIG. 22 is a block diagram illustrating exemplary architecture of a multi-fab federated coordination system for semiconductor manufacturing, implementing a distributed architecture that enables secure collaboration and process optimization across multiple fabrication facilities while maintaining local data sovereignty and operational independence, in an embodiment.

FIG. 23 is a method diagram illustrating the operational sequence of a digital twin and virtual metrology framework for semiconductor manufacturing control.

FIG. 24 is a method diagram illustrating the operational sequence of an explainable artificial intelligence (XAI) subsystem for semiconductor manufacturing control.

FIG. 25 is a method diagram illustrating the operational sequence of an energy-aware sensor orchestration system for adaptive power management and contextual activation in semiconductor manufacturing.

FIG. 26 is a method diagram illustrating the operational sequence of an AI-driven composable chiplet store and automated EDA pipeline system for semiconductor packaging applications.

FIG. 27 is a method diagram illustrating the operational sequence of an intelligent sensor orchestration subsystem for semiconductor manufacturing control.

FIG. 28 is a method diagram illustrating the operational sequence of a wafer-level smart tag system for semiconductor manufacturing control.

FIG. 29 is a method diagram illustrating the operational sequence of a modular app store architecture for integrating third-party process control extensions into semiconductor manufacturing platforms.

FIG. 30 is a method diagram illustrating the operational sequence of an enhanced smart tag system for semiconductor wafer tracking and process optimization.

FIG. 31 is a method diagram illustrating the operational sequence of a temporal dynamics and multi-model integration system for semiconductor process control.

FIG. 32 is a method diagram illustrating the operational sequence of a persistent homology optimization system for semiconductor manufacturing control.

FIG. 33 is a method diagram illustrating the operational sequence of a multi-fab federated coordination system for semiconductor manufacturing.

### DETAILED DESCRIPTION OF THE INVENTION

The inventor has conceived and reduced to practice an adaptive neurosymbolic semiconductor manufacturing control system designed to enhance the precision, efficiency, and adaptability of semiconductor fabrication processes at scale and fully utilize burgeoning AI-enabled semiconductor design, layout and engineering software systems. The system architecture comprises several key components working in concert to optimize manufacturing operations: a multi-modal sensor network, a central processor, a knowledge graph module, an optimization engine, and a real-time controller. Together, these components enable the system to dynamically respond to changing conditions, predict process outcomes, and make data-driven adjustments to ensure high throughput and product quality.

At the core of the system is a processor configured to manage and analyze data collected by a network of multi-modal sensors. These sensors include thermal, positional, optical, acoustic, electromagnetic, chemical, spectral, electrical, and environmental sensors, which together provide a comprehensive view of the manufacturing environment. The processor uses this data to maintain a dynamic state model of the process, leveraging particle-based estimation techniques. This model accounts for real-time conditions, historical data, and predictive insights to provide a robust representation of the process state at any given moment.

The system further incorporates a knowledge graph module that represents relationships between process parameters, equipment states, and economic factors. This knowledge graph integrates causal relationships, temporal dependencies, and spatial correlations to enable advanced process analysis and decision-making. It supports context-aware insights by allowing the processor to perform vector similarity searches and hybrid retrieval strategies, ensuring that control decisions are informed by the most relevant data and trends.

To optimize process parameters, the system employs a multi-fidelity decision framework based on light cone theory, which adapts model resolution and computational resources according to the temporal and spatial scope of decisions. The framework implements variable fidelity mapping where near-term, localized decisions utilize high-resolution models with detailed parameter spaces, while longer-term strategic decisions employ broader, probabilistic models that account for increasing uncertainty over time. This dynamic resolution adjustment is achieved through an advanced tree-based search algorithm that incorporates super-exponential regret bounds and adaptive exploration factors. The decision engine balances computational efficiency with solution quality by dynamically adjusting model fidelity based on temporal proximity of decisions, spatial scope of impact, available computational resources, and economic factors including wafer value, energy costs, and maintenance considerations. This approach ensures that the system can effectively navigate both immediate operational decisions requiring precise parameter optimization and longer-term strategic choices where uncertainty must be more broadly considered. The framework maintains alignment with both technical performance targets and broader operational objectives while appropriately scaling computational resources based on decision criticality and time horizon.

Finally, a real-time controller translates the optimized process parameters into actionable control signals for semiconductor manufacturing equipment. The controller enables adaptive adjustments to critical parameters such as thermal compensation, overlay alignment, and field size adaptation. By continuously refining its outputs based on real-time data, the controller ensures precise and consistent manufacturing results, even in the face of variability or unexpected disruptions.

This cohesive system architecture provides a transformative approach to semiconductor process control, leveraging AI-enhanced decision-making and multi-modal integration to address the complex challenges of modern semiconductor manufacturing.

The multi-modal attention mechanism is a key component of the adaptive semiconductor process control system, enabling dynamic integration and prioritization of diverse information streams to support precise and adaptive process control. This mechanism synthesizes multiple sources of data, including process state information, environmental conditions, control history, sensor fusion outputs, real-time measurements, and historical performance metrics. By combining these streams, the system gains a comprehensive view of both current and historical manufacturing conditions, enhancing its ability to make informed and timely decisions.

A dynamic weighting system is employed to evaluate and adjust the relative importance of various factors influencing the process. These factors include thermal conditions, mechanical forces, chemical properties, historical performance patterns, confidence levels, and metrics reflecting uncertainty in measurements or predictions. The weighting system is designed to adapt in real-time, allowing the system to prioritize critical inputs based on evolving process requirements and operational conditions. For example, in scenarios where thermal fluctuations dominate process variations, the system can allocate greater attention to thermal sensor data and related compensation mechanisms.

This mechanism ensures that process adjustments account for multiple interdependent variables, balancing immediate process needs with long-term stability and quality goals. By dynamically redistributing attention among various data streams, the system achieves a level of responsiveness and adaptability that surpasses traditional static or single-variable control methods. This forms a foundation for real-time, data-driven optimization, ensuring that the system can effectively handle the complexity and variability of modern semiconductor manufacturing environments.

The multi-modal attention mechanism may include, for example, a processor configured to integrate and analyze diverse streams of data collected from various sensors and subsystems. In an embodiment, the data streams may comprise process state data that reflects the current operational conditions of manufacturing equipment, environmental conditions such as temperature and humidity, and control history indicating prior adjustments and their outcomes. Additional inputs may include sensor fusion outputs derived from the combination of multiple sensor modalities, real-time measurement data collected during active processes, and historical performance metrics that provide insights into past trends and deviations.

In an embodiment, the dynamic weighting system may use algorithms such as neural networks, fuzzy logic controllers, or weighted sum models to assign and update importance scores for each input stream. These importance scores may be dynamically adjusted based on predefined criteria, real-time measurements, or statistical analyses. For instance, thermal factors may receive higher weighting when significant temperature fluctuations are detected, while mechanical factors such as vibration may be prioritized during high-precision alignment tasks. Confidence levels and uncertainty metrics associated with each input source may further refine the weighting process, ensuring that reliable data sources are emphasized while noisy or uncertain data is given reduced influence.

The mechanism may also include a feedback loop that continuously updates the weighting system based on real-time outcomes and predictive analytics. For example, in an embodiment, the system may use a reinforcement learning model to iteratively optimize the attention mechanism by correlating specific weight adjustments with improvements in process stability, yield, or throughput. This allows the system to evolve and refine its prioritization strategies over time, improving its ability to respond to new challenges and variability in the manufacturing environment.

In an embodiment, the system may incorporate specialized hardware, such as field-programmable gate arrays (FPGAs) or application-specific integrated circuits (ASICs), to execute the multi-modal attention mechanism with low latency. This hardware may be configured to handle high-bandwidth data streams from multiple sensors and execute complex weighting algorithms in real time. Alternatively, the mechanism may be implemented in software, utilizing distributed processing architectures to scale computational resources according to the demands of specific manufacturing processes.

The multi-modal attention mechanism, as described in various embodiments, enables the adaptive process control system to integrate and prioritize diverse inputs effectively, supporting precise and reliable decision-making in dynamic and complex semiconductor manufacturing environments.

The process-specific compensation subsystem enables precise real-time adjustments to critical parameters in semiconductor manufacturing. In an embodiment, this subsystem includes capabilities for thermal compensation, overlay correction, focus optimization, dose adjustment, field size adaptation, and critical dimension control. Each of these adjustments is dynamically driven by real-time data and predictive models, allowing the system to respond effectively to changes in process conditions.

Thermal compensation may involve monitoring temperature variations in the equipment and environment and adjusting parameters such as exposure dose or cooling mechanisms to mitigate thermal expansion effects. For example, the subsystem may use multi-modal sensor data to detect localized temperature fluctuations on a wafer and apply localized cooling or process adjustments to maintain dimensional stability.

Overlay correction ensures proper alignment between layers of a semiconductor wafer. In an embodiment, the subsystem may analyze position sensor data and historical overlay performance metrics to calculate misalignment and generate corrective actions. These actions may include fine-tuning scanner positions or dynamically altering process settings to ensure proper layer alignment.

Focus optimization may involve analyzing optical and environmental data to ensure precise focus settings during lithography. For instance, the subsystem may detect variations in wafer topography or surface reflectivity and adjust focus parameters in real time to maintain uniform exposure quality.

Dose adjustment compensates for variations in exposure intensity or material properties that affect the uniformity of critical dimensions. In an embodiment, this subsystem may use real-time feedback from process sensors to fine-tune dose levels dynamically during operation.

Field size adaptation and critical dimension control are achieved by integrating data from topology-aware sensor fusion and predictive models. Field size adaptation may optimize exposure areas to accommodate large field sizes while maintaining throughput, while critical dimension control ensures that feature sizes remain within tight tolerances by continuously monitoring and adjusting process parameters.

The process-specific compensation subsystem is designed to adapt in real-time based on current measurements, predicted states, historical performance data, process requirements, equipment constraints, and quality targets. For example, during high-volume manufacturing, the subsystem may prioritize throughput while ensuring that process variability remains within acceptable limits. In advanced packaging applications, the subsystem may focus on achieving precise alignment and small critical dimensions to meet the stringent requirements of multi-layer designs.

The predictive state modeling subsystem enables the system to anticipate process outcomes and make data-driven adjustments to maintain optimal conditions. In an embodiment, this subsystem uses particle-based optimization techniques to model the state of the manufacturing process in real time. The state model incorporates data from multi-modal sensors, historical records, and predictive algorithms, providing a probabilistic representation of current and future process conditions.

The predictive state modeling subsystem leverages cutting-edge technologies like quantum computing, deep learning, and AI to deliver highly accurate, adaptive, and scalable process control. By incorporating these advanced methods, the system anticipates process outcomes, manages variability, and optimizes manufacturing operations dynamically.

In the realm of quantum computing for state optimization, quantum algorithms enhance particle-based optimization by solving complex, multi-variable optimization problems faster and more efficiently. Quantum Particle Filters utilize quantum algorithms, such as quantum annealing, to improve the performance of particle-based models. By leveraging quantum superposition, the system evaluates multiple potential process states simultaneously, reducing computational time for state updates. For high-dimensional state spaces, quantum Monte Carlo methods efficiently sample distributions, allowing better representation of uncertainties in wafer alignment, thermal gradients, or material deposition. During lithography, quantum algorithms analyze overlay alignment data from multiple sensors in real time, identifying the optimal scanner position to achieve nanometer-scale precision with minimal delay.

Deep learning models enable the system to extract complex patterns and correlations from high-dimensional sensor data. Convolutional Neural Networks (CNNs) are used to analyze optical and thermal sensor data, identifying subtle anomalies such as surface irregularities or thermal hotspots. Recurrent Neural Networks (RNNs) and Transformers handle time-series data to predict process trends, such as gradual misalignments or equipment drift, based on historical and live measurements. For instance, a CNN analyzes high-resolution wafer inspection images to detect microscopic defects, while a transformer predicts potential defect locations based on historical process data, enabling preemptive parameter adjustments.

AI-driven multi-modal sensor fusion optimizes the integration of data from thermal, optical, positional, and environmental sensors. Advanced AI techniques, such as attention mechanisms, prioritize the most relevant sensor data streams for specific process conditions. Bayesian Deep Learning incorporates uncertainty quantification into sensor fusion, allowing the system to weigh data reliability when sensors provide conflicting measurements. During wafer bonding, AI models dynamically combine thermal and positional data to predict alignment deviations and trigger real-time adjustments, ensuring sub-micrometer accuracy.

Hybrid models combine the predictive power of AI with the deterministic insights of physics-based models. Physics-Informed Neural Networks (PINNs) embed physical laws, such as thermal diffusion or fluid dynamics, into deep learning architectures to improve the accuracy and interpretability of predictions. AI-Augmented Stress Models predict material deformation during etching or bonding by combining AI's ability to learn from historical data with stress-strain equations. A PINN predicts wafer expansion due to thermal variations, adjusting cooling mechanisms in real time based on both physics equations and AI-derived trends.

Quantum-assisted feature selection enhances the identification of the most impactful process variables. Quantum Feature Reduction algorithms identify key variables from multi-dimensional datasets that most significantly influence outcomes, such as defect rates. Quantum Kernels in Machine Learning improve the efficiency of predictive models by mapping input data to higher-dimensional quantum spaces where patterns are more easily separable. For example, a quantum feature reduction algorithm identifies that temperature fluctuations in a specific wafer region strongly correlate with increased defect density, enabling targeted thermal control.

Dynamic state updates with reinforcement learning enable the system to adapt to changing conditions by learning optimal control policies through continuous feedback. Model-Free RL algorithms like Deep Q-Networks (DQN) learn optimal parameter adjustments directly from process data, without requiring explicit models of the manufacturing environment. Model-Based RL uses a predictive state model to simulate the effects of actions, optimizing decisions based on expected outcomes. A reinforcement learning agent adjusts lithography exposure settings dynamically during a batch, learning from feedback to maximize yield while minimizing energy consumption.

Scenario forecasting combines quantum computing and AI to simulate multiple potential outcomes rapidly. Quantum Variational Algorithms simulate process variability, such as thermal gradients or material inconsistencies, across multiple wafers in parallel. AI-Based Risk Prediction identifies the likelihood and severity of process disruptions, such as misalignments or material failures. Before initiating a production run, quantum-enhanced AI evaluates thousands of thermal compensation strategies, selecting the one that minimizes energy usage while maintaining process stability.

Self-supervised learning generates insights from unlabeled process data, reducing the reliance on annotated datasets. Autoencoders identify anomalies by reconstructing expected sensor readings and flagging deviations, while Contrastive Learning learns representations of process states to distinguish between normal and abnormal conditions. An autoencoder trained on historical sensor data identifies an unusual thermal gradient during wafer processing, prompting immediate corrective actions.

Uncertainty-aware AI for risk mitigation incorporates uncertainty quantification to improve decision-making under ambiguous conditions. Dropout as a Bayesian Approximation enables deep learning models to estimate prediction uncertainties by applying dropout during inference. Ensemble Learning combines predictions from multiple models to generate confidence intervals and reduce overfitting. An ensemble model predicts the likelihood of alignment errors during lithography, providing confidence intervals that guide scanner adjustments.

Federated learning enables the system to learn collaboratively from multiple manufacturing facilities without sharing raw data, ensuring data privacy and security. Distributed Training allows models to be trained on local data at each facility, with aggregated updates used to improve global models. Domain Adaptation enables the system to transfer knowledge between facilities with different equipment configurations or process conditions. Federated learning aggregates insights from facilities operating on different nodes, improving defect prediction models while preserving data privacy.

The key advantages of these advanced techniques include scalability, where quantum computing and AI enable real-time, large-scale data processing for high-volume manufacturing; precision, as deep learning and hybrid models enhance the accuracy of state predictions, enabling sub-micron control; adaptability, through reinforcement learning and federated learning that ensure continuous improvement across dynamic conditions and diverse facilities; and efficiency, where quantum-enhanced algorithms reduce computational overhead, enabling rapid decision-making. By integrating quantum computing, AI, deep learning, and advanced hybrid models, the predictive state modeling subsystem achieves unparalleled precision, adaptability, and scalability in semiconductor manufacturing.

Multi-hypothesis tracking is used to maintain multiple potential representations of the process state, each with an associated probability weight. This approach allows the system to account for uncertainties in sensor data or environmental conditions, ensuring robust decision-making even when the process state is partially ambiguous. Adaptive resampling strategies may refine the particle distribution over time, focusing computational resources on the most likely hypotheses and discarding those with low probabilities.

Dynamic particle count adjustment ensures that the system can allocate resources efficiently based on process complexity or variability. For example, during a stable manufacturing phase, the subsystem may reduce the number of particles used in the model to conserve computational resources, while during periods of high variability, the particle count may increase to capture a more detailed representation of the state space.

Future state prediction combines physics-based models, statistical methods, and machine learning approaches to forecast process conditions under various scenarios. For instance, a hybrid model may predict thermal expansion during exposure steps by integrating physics-based thermal equations with statistical correlations derived from historical data. Real-time adaptation of these models ensures that predictions remain accurate as process conditions evolve.

Uncertainty quantification is integral to predictive state modeling. In an embodiment, the subsystem may use probabilistic modeling to estimate confidence intervals for predicted states, enabling the system to assess risks and adjust its strategies accordingly. Sensitivity analysis may identify which variables have the greatest impact on process outcomes, allowing targeted adjustments to reduce variability. Robustness metrics, such as error bounds and risk assessments, ensure that the predictions remain reliable even under adverse conditions.

Uncertainty quantification ensures decision-making is robust and reliable, even in the face of variable or incomplete data. In this context, it enables the adaptive process control system to estimate confidence levels for predicted process states, identify risks, and adjust strategies proactively. Several techniques and methodologies can be employed to achieve comprehensive Uncertainty quantification (UQ).

Probabilistic modeling for confidence intervals employs models such as Bayesian networks or Monte Carlo simulations to estimate confidence intervals for predicted states. By modeling the probability distributions of critical process parameters like wafer temperature and alignment precision, the system can quantify the likelihood of deviations from optimal conditions. A Monte Carlo simulation might repeatedly sample possible values for overlay alignment errors based on sensor noise distributions, generating a range of potential outcomes and their associated probabilities. Bayesian updating can refine these distributions in real-time as new sensor data is incorporated, dynamically improving the accuracy of confidence intervals.

Sensitivity analysis evaluates how variations in input parameters, such as thermal fluctuations and exposure dose, impact process outcomes like yield or defect rates. Global Sensitivity Analysis (GSA) quantifies the overall influence of each input variable across its entire range. Sobol indices, for example, can rank parameters by their contribution to variance in critical outputs. Local Sensitivity Analysis examines small perturbations around nominal operating conditions to identify the most impactful factors. For instance, tweaking wafer positioning parameters may reveal how sensitive edge placement accuracy is to alignment errors. Identifying the most influential parameters allows the system to prioritize control strategies that mitigate variability in these critical areas.

Robustness metrics ensure that process predictions remain stable and trustworthy under varying conditions. These include error bounds, which are calculated for key parameters to indicate the expected deviation range of model predictions. For example, thermal compensation models may predict wafer temperatures with a ±1° C. error bound, providing clear limits for process adjustments. Risk assessments utilize historical data and probabilistic models to estimate the likelihood of adverse outcomes. For example, a high risk of overlay misalignment during extreme humidity conditions can prompt preemptive recalibration.

Quantifying measurement uncertainty is crucial, as a significant source of uncertainty in semiconductor manufacturing arises from sensor noise and calibration errors. Sensor Fusion Algorithms combine data from multiple sensors (thermal, optical, positional) to reduce measurement uncertainty and improve confidence in the aggregated data. Error Propagation Models calculate how measurement errors propagate through predictive models to determine their impact on final outcomes.

Real-time adaptive resampling employs particle-based estimation techniques, where particles represent potential process states. Adaptive resampling strategies refine the particle distribution by emphasizing high-confidence regions of the state space while discarding unlikely scenarios. During periods of stable operation, fewer particles may be allocated to conserve computational resources, whereas higher variability conditions may trigger increased sampling to maintain accuracy.

Hybrid modeling approaches combine physics-based and data-driven models to enhance the reliability of UQ. Physics-Based Models use established equations (thermal diffusion, stress-strain relationships) to provide deterministic bounds on expected outcomes. Machine Learning Models incorporate historical data and real-time measurements to capture complex, nonlinear dependencies not captured by physics-based approaches. The integration of these models allows for better uncertainty quantification by leveraging the strengths of both approaches.

Visualization of uncertainty through tools such as uncertainty heatmaps or probability density functions (PDFs) can help operators and engineers understand the spatial and temporal distribution of uncertainties across a wafer or manufacturing process. A heatmap of overlay errors might reveal regions of the wafer prone to misalignment, guiding localized adjustments or additional measurements.

Real-world validation and feedback ensures UQ methodologies are validated against real-world manufacturing outcomes. Discrepancies between predicted and observed states can be used to refine the UQ models through techniques like Cross-Validation, which tests models on separate datasets to evaluate predictive accuracy, and Real-Time Feedback Loops, which continuously update UQ metrics as new data is collected, ensuring the system adapts to evolving conditions.

In terms of practical considerations, scalability is essential as UQ techniques must be computationally efficient to support real-time decision-making in high-volume production environments. Data quality is crucial since the reliability of UQ depends on the accuracy and resolution of sensor data, making calibration and periodic validation of sensors essential. Integration with control systems is vital as UQ outputs should seamlessly inform optimization algorithms and control signals, ensuring that uncertainty-driven insights translate into actionable decisions.

The predictive state modeling subsystem provides a foundation for advanced process optimization by enabling proactive adjustments and minimizing deviations from desired process outcomes. For example, in mixed technology node processing, the subsystem may predict the effects of varying process conditions on different device types, enabling the system to optimize settings for each node simultaneously.

The advanced data integration layer is a component of the adaptive semiconductor process control system, structured to unify and interpret data from diverse sources to enable process optimization. By incorporating topology-aware sensor fusion and enhanced knowledge graph integration, this layer provides real-time data analysis and supports decision-making. It includes a framework for integrating multi-modal sensor data, generating actionable features, and mapping relationships between process parameters, environmental conditions, and equipment states.

The integration layer is designed to address the challenges of high data volumes, complex dependencies, and real-time requirements in semiconductor manufacturing. By employing dynamic feature adaptation, multi-scale analysis, and relationship mapping, it supports the continuous refinement of operations and contributes to improved process stability and efficiency.

The advanced data integration layer is designed to enable seamless aggregation, processing, and analysis of diverse data streams within the semiconductor manufacturing process. This layer may include, for example, a topology-aware sensor fusion framework and an enhanced knowledge graph integration module, working in tandem to provide comprehensive data representation and actionable insights.

In one aspect, the system implements an in-line digital twin and virtual metrology framework that continuously runs in parallel with the physical semiconductor manufacturing process, providing predictive insights regarding wafer-level outcomes. Unlike batch-mode or static models, which require substantial post-processing time, the disclosed in-line approach leverages real-time sensor data, including optical, thermal, positional, and environmental measurements, to maintain a dynamically updated model. This “digital twin manager” executes on a computing platform connected to a network of in-fab sensors, ingesting both live measurements from current wafers under processing and historical data from previous wafer batches. By fusing the multi-modal sensor readings with known physical behaviors such as thermal diffusion and fluid-structure interactions, the system updates a simulation model at each critical step in wafer processing. The disclosed approach may incorporate finite-element and fluid-structure interaction models that accurately capture local variations in temperature, stress, or material properties (e.g., resist flow), ensuring high-fidelity predictions for each wafer pass. This real-time calibration loop involves comparing simulated outcomes—such as thickness or overlay accuracy—against recently gathered sensor data, then continuously adjusting model parameters to maintain consistency between predicted and observed behavior.

In another aspect, the framework integrates a virtual metrology module that computes critical metrics, including but not limited to effective exposure dose, thickness uniformity, and critical dimension measurements, based on the calibrated digital twin outputs. As wafers move through various stages of lithography, etching, deposition, or bonding, the virtual metrology module analyzes sensor data in multiple possible representation formats—such as vectorized feature sets, pixelized (two-dimensional grid), voxelized (three-dimensional volume), or mesh-based coordinate systems. In a vectorized approach, each wafer region may be condensed into a feature vector encompassing parameters like local film thickness, reflectance spectra, and overlay offset. By contrast, pixelized or voxelized data structures allow the system to process wafer surfaces or volumes as discretized grids, enabling convolution-based filters or deep learning models to detect anomalies in near real time. For advanced packaging or three-dimensional stacking scenarios, the voxelized scheme is especially beneficial, as it captures internal volumetric attributes (e.g., interlayer voids, structural stress) beyond surface-level measurements. In certain embodiments, mesh-based geometries—such as triangular or tetrahedral meshes—are employed to better conform to irregular wafer shapes or specialized module layouts, with each mesh node storing localized sensor-derived variables. Through these approaches, the virtual metrology module and knowledge graph can record “snapshots” of wafer states as time-series nodes, facilitating both quick checks during a given production run and longer-term historical comparisons across multiple runs.

In another embodiment, the digital twin manager contributes to closed-loop process control by leveraging the real-time simulation outputs and virtual metrology metrics to inform upper confidence tree (UCT) optimization algorithms (sometimes with advanced techniques like super exponential regret) or analogous AI-based controllers. When the digital twin detects or forecasts potential deviations—such as a localized temperature spike or alignment drift—the system preemptively adjusts critical manufacturing parameters (e.g., scanner overlay corrections, thermal compensation, or exposure dose) to avert out-of-spec conditions before they fully materialize. Hence, if the simulation predicts a rising temperature gradient along the wafer edge based on pixelized thermal maps, the digital twin manager can relay this information to the optimization subsystem, prompting it to modify, for example, cooling rates or scanning speeds in that region. This proactive mechanism substantially lowers the risk of yield excursions by intervening at the earliest indication of process instability, effectively optimizing doping levels, resist curing schedules, or stage velocities mid-run rather than waiting until post-process inspection.

To further enhance scalability, the digital twin and virtual metrology system is designed for distributed computing architectures. In certain implementations, high-performance computing (HPC) clusters or GPU-accelerated workstations are employed to handle the real-time simulation workloads. The framework supports a hybrid “edge plus cloud” topology wherein preliminary sensor fusion and coarse-level calculations are performed locally on the manufacturing equipment (the edge), while computationally intensive finite-element or 3D fluid-structure simulations may be offloaded to remote HPC resources or cloud-based services when needed. This approach ensures that even facilities processing thousands of wafers daily can maintain near real-time updates to their digital twins without sacrificing simulation fidelity. Additionally, partial or condensed simulation states may be periodically shared between multiple lines or geographically separate fabrication sites, enabling collaborative learning and federated modeling that accelerate the improvement of predictive accuracy across an entire manufacturing network.

The system's adaptability to multiple data representations—vectorized, pixelized, voxelized, or mesh-based—provides additional flexibility in how wafer metrology data is stored, processed, and leveraged for decision-making. In a vectorized embodiment, each wafer site (or grouping thereof) is reduced to a carefully selected feature set—potentially including thickness, reflectance, variance, alignment, or layer-specific parameters—allowing fast numeric processing and direct compatibility with conventional machine learning pipelines. In a pixelized scenario, the wafer or its relevant sections are mapped onto a two-dimensional grid, each pixel encoding aggregated measurements for that region. Such a format is particularly amenable to standard 2D convolutional neural network architectures, enabling rapid detection of anomalies such as local hotspots or scratches. For advanced 3D processes like through-silicon via (TSV) formation or multi-die stacking, a voxelized model may be more advantageous, as it accommodates volumetric signals from ultrasonic, X-ray, or optical tomography scans. In still other cases, specialized polygonal or tetrahedral meshes conform exactly to the wafer's shape or die layout, allowing for refined simulation at irregular edges or critical layered interfaces. Each representation can be dynamically chosen based on the granularity required, the sensor data available, and the type of process step being simulated.

By merging this continuously updated in-line digital twin with the broader knowledge graph and optimization subsystems, the invention empowers semiconductor manufacturers to detect, diagnose, and correct process deviations in real time. This reduces reliance on downstream inspections or rework loops, thus minimizing overall cycle time and cost. Moreover, storing incremental simulation snapshots as part of the knowledge graph enables long-horizon trend analysis, wherein unusual patterns or slowly developing equipment drifts can be caught earlier. Consequently, the disclosed system not only enhances individual wafer quality but also promotes global process consistency across high-volume fabs. When combined with a robust AI-based optimization layer and real-time feedback loops, this digital twin and virtual metrology paradigm enables an entirely new level of predictive control, supporting next-generation nodes and advanced packaging strategies with unprecedented agility and precision.

In an embodiment, the topology-aware sensor fusion framework integrates data from multiple sensor modalities, including thermal sensors, position sensors, optical sensors, process-specific sensors, environmental monitors, and quality inspection systems. These sensors may collectively provide a multi-faceted view of the manufacturing environment, capturing critical parameters across spatial and temporal scales. To enhance data utility, the framework may generate topology-aware features by applying techniques such as persistent homology integration, scale-specific feature extraction, and feature matching with confidence scoring. For example, persistent homology may be used to identify and track topological features that persist across multiple scales, enabling the detection of stable patterns and anomalies.

The framework may perform multi-scale topological analysis to identify relationships between features at varying levels of granularity. Dynamic feature adaptation may be employed to adjust feature representations in real time, ensuring that the data fusion process remains robust under changing conditions. In an embodiment, real-time feature selection algorithms may prioritize features that contribute most significantly to process optimization, based on metrics such as information gain or predictive value.

Real-time data fusion may be achieved through techniques such as Kalman filtering, particle filtering, neural network fusion, Bayesian integration, and multi-scale decomposition. For instance, a particle filter may combine data from position sensors and optical sensors to provide a probabilistic estimate of equipment alignment, while Bayesian integration may be used to reconcile conflicting measurements from thermal and environmental sensors. Hierarchical fusion strategies may also be employed to combine data at different levels of abstraction, supporting both localized and system-wide decision-making.

The enhanced knowledge graph integration module may, in an embodiment, represent process relationships, parameter interactions, and constraints in a structured and interpretable format. Neuro-symbolic integration techniques may be used to link data-driven insights with semantic understanding, enabling advanced functionalities such as vector similarity search and graph traversal. For example, the system may retrieve similar process conditions from historical data by performing a vector similarity search, then traverse the knowledge graph to identify causal relationships and temporal dependencies relevant to current conditions.

Process relationship mapping may be facilitated through the representation of causal relationships, spatial correlations, and quality dependencies. In an embodiment, the knowledge graph may dynamically update based on new measurements, process outcomes, performance metrics, and environmental conditions. For instance, if a particular process step consistently leads to deviations in overlay alignment, the knowledge graph may incorporate this relationship to refine future predictions and control strategies.

The advanced data integration layer, as described in various embodiments, enables the adaptive semiconductor process control system to aggregate and interpret complex datasets, providing a robust foundation for real-time optimization and predictive decision-making.

The artificial intelligence (AI)/machine learning (ML) model management component is structured to support the development, deployment, and ongoing optimization of machine learning models used in the adaptive semiconductor process control system. This component integrates a hybrid model architecture and a flexible training and validation framework, enabling the system to learn from diverse data sources, adapt to changing conditions, and maintain robust performance in dynamic manufacturing environments and includes techniques such as but not limited to hyperparameter optimization, chain of thought, structured expert judgment from teams of agents, reinforcement learning, or fine tuning.

The model management component provides a platform for leveraging various machine learning approaches, including physics-informed models, statistical methods, neural networks, Kolmologorov Arnold Networks, Transformers, Titans, VAEs. It supports real-time adaptation through techniques such as online learning and reinforcement learning, ensuring the system remains responsive to new data and evolving process requirements. Through a combination of robust training strategies and comprehensive validation methods, this component ensures that the models are accurate, reliable, and capable of addressing the complexities of semiconductor manufacturing processes.

The model architecture may include, for example, a hybrid structure combining multiple methodologies to address different aspects of process control. In an embodiment, the system may utilize physics-informed neural networks to incorporate domain knowledge into the modeling process, embedding physical constraints or equations directly into the network structure to improve predictions of process behavior. Statistical process control models may be included to monitor process stability and identify anomalies, while rule-based systems can enforce critical constraints or operational rules to prevent deviations.

Learning components may include Bayesian networks for probabilistic reasoning, enabling the system to handle uncertainty by calculating the likelihood of various outcomes based on available data. Causal models may identify directional relationships between process variables, helping the system to predict the impact of changes in one parameter on others and to design more effective control strategies.

Adaptation mechanisms may involve, for example, online learning algorithms that update model parameters in real time based on incoming data. In another embodiment, transfer learning may enable the system to apply knowledge gained from one process to similar processes, while reinforcement learning may optimize control strategies through trial-and-error interactions with the manufacturing environment.

In an embodiment, an Explainable AI (XAI) component may be incorporated into an existing AI-driven semiconductor manufacturing control system for process mapping, transparency, and improvement. The adaptive semiconductor process control platform includes an Explainable AI (XAI) subsystem configured to enhance transparency and interpretability of decisions made by AI models, such as the UCT optimization engine, particle filters, or neural networks. This subsystem, referred to as the “XAI Module,” operates in tandem with the core control processes—namely, data integration, model management, and process optimization—to generate explanations on demand. The XAI Module ingests inputs such as model outputs from the upper confidence tree (UCT) optimization algorithm, multi-modal sensor data, updated knowledge graph data including wafer process parameters, and intermediate results from machine learning pipelines. By correlating these inputs with the final control signals or parameter adjustments, the XAI Module produces human-readable justifications, such as highlighting sensor measurements, confidence intervals, or process constraints that influenced a certain optimization decision. Through specialized interpretability techniques, including perturbation-based feature attribution, saliency mapping, or model-specific explanation frameworks like SHAP, LIME, and Grad-CAM, the XAI Module clarifies which measurements or topological features in the wafer data were most determinative in the AI's decision logic.

According to one exemplary implementation, the XAI Module includes an “Interpretability Engine” that periodically or on demand processes the intermediate decision states, parameters, and confidence values generated by the UCT optimization engine. In response to a request from an operator dashboard, an automated audit trigger, or a wafer anomaly alert, the Interpretability Engine retrieves the relevant AI model states and associated process data from the knowledge graph. The engine then executes one or more interpretability algorithms that map each decision node in the UCT search tree—together with the recognized sensor patterns—to ranked significance scores. If a dose adjustment was made because the system detected a 10° C. thermal gradient at the wafer edge, the engine can present a structured explanation, such as “Thermal gradient above threshold→system raised local cooling level→predicted defect reduction of 5%.” Operators are thus provided real-time or near real-time textual and graphical justifications, which helps them swiftly validate or override certain adjustments if needed.

In a further embodiment, the knowledge graph itself is extended with specialized “explanation nodes” to store the rationale behind critical steps in the optimization or control process. Each explanation node may contain Causal Assertions, which state the causal chain discovered by the AI (e.g., “Raised wafer edge temperature can cause localized film thickness defects”); Model Version and Confidence Values, which reference the specific AI model versions or ensembles used to compute the effect magnitude; and Explanatory Links, which are directed edges connecting specific sensor readings, derived features, and recommended actions. This approach enables future queries to trace back the origin of a control decision. For example, an engineer or system audit can easily navigate from final parameter changes to the underlying sensor anomalies or topological features that triggered them. In certain implementations, the graph manager calculates a “confidence weighting” for each explanation node, factoring in the variance or Bayesian posterior distributions reported by the AI models. Explanations with low confidence might be flagged for manual review to ensure that questionable data sources do not unduly influence wafer processing steps.

To address potential compliance mandates or internal quality governance, the XAI Module logs a historical lineage of both model usage and explanation data. For each wafer lot, the system stores Model Identification, including the exact AI model or ensemble revision used for each decision event, with hyperparameter settings or partial neural network weights if permissible; Sensor Events and Anomalies, including flagged anomalies, missing sensor data, or override events initiated by human operators; and Causal/Explanatory Summaries explaining how the system integrated anomalies into final decisions. These records are written to a secure, version-controlled repository, which can be accessed during external audits or internal investigations. Because certain regulatory frameworks may require near real-time justification of AI-based decisions, the system can selectively generate formalized explanation reports automatically each time wafer parameters are adjusted. If or when an audit arises, these logs form a comprehensive chain of trust that details every major action the AI took and why.

In some embodiments, a “lineage manager” component within the XAI Module implements cryptographic hashing or secure timestamps for each explanation record, ensuring tamper-evident storage. Whenever an AI model is updated, the system logs the difference between the old and new models, along with an automatic comparison of any changes in explanation patterns. This approach fulfills stringent traceability requirements, letting the fab operator demonstrate the consistency or improvements in how the system justifies process decisions before and after the model update.

To facilitate practical usage on the factory floor, the system supports a real-time user interface that displays color-coded overlays and saliency maps for rapid human interpretation. A lithography engineer may open an “explanation panel” and see a wafer map with highlighted regions that the AI deems critical. Red or orange shading might denote areas associated with high confidence in imminent defects if left uncorrected, whereas green shading signifies stable zones. Alongside this wafer map, short textual highlights may appear in tooltips, explaining which sensor signals triggered the concern. For neural-network-based submodules, the interface can display saliency maps or gradient-based explanations at the pixel or feature level, clarifying why certain edges or patterns strongly contributed to the classification.

In some embodiments, the system employs a scheduling algorithm to decide which explanations or saliency maps must be generated in near real time versus deferred to batch mode. High-urgency steps may push the XAI Module to produce a concise, critical explanation immediately, while more detailed visual breakdowns might be assembled in the background. This ensures that operators can confidently act on system-recommended changes without experiencing excessive delays. By presenting targeted, context-specific explanations, the platform bridges the gap between black-box AI decisions and the practical constraints of a fast-paced manufacturing environment.

The XAI subsystem is not restricted solely to the UCT engine. In some designs, the particle filter engine or deep neural networks used for real-time sensor fusion also produce intermediate states that influence wafer process decisions. The XAI Module can intercept these intermediate states to generate local interpretability artifacts. For example, if the particle filter's posterior distribution indicates a 30% chance of an alignment drift, the XAI engine can highlight precisely which subset of sensor nodes contributed to the drift probability. This multi-stage approach ensures that, from data ingestion through final control signals, the system is capable of describing the rationale behind each computational step.

Implementation variations include Lightweight vs. Comprehensive Explanations, where in certain high-throughput conditions, the XAI Module generates only short bullet-point rationales, whereas a more thorough version can be compiled offline for later review; Hierarchical Explanation Trees, where for large optimization problems, explanations may be structured into hierarchical trees or DAGs, allowing quick navigation from top-level “why” answers down to the underlying model logic; and Modular Deployment, where the XAI Module can be containerized and deployed on separate hardware resources, such that interpretability tasks do not impede critical real-time computations.

The disclosed XAI architecture seamlessly weaves interpretability and transparency into the existing AI-driven semiconductor control environment, improving trust, debugging efficiency, and readiness for regulatory or standards-based oversight of AI solutions. By incorporating the specialized interpretability engine, explanation nodes in the knowledge graph, comprehensive lineage and audit logs, and advanced real-time visualization overlays, the invention addresses the critical need for manufacturing professionals to understand, validate, and refine how AI-driven control signals are produced. This approach thus empowers operators and engineers to embrace AI optimizations with confidence, ensures accountability, and positions semiconductor fabs to comply with future regulations mandating interpretable or auditable AI in mission-critical processes.

Federated learning, in an embodiment, may allow distributed model training across geographically dispersed facilities while preserving data privacy. For example, sensor data from multiple factories may be used to train a global model without transferring raw data, reducing risks associated with centralized data storage while leveraging diverse operational experiences.

In an embodiment, federated learning enables distributed model training across multiple manufacturing facilities while preserving data privacy and security. The federated learning implementation comprises local model training on facility-specific data, secure aggregation of model updates, and global model distribution. Local training occurs within each facility's model management subsystem 300, where learning adaptation unit 340 uses local process data to update neural network weights and knowledge graph structures. Model parameters rather than raw data are encrypted and transmitted through communications interface 104 to a central model aggregation service. The aggregation service combines model updates using weighted averaging based on factors including data volume, facility characteristics, and historical model performance. The resulting global model is validated against cross-facility performance metrics before being redistributed to individual facilities.

To maintain data privacy, differential privacy techniques are applied to model updates before aggregation, adding calibrated noise to prevent reconstruction of facility-specific information. The system implements secure multi-party computation protocols for model averaging, ensuring that individual facility contributions remain confidential during aggregation. Adaptive compression techniques reduce communication overhead while preserving model accuracy, with compression ratios dynamically adjusted based on network conditions and model sensitivity.

Other adaptation mechanisms may include meta-learning, which enables the system to improve its learning efficiency over time by refining its model architecture and learning processes, active learning to prioritize the most informative data points for training, and self-supervised learning to generate training signals from unlabeled data.

The training and validation framework may include a variety of approaches to ensure that the models are robust and effective. In an embodiment, supervised learning techniques may be used to train models using historical process data, while reinforcement learning may refine these models based on feedback from real-time process outcomes. Unsupervised learning methods may be applied to discover hidden patterns or correlations in the data, and self-supervised learning may enable the system to generate training signals from unlabeled data.

Few-shot learning may be used to train models with limited labeled data, improving efficiency in scenarios where extensive data collection is impractical. Online adaptation capabilities may allow models to continuously refine their performance based on live data, ensuring that they remain effective as process conditions evolve.

Validation methods may include, for example, cross-validation to evaluate model performance on different subsets of the data, out-of-sample testing to assess generalization to new conditions, and process simulation to test models under controlled virtual environments. Real-world verification may confirm model effectiveness in actual manufacturing scenarios, while stress testing and robustness analysis may evaluate model performance under extreme or unexpected conditions. For instance, stress tests may simulate scenarios such as significant sensor failures, high levels of data noise, or drastic deviations in environmental conditions to ensure that the models remain stable and effective under challenging circumstances.

The AI/ML model management component, with its hybrid architecture and adaptive training and validation capabilities, provides the foundation for integrating intelligent decision-making into the semiconductor manufacturing process.

The process optimization engine enables the adaptive semiconductor process control system to achieve efficient and accurate optimization of manufacturing parameters. By integrating advanced optimization algorithms, economic considerations, and measurement strategies, this engine supports dynamic and context-aware decision-making. The engine is designed to address complex, multi-variable challenges in semiconductor manufacturing, leveraging techniques such as regret minimization, economic factor modeling, and targeted measurement planning.

This component incorporates a combination of advanced computational techniques and real-time feedback mechanisms to optimize process parameters while balancing throughput, quality, and cost. Through adaptive exploration and economic integration, the process optimization engine provides a scalable solution for managing the intricate demands of modern semiconductor manufacturing environments.

The process optimization engine may include, for example, an advanced upper confidence tree (UCT) implementation. In an embodiment, the UCT algorithm may use a modified AlphaZero-style formula to minimize super-exponential regret, ensuring effective decision-making across a complex search space. The algorithm may operate with a bounded tree depth (e.g., approximately 20 levels) to constrain computational requirements while maintaining sufficient depth for nuanced optimization.

Iterative expansion control may be employed to manage the growth of the search tree, limiting expansions to branches with high potential for improvement based on confidence thresholds or dynamic evaluation metrics. Progressive widening may allow the system to focus on expanding promising branches selectively, balancing exploration of new possibilities with the exploitation of known high-value decisions. For example, this may use MCTS+RL or UCT w/super exponential regret paired with an objective function.

Multi-scale sampling techniques may optimize decisions at different levels of granularity. For example, localized optimizations, such as critical dimension adjustments in specific wafer areas, may complement broader optimizations like throughput maximization across multiple wafers in a batch. These techniques enable the system to address both fine-grained and large-scale process requirements efficiently.

Dynamic exploration strategies may include confidence-based exploration, prioritizing paths with high certainty of success; risk-aware sampling, which evaluates the likelihood and impact of adverse outcomes; and Thompson sampling, which balances exploration and exploitation using probabilistic models. Other strategies may include information gain maximization, where the system identifies adjustments with the most significant potential to improve process knowledge, and contextual bandits, which adapt decisions based on real-time changes in operational context. Hierarchical exploration may manage multi-level decision spaces, such as optimizing individual wafer layers while considering overall batch performance.

The economic optimization framework may include integration of key economic factors to ensure that process optimization aligns with operational and financial goals. In an embodiment, the framework may incorporate wafer value optimization by prioritizing high-value wafers for more precise adjustments. Energy cost management may involve minimizing power consumption during manufacturing, while maintenance cost optimization may focus on predictive maintenance scheduling to reduce unplanned downtime.

Material cost control may include optimizing the use of consumables, such as chemicals or deposition materials, and labor cost optimization may focus on streamlining manual interventions. Equipment depreciation may also be considered, enabling decisions that extend the usable life of critical assets. For instance, the system may adjust operating parameters to reduce wear and tear on aging equipment, balancing immediate performance with long-term cost savings.

Market-driven adaptation may include demand factor integration to align production schedules with periods of high market demand or to prioritize production of high-margin products. Price premium modeling may guide decisions to maximize profitability in niche markets, while competition analysis may help optimize production strategies based on industry trends. Capacity utilization optimization may ensure efficient use of manufacturing resources, while supply chain constraints and market segment targeting may refine economic strategies based on material availability and customer demands. For example, during supply chain disruptions, the system may prioritize production of simpler or less resource-intensive products to maintain throughput.

The process optimization engine may also include a measurement strategy integration module, enabling targeted data collection to support real-time decision-making. This may involve, for example, just-in-context (JIC) measurements, where pre-bonding baseline measurements are complemented by more than 5,000 measurements per wafer during bonding and more than 2,000 measurements per wafer post-bonding. JIC measurements may use adaptive sampling strategies to prioritize the most relevant data points based on process conditions and context-aware planning to align measurements with specific requirements. Quality-driven sampling may focus on areas with historically high defect rates, ensuring that resources are directed toward high-risk regions.

Just-in-time (JIT) measurements may focus on real-time verification, enabling dynamic adjustments to reduce overlay errors and optimize the process window. These measurements may use critical parameter monitoring and threshold-based triggering to respond promptly to deviations, ensuring process consistency. For example, real-time detection of misalignment during wafer bonding may trigger immediate adjustments to correct scanner positions.

Just-in-place (JIP) measurements may include scanner correction and control, deformation monitoring, and real-time adjustments tailored to specific locations on the wafer. For instance, JIP measurements may identify localized variations in field size or critical dimensions and apply compensation techniques in real time. This strategy may enable location-specific compensation, field-size optimization, and localized process control to improve overall manufacturing precision. In some embodiments, JIP adjustments may be triggered by anomalies detected during JIT verification, creating a feedback loop that ensures immediate corrective action.

In an embodiment, an energy-aware sensor orchestration subsystem for adaptive power management and contextual activation is disclosed. The semiconductor process control platform incorporates an energy-aware sensor orchestration layer designed to dynamically manage sensor usage based on predicted data utility. This approach extends beyond conventional static gating or fixed sampling schedules, employing AI-driven decision logic, such as reinforcement learning or multi-armed bandits, to selectively power or adjust sensor subsets in real time. The system aims to reduce overall energy consumption while preserving adequate coverage and fidelity for critical measurements necessary to maintain high wafer yield and low defect rates. The layer operates in concert with the data integration subsystem, knowledge graph, and process optimization subsystem, ensuring that turning off certain sensor streams—or lowering their sampling rates—does not compromise the accuracy of wafer state estimation or process control decisions.

A specialized software module, referred to as the “sensor subnetwork manager,” continuously monitors incoming data from multiple sensor modalities (thermal, optical, positional, chemical sensors) and evaluates the likely benefit of the next measurement from each sensor relative to its associated energy cost. In one exemplary implementation, the subnetwork manager uses an AI-based heuristic algorithm, such as Q-learning, policy-gradient reinforcement learning, or multi-armed bandit strategies. Each sensor is treated as an “arm” that yields a time-varying reward corresponding to the sensor's marginal contribution to reducing uncertainty in process parameters or improving yield predictions. By monitoring these rewards over time, the sensor subnetwork manager estimates expected utility for near-future measurements and dynamically chooses which sensors to activate and at what frequency. Under stable process conditions—identified by low variation in wafer alignment, temperature, or other key indicators—sensors that contribute minimal incremental information may be idled or set to a lower power state. In contrast, during complex or rapidly changing steps, the subnetwork manager reactivates or intensifies sampling from critical sensors to maintain sufficient data coverage.

To further optimize coverage, the sensor subnetwork manager integrates seamlessly with the UCT optimization engine (or other AI-based controllers) that tracks potential risk hotspots on the wafer. When the system predicts a higher probability of overlay misalignment, local thermal runaway, or doping inconsistencies in a certain region or process phase, the manager selectively triggers additional sensors in those specific zones (“just-in-place” activation) or time windows (“just-in-time” sampling). For example, if the UCT engine detects that a wafer edge is approaching a critical limit for temperature uniformity, the subnetwork manager dynamically activates multiple thermal sensors (or intensifies their sampling rate) in that region only, leaving unaffected areas in a lower-power monitoring mode. This approach prevents unnecessary global activation of sensors and focuses resources where they have the highest expected impact on yield or defect detection. During ramp-up or high-variability phases, the system can revert to a broader activation profile to ensure anomalies are not missed.

In another embodiment, the sensor subnetwork manager receives continuous input from an economic analysis processor that weighs sensor energy costs, maintenance overhead, and wafer value. These parameters are stored in the knowledge graph for real-time retrieval. For instance, a sensor that is known to require frequent calibration or has a high power draw might be assigned a higher “cost coefficient.” The system then performs a cost-benefit analysis, seeking to maximize yield improvements minus the total sensor operation costs. By combining real-time wafer risk levels with an economic perspective, the platform can decide if the added yield gain of enabling an expensive sensor is justified. The manager might rank sensors by their “utility minus cost,” ensuring that only high-value data streams remain active, while low-impact sensors remain idle or at reduced sampling intervals. This model can also factor in near-future wafer batches that have different complexities or economic priorities, further refining sensor usage strategies.

In parallel to adjusting sensor power states, the system implements a continuous calibration and drift compensation loop. A dedicated calibration routine compares real-time sensor data against reference baselines or cross-checks multiple overlapping sensors. If a particular sensor's readings deviate significantly from expected tolerances, or if correlation with other sensors breaks down, the subnetwork manager flags the sensor for recalibration. Depending on the severity and type of drift, the platform either attempts an automated re-calibration step or transitions that sensor to a lower activity state until manual servicing can be scheduled. By minimizing reliance on out-of-spec sensors, the system avoids feeding erroneous data to the wafer state model and thus prevents corrupting yield predictions or inadvertently triggering spurious control decisions. Should the drift be minor yet consistent, the subnetwork manager applies a dynamic offset within the data integration pipeline and continues using the sensor at an adjusted reading until a full calibration is feasible.

The energy-aware sensor orchestration may be implemented as a software layer communicating with hardware-level control signals for each sensor (through I²C, SPI, or custom fieldbus protocols). On the hardware side, sensors may support multiple power states: fully powered for high-frequency sampling, idle (ultra-low power mode), or partial sleep states where only internal housekeeping functions run. The subnetwork manager issues commands to switch these states, specifying reduced sampling rates or changed bit-depth for analog-to-digital converters. This granular control mechanism enables partial energy savings even if full shutdown is not advisable. Additionally, the subnetwork manager continuously updates the knowledge graph with the “sensor subnetwork state,” indicating which sensors are active, which are idled, and any ongoing calibrations, so that the broader system is aware of potential data coverage gaps.

Since the wafer state estimation processes assume certain data availability, the subnetwork manager synchronizes closely with the model management subsystem. If the manager plans to idle multiple sensors for energy reasons, it checks with the state model to ensure that such a decision will not cause an unacceptable increase in uncertainty. In some embodiments, the system uses an iterative approach: it simulates the effect on the posterior distribution of wafer states if sensor S is temporarily turned off. If the expected variance or predicted risk of misclassification remains below a threshold, the manager proceeds with the power-down request. Conversely, if shutting off a key sensor degrades the state model's accuracy significantly—possibly increasing the risk of yield excursions—the request is disallowed or delayed until process conditions are less critical.

The sensor subnetwork manager can operate at multiple levels. At a low level (per sensor or sensor group), it adjusts sampling frequency and power states in real time (millisecond to second scale). At a higher level (per wafer batch or shift), it may recalculate overarching “sensor usage profiles” based on historical performance or upcoming production schedules. For instance, if the system detects consistent, stable conditions for a batch of standard logic devices, it might define a “low-power sensor mode” for that shift, enabling only the highest utility sensors except during anomalies. Conversely, for advanced or high-value wafers, the system reverts to full sensor activation. This multi-level approach ensures that each batch receives the sensor strategy that balances cost, risk, and throughput under dynamic manufacturing demands.

The example operational flow begins with initial sampling, where the system starts with most sensors at nominal rates to gather baseline data on wafer alignment, temperature, and thickness. In stability detection, the AI heuristic recognizes minimal variation over several wafers, concluding that the marginal gain of certain sensors is low. During selective idling, the manager lowers sampling rates of those arrays and sets them into partial sleep, cutting power consumption by 60%. When a risk trigger occurs midway through processing as a new wafer type starts, the UCT algorithm flags a likely overlay drift in a wafer region, and the manager reactivates additional positional sensors near that region. A cost-benefit check indicates a slight uptick in energy usage, but the potential yield savings from mitigating overlay errors justifies the reactivation cost. During on-demand calibration, if a humidity sensor is found drifting beyond acceptable bounds, it is either recalibrated automatically or flagged for manual maintenance, while the platform partially compensates for the drift in real time by referencing correlation data from a backup humidity sensor.

Technical advantages and potential variations include subnetwork partitioning, where sensors are grouped into functional clusters that can be turned on or off depending on process phases; machine learning methods using reinforcement learning with Q-learning or policy gradients, or bandit models with Thompson sampling for dynamic sensor sampling decisions; predictive maintenance synergy, where the system's predictive maintenance engine can feed sensor reliability estimates to the subnetwork manager; edge vs. cloud implementation options; and fail-safe mechanisms that trigger full or partial reactivation of previously idled sensors if the manager's reduction in sensor coverage causes intolerable uncertainty spikes.

The adaptive sensor “subnetworks” and power management strategy described offers a holistic, AI-driven methodology to balance data fidelity with energy efficiency in semiconductor manufacturing. By continuously estimating the marginal utility of each sensor's measurements, factoring in both local wafer risk profiles and broader economic considerations, and implementing closed-loop calibration to prevent reliance on drifting sensors, the system ensures that only the most impactful data streams are prioritized at any given time. This flexible, context-aware solution reduces overall operational costs, extends sensor lifespans, and maintains robust wafer quality and yield—particularly in large-scale or rapidly evolving manufacturing environments.

The adaptive semiconductor process control system described herein is applicable to a variety of modern semiconductor manufacturing scenarios, offering enhanced efficiency, precision, and scalability. Its advanced integration of AI-driven optimization and real-time adaptability addresses complex challenges in production, making it suitable for diverse implementations and enabling significant performance improvements.

The system can be implemented in large field lithography optimization, where it enhances precision and uniformity across expansive fields by dynamically adjusting field sizes, correcting overlay errors, and compensating for thermal variations. In multi-layer process control, the system supports the precise alignment and dimensional stability required across multiple wafer layers. This capability is especially critical for advanced manufacturing processes that demand consistency across complex, multi-step workflows. The system is also well-suited for advanced packaging applications, including wafer-level packaging and three-dimensional integration, where high-resolution control is necessary for compact, multi-layer designs. Real-time compensation and just-in-place measurement strategies ensure the system meets these demanding requirements.

In high-volume manufacturing environments, the system improves production throughput by optimizing process cycle times and maximizing equipment utilization. Its adaptive exploration strategies allow manufacturers to maintain high output without compromising quality, supporting large-scale semiconductor fabrication facilities. For mixed technology node processing, the system can dynamically adjust process parameters to accommodate varying device requirements, enabling efficient management of diverse product lines using shared equipment. Additionally, in flexible manufacturing systems, the system facilitates rapid reconfiguration of processes, allowing manufacturers to produce a variety of devices with minimal downtime. By leveraging its knowledge graph integration and AI-driven adaptability, the system enables efficient transitions between product types while maintaining quality and consistency.

In an embodiment, the previously described multi-expert AI system (integrating wave-based thermal modeling, advanced stress/strain analysis, RL-driven optimization, and multi-scale data fusion) can be extended to improve modularity, composability, and interoperability in semiconductor packaging—particularly for chiplet-based designs, composable chiplet stores, and fully automated EDA pipelines. This embodiment references challenges mentioned by industry leaders (Amkor, ASE, Promex, Synopsys Photonics) and shows how an AI-driven approach can streamline the creation of a true “chiplet ecosystem” with standardized, automated EDA solutions.

The diverse and evolving packaging needs arise as AI accelerators, next-gen photonics, and large 2.5D/3D modules demand flexible integration of multiple dies (processor, photonics, memory, RF, etc.). Each domain—such as optical I/O, high-bandwidth memory, or specialized compute—may come from different vendors with varying process technologies. Despite initiatives like UCIe (Universal Chiplet Interconnect Express) or AIB (Advanced Interface Bus), true interoperability remains limited, and designers struggle to create “reusable” chiplets because each has unique power/thermal/photonic constraints. Standard “off-the-shelf” chiplets or partial IP blocks must integrate seamlessly in advanced packages. A fully automated EDA pipeline—managing everything from floorplanning, multi-physics simulation, to final signoff—reduces time-to-market, while AI-driven design assists in bridging the gap between diverse chiplets, advanced packaging constraints, and reliability goals.

The technical framework incorporates AI modules from the core system. The thermal wave and stress/strain expert's previously described wave-based thermal modeling and advanced mechanical warpage analysis now factor into standard package templates, helping identify how a new chiplet will behave thermally and mechanically in a well-defined 2.5D or 3D package environment. Multi-modal and Titans memory features Mirasol3B-based chunking for time-aligned sensor data plus contextual design data, while Titans-based long-term memory at test time enables the system to store previous successful packaging recipes or floorplans in the “Chiplet Store” knowledge base. The reinforcement learning (DeepSeek-R1) system tries different floorplans, interposer designs, co-packaged optics alignments, etc., receiving feedback from an internal “cost/yield performance” reward function. Over time, the pipeline “learns” which chiplet configurations yield optimal power, mechanical stability, signal integrity, and cost.

The Composable Chiplet Store (CCS) serves as a catalog of modular chiplets where chip vendors can register “chiplet IP” in a standardized format. Each entry includes UCIe or AIB interface specs, thermal/power profiles, optical waveguide alignment guidelines (if photonic), and mechanical attach specs. The system features automated compatibility checking, where upon selecting two or more chiplets from the CCS, it automatically checks I/O compliance, pin assignment collisions, and potential warpage conflicts. The “wave-based thermal expert” and “stress/strain model” run quick multi-physics simulations to see if the combined heat load or mechanical stack is feasible. The store includes “reference package layouts,” focusing on commonly used layer counts, line/space constraints, or optical coupling approaches. Users can start from a known reference, then the pipeline tailors it to the chosen chiplets.

The hierarchical EDA flow encompasses system-level floorplanning where the AI engine arranges chiplets on an interposer or in 3D stacks, respecting height constraints, waveguide alignment for photonics, and large HPC SoC heat zones. If a chiplet belongs to “Mask Specialist” or “Layer Expert,” the pipeline integrates that domain knowledge. In-depth packaging analysis automates 2.5D or 3D route planning, warpage and stress checks, thermal wave simulation, and real-time design rule checks for mechanical reliability. The final implementation outputs a “Package Assembly Design Kit” (PADK) that includes BOM for package substrate layers, precise XY coordinates of each chiplet or optical fiber attach area, and definition of alignment features and coupling strategies.

Integration of photonic co-packaging addresses optical I/O, where the pipeline can route photonic waveguides in the interposer, checking alignment sensitivity and thermal drift. If the selected chiplet is a “silicon photonics transceiver,” the system references known param libraries to validate feasible waveguide offsets. Temperature and warpage considerations ensure that high-power chips do not degrade photonic coupling beyond acceptable thresholds. The pipeline attempts alternative floorplans if simulations predict unacceptable misalignment under load. Multi-stage RL using DeepSeek-R1 style methods tries multiple arrangement heuristics, awarding higher “rewards” if alignment and yield remain stable across predicted thermal cycles.

The benefits of the modular AI-driven approach include accelerated packaging innovation through reduced customization overhead and automated, composable EDA. The system provides standardized chiplet specs and reference package templates, mitigating photonics or advanced AI device complexities, while the AI pipeline quickly explores design permutations. Traditional packaging flows rely on ad-hoc or manual integration, but here an orchestrated pipeline uses consistent param data from the “Chiplet Store,” bridging design, analysis, and signoff within a single environment.

Lower NRE and high interoperability are achieved through ecosystem growth, where more vendors can publish chiplets to the store, trusting that standard UCIe or advanced photonics interfaces will “just work.” The system's wave-based modeling and stress/strain checks help ensure final assemblies pass reliability constraints. Dynamic reusability allows memory chiplets or analog/RF front-ends to be swapped for improved versions if the pipeline's AI sees minimal re-qualification overhead, while the AI system re-checks that updated chiplet specifications remain within reference template constraints.

Enhanced reliability and performance are achieved through multi-physics at scale, where the wave-based approach identifies hotspots and the stress/strain sub-model ensures mechanical integrity. RL optimizations converge on robust solutions that conventional EDA might miss. Real-time updating through Titans memory stores all prior package configurations, analyzing how certain chiplets or topologies fared in production or field returns, and over multiple cycles, the pipeline refines design heuristics.

The example usage flow demonstrates how a mid-size semiconductor startup might combine custom HPC die, photonics transceiver chiplet, and HBM memory chiplet. The process includes importing chiplets, AI-driven floorplanning, automated EDA, final signoff, and deployment with feedback. The system runs multi-physics checks, tries different layouts, auto-generates substrate stack-ups and route planning, and exports manufacturing drawings and a Package Assembly Design Kit. Real in-fab measurements feed back into the system, updating Titans memory for future designs.

In conclusion, by integrating advanced AI-based modeling, reinforcement learning for dynamic multi-objective optimization, long-term “Titans memory,” and Mirasol3B-like multimodal chunking, the system extends prior ideas to enable a composable chiplet ecosystem and fully automated EDA pipelines. This addresses standardization gaps through interoperability, complexity through automated multi-physics checks, and scalability through Titans memory and RL. This vision accelerates packaging innovation—particularly for AI, HPC, and photonics—by providing an AI-driven, modular approach that can keep pace with rapid changes in advanced packaging, chiplet integration, and system-level standardization efforts. The performance of the system is reflected in both throughput and quality metrics. Throughput improvements are achieved through enhanced wafers-per-hour output, reduced process cycle times, and improved equipment utilization. The system also enhances qualification efficiency by automating adjustments and aligning operations with predefined standards. Quality is maintained through superior edge placement accuracy and critical dimension control, achieved by integrating topology-aware sensor fusion and real-time compensation techniques. By minimizing defects and maintaining consistent process windows, the system reduces defect density and ensures stable yields, even under varying operating conditions. Yield stability is further enhanced by reducing variability and rework rates, as the system minimizes errors during initial processing, resulting in lower costs and greater efficiency.

According to another aspect of an embodiment, this introduces a specialized sensor orchestration layer (SOL) that coordinates sensor usage dynamically, optimizing power consumption and preserving measurement fidelity in high-density semiconductor process environments. The SOL integrates seamlessly with existing AI-driven control platforms, providing real-time decisions on sensor activation, calibration schedules, and data quality validation. It resides between the sensor array and the main data processing layers, enabling flexible and context-aware adjustments of sensor states. A hierarchical gating mechanism is employed to systematically regulate sensor activity. At the lowest level, individual sensors include hardware support for multiple power states (e.g., partial read, idle, deep sleep). The SOL controls these states on a per-sensor basis, allowing fine-grained power savings when full sampling is unnecessary. At a mid-level, sensors are grouped into functional clusters (e.g., thermal, chemical, alignment), so that entire clusters can be throttled or suspended when real-time process models indicate stable conditions. At the top level, global policy dictates overall gating based on broader fab scheduling, batch processing stages, and energy constraints. This multi-tiered approach ensures that minimal sensor coverage is maintained during idle or predictable phases, while more sensors are activated only when critical operations demand high-resolution data. Ensuring accurate measurements in a highly dynamic fab environment is challenging, especially as sensors drift from environmental stressors or repeated usage cycles. The subsystem uses real-time drift detection based on cross-correlation among overlapping sensors and particle filter-style state estimation. If one sensor diverges significantly from its expected range or from reference sensor data, the SOL flags possible drift. Local corrective actions (e.g., offset adjustments) can be applied automatically without halting the process. In cases of larger or multi-sensor deviations, the subsystem schedules partial or global calibrations. This approach leverages hardware references and established calibration standards while minimizing production downtime, thus preserving wafer throughput and data integrity.

Reinforcement Learning for Sensor Orchestration is core to this invention through its application to optimize sensor gating and calibration over time. A custom reward function balances energy reduction, measurement quality, and yield performance, incentivizing the system to discover gating patterns that minimize power usage without degrading critical measurements. The RL policy refines itself by exploring different gating intensities, calibration intervals, and sensor cluster activations, receiving feedback from final yield statistics or detection accuracy. Over successive manufacturing runs, the policy converges on gating strategies that yield notable power savings yet maintain the measurement fidelity demanded by advanced process control algorithms.

The SOL collaborates closely with domain experts such as wave-based thermal modeling, stress/strain analysis, and yield monitoring. For example, if wave-based thermal analysis detects steady-state conduction, the subsystem is free to idle or downsample certain thermal sensors to conserve power. Conversely, when real-time models predict potential warpage or overlay misalignment, the SOL reactivates the relevant sensors or raises sampling frequency in localized regions of concern. Yield monitoring modules can track defect rates and relate them back to gating decisions, helping refine RL policies if insufficient sensor data correlates with missed detection of process faults. This bidirectional synergy ensures the subsystem's gating and calibration moves respond directly to the nuanced, evolving demands of each process phase.

By selectively powering sensors according to real-time manufacturing requirements, this subsystem can achieve significant reductions in total sensor power consumption. Automated, on-the-fly calibration prevents data quality degradation from drift without requiring extensive process downtime. Through multi-modal data sharing, the AI-driven platform maintains robust coverage for critical steps, preventing yield losses or missed anomalies. The scalable nature of the SOL design accommodates future expansions in sensor count, new sensor types, or multi-physics measurement arrays, making it adaptable to next-generation semiconductor processes like co-packaged optics, 3D stacking, and advanced packaging.

A typical deployment includes edge microcontrollers that switch sensors between different power states, responding to real-time gating signals from a central AI orchestrator. High-bandwidth fab networks ensure sensor data arrives promptly where needed, while the orchestrator uses integrated RL logic and knowledge graph data to finalize gating or calibration orders. Operators can observe sensor health and calibration status through a dedicated diagnostics interface, overriding the system if manual intervention or advanced re-check is required. Notably, the subsystem supports incremental updates, meaning it can gradually incorporate or retire sensor nodes as process flows evolve or new equipment is brought online.

The intelligent sensor orchestration subsystem addresses critical challenges by unifying energy efficiency, measurement accuracy, and adaptive calibration within a single AI-driven solution. Its hierarchical gating strategy, guided by real-time drift detection and reinforced by advanced learning algorithms, ensures that large sensor arrays remain responsive yet power-conscious. By integrating this subsystem into broader multi-expert semiconductor control architectures, fabs can significantly reduce operational costs, streamline calibrations, and maintain high-quality data essential for next-generation manufacturing processes. Next is a comprehensive technical embodiment describing how wafer-level “smart tags” enable real-time identification, data capture, and lifecycle tracking within a semiconductor manufacturing environment.

In one embodiment, the semiconductor manufacturing control system incorporates wafer-specific “smart tags” to facilitate continuous identification, data logging, and process orchestration as each wafer progresses through multiple fabrication steps (e.g., lithography, etch, deposition, or bonding). Unlike conventional barcodes or RFID labels limited to static readout, these smart tags employ ultra-thin, flexible electronics or specialized RFID-like chipsets with writable memory and short-range wireless communication capabilities. The tags can store wafer identity, station-specific process history, sensor signatures, and next-step instructions, establishing a micro-level feedback loop for real-time updates. By placing the smart tag on or near each wafer (e.g., on the backside or along the periphery), the invention ensures localized data persistence and secure traceability, even when wafers move between disparate tools or fabs.

A principal component of this embodiment is the “smart tag module,” composed of lightweight, flexible electronic layers bonded to the wafer surface or integrated into a protective coating. The module features non-volatile memory (e.g., EEPROM or flash) and a low-power wireless transceiver (NFC, Bluetooth Low Energy, UHF RFID, or similar). In some configurations, tags draw power inductively from the tool's field—e.g., via near-field communication (NFC) coils—or from miniature integrated batteries rechargeable at each station pass. Because semiconductor handling imposes constraints on thickness and thermal tolerance, the tag substrate is designed to withstand repeated thermal cycles, chemical exposure, and mechanical stress. The memory capacity of each tag may range from a few kilobytes to several megabytes, sufficient to store essential wafer parameters, partial sensor logs, and future recipe instructions. Optionally, a minimal sensor suite could be embedded directly on the tag (e.g., temperature or humidity sensor) for redundancy in detecting environmental extremes.

During each station pass (e.g., as the wafer enters a lithography tool or an inspection stage), the tag wirelessly exchanges data with a local station reader or the main control system. This exchange can occur through near-field or short-range protocols, including but not limited to ISO/IEC 14443 NFC or custom low-power RFID channels. The station software retrieves stored wafer identifiers, checks the most recent process data (e.g., overlay errors, measured thickness, doping levels) and writes updated instructions for subsequent steps. For example, if the wafer requires a specific reticle alignment offset based on prior inspection results, that offset is pre-loaded onto the tag. Once the wafer arrives at the next tool, the equipment interface automatically reads those instructions, customizing its operating parameters without manual operator intervention. This handshake approach ensures synchronization of wafer-specific details (e.g., cycle count, last known temperature spike) in near real time, maintaining consistency across different tools in a large-scale fab.

The system's knowledge graph stores long-term relationships and hierarchical process flows for each wafer. At each station, the manufacturing control software or local station reader sends the wafer's newly acquired data to the knowledge graph. For instance, if the wafer's overlay alignment measured 3 nm deviation above nominal, that numeric value is appended to the wafer's data node in the graph. Simultaneously, the tag's onboard memory receives a compressed or partial record of that same event, creating a local copy. In one exemplary workflow: The tool logs station metrics (overlay error, temperature profile, chemical usage) both into the knowledge graph and onto the wafer's tag memory. If the wafer is flagged for recipe adjustments (e.g., adjusted exposure time in the next station), those instructions are uploaded to the tag. A background synchronization routine ensures consistency between the wafer tag's local data and the knowledge graph, even if network connectivity at certain stations is intermittent. Because each wafer physically carries its own “traveling data log,” any station can retrieve critical historical details even if communication with the central database is temporarily disrupted. Once reconnected, the station re-synchronizes with the knowledge graph, preventing data loss or version conflicts.

This embodiment also enables dynamic, per-wafer recipe adaptation. As soon as station N completes its process, the system evaluates the wafer's newly captured metrics (e.g., local thickness uniformity). If a subsequent station N+1 is known to require specific alignment or doping parameters, the UCT optimization subsystem calculates recommended adjustments based on real-time conditions and writes them into the wafer's smart tag. Consequently, when the wafer arrives at station N+1, the tool reads the instructions and applies them immediately—bypassing the need for the tool to request data from a central server. This approach can significantly reduce overhead and decrease the potential for errors introduced by network latency or miscommunication, while guaranteeing that wafer-specific nuances are preserved, even across shifts or multi-fab transfers.

By storing an end-to-end record of wafer process history, sensor signatures, and final outcomes (e.g., post-dicing yield or binning results), the system supports high-level correlation analysis. For instance, after final electrical testing and burn-in, the knowledge graph can trace back how particular overlay or doping metrics recorded on the wafer's tag correlate with the wafer's ultimate performance class. Over time, the AI-based model management subsystem refines its predictive accuracy, leveraging these cross-step correlations to preempt known failure modes in wafers exhibiting similar sensor patterns. As part of this iterative improvement cycle, future wafers can receive more targeted instructions, culminating in higher yield and reduced rework or scrap. Additionally, by linking each wafer's unique journey to final reliability or performance data, fab engineers can pinpoint root causes of systematic drift or batch-level anomalies.

A key advantage of per-wafer tagging with advanced writable memory is the potential for robust supply chain security. The system optionally integrates blockchain or distributed ledger technology to cryptographically record each wafer's manufacturing steps, equipment usage, and final test results. If a wafer is produced in a secure foundry environment, each major milestone (e.g., completion of lithography, doping, final test) can be hashed and added to an immutable ledger. When the wafer eventually leaves the fab or is handled by downstream assembly/test providers, the ledger ensures that no sub-par or counterfeit wafers are inserted undetected. The onboard smart tag can store a reference pointer or short cryptographic proof that ties the wafer's local data to the blockchain record. As a result, downstream customers—such as integrated device manufacturers (IDMs) or OEM partners—can verify the authenticity and chain of custody. In high-security contexts (e.g., military or cryptographic chips), this robust traceability provides a significant deterrent to tampering or illicit wafer swaps.

Smart tags in a semiconductor environment face stringent thermal, chemical, and mechanical exposures. Accordingly, the disclosed embodiment may employ encapsulation techniques—such as polymer coatings or thin ceramic shells—to protect the tag's circuitry. Some versions use anisotropic conductive adhesives or ultrasonic bonding to attach the tag near the wafer edge, minimizing interference with photolithography or bonding areas. If required, the smart tag may be positioned off the main wafer surface, for example on a wafer carrier or frame, provided that tracking software ensures it remains physically associated with its corresponding wafer at all times. Additional safety checks confirm that each wafer's ID in the central system matches the ID stored on the tag, avoiding mismatches during carrier swaps.

Because the smart tag continuously updates wafer status, operators gain immediate visibility into wafer state at any station. A handheld or station-based reader can show a dashboard that includes wafer ID, last process step, sensor anomaly flags, and next-step instructions. If an engineer manually inspects a wafer or reassigns it to a different process queue, they can update the wafer's tag with reason codes or notes (e.g., “Minor defect found in layer 2, proceed with rework”). The station software then pushes this override to the knowledge graph to maintain global consistency. Through this tight coupling of physical and digital data, the system reduces the frequency of human error (e.g., selecting the wrong lot for a high-value device run) and streamlines process flows.

In very high volume fabs handling tens of thousands of wafers daily, the aggregate data stored on each wafer's tag can become extensive. To address these concerns, the system implements several key strategies. Compression & Rolling Logs allow the system to store compressed snapshots or rolling event logs on the tag, retaining only the most recent or critical steps, while the entire history remains accessible in the knowledge graph. Data Drop Strategies ensure that non-essential data (e.g., certain intermediate sensor reads) might be pruned once it has been mirrored in the central database, preserving only summary statistics. For Edge Cases, if a tag becomes damaged or unreadable, station tools can fall back on the global knowledge graph for wafer identification, and re-tagging procedures can restore in-line tracking after verifying the wafer's unique ID.

The implementation variations encompass several important features. Encrypted Communications ensure that for sensitive processes, tags and station readers exchange data with encryption and authentication handshakes to safeguard IP or manufacturing secrets. The system supports both Passive vs. Active Tags, where passive tags draw energy solely from station fields, while active tags integrate small batteries or supercapacitors, enabling extended read/write range and advanced local logging between stations. Multi-Fab Coordination allows that if wafers are transferred between different geographical fabs, the knowledge graph can unify data from all sites, while the wafer tag physically carries essential data to new locations for immediate tooling reference. Scoring & Risk Indicators enable the wafer's tag to store real-time “risk indices” or “anomaly scores” generated by the AI, guiding subsequent stations to apply extra caution or specialized doping or alignment measures.

By optionally attaching ultra-thin, writable smart tags to each wafer and maintaining synchronous updates with a central knowledge graph, the disclosed system ensures an unbroken chain of wafer-specific data throughout the entire lifecycle—from initial lithography through final test. This approach not only provides rapid station-to-station customization of recipes but also enables advanced yield analysis via continuous end-to-end traceability. Further, the optional integration of secure ledger technologies protects against counterfeit or sub-quality wafers, enhancing overall supply chain integrity. The result is a robust, future-proof solution for real-time wafer management and lifecycle analytics in modern semiconductor production. Next is another embodiment detailing a modular “app store” architecture for integrating third-party process control extensions into a semiconductor manufacturing platform. The paragraphs provide an extensive description of APIs, containerization strategies, validation protocols, marketplace governance, and interoperability standards.

In one embodiment, the semiconductor process control system includes a modular “app store” framework designed to allow third-party developers and solution providers to integrate specialized modules—ranging from optimization heuristics to advanced sensor analytics—into an existing manufacturing control platform. This enables a broad ecosystem of innovation: foundries can easily install and update third-party modules for tasks such as EUV overlay optimization, advanced logic node defect detection, or real-time 3D packaging analysis. The platform's core architecture supports containerization, robust APIs, and a secure validation pipeline, ensuring that new modules integrate seamlessly without compromising system reliability or intellectual property (IP) security.

The system exposes a standardized application programming interface (API) that serves as the gateway for all third-party modules. This API includes endpoints for querying real-time sensor data, submitting optimization proposals, fetching wafer state estimates, and writing back recommended control parameters. In certain embodiments, the API is defined using widely accepted interface specifications such as REST/JSON, gRPC, or industry-specific protocols (e.g., SEMI EDA/Interface A) for equipment integration. To isolate third-party code and manage resource allocation, each module is packaged as a lightweight container (e.g., Docker or an OCI-compliant container). The container encloses the module's runtime environment—comprising libraries, dependencies, and custom logic—ensuring reproducible deployment. A container orchestration layer, such as Kubernetes or another distributed computing framework, is responsible for instantiating, scaling, and monitoring these module containers. When the system boots or a new module is introduced, the orchestrator fetches the container image from a secure repository, validates its integrity (e.g., via cryptographic checksums), and then deploys it on a suitable compute node within the fab's network infrastructure. The orchestrator monitors resource usage, ensuring modules do not inadvertently starve mission-critical tasks of CPU, memory, or GPU resources.

Each containerized module interacts with the system's data integration subsystem and knowledge graph through the aforementioned core API. For instance, a “Defect Classification” module might request wafer-edge optical data, overlay alignment metrics, or historical yield patterns from the knowledge graph, then apply its proprietary machine learning pipeline to detect anomalies. After processing, it can post results back into the knowledge graph for consumption by the UCT optimization engine or other modules. By relying on uniform data exchange protocols, modules are effectively sandboxed and do not directly manipulate shared data structures. Instead, they make API calls that the platform logs and audits for reliability. Optionally, modules can subscribe to “event streams,” receiving push notifications whenever relevant sensor data or wafer states change (e.g., after each lithography step). This event-driven architecture enables real-time responsiveness while still enforcing boundary separation for security and stability.

Because multiple modules can run in parallel, the system employs an internal scheduling or conflict-resolution mechanism to handle conflicting suggestions or parameter sets. For example, if two modules recommend different scanning speeds for the same wafer region, the system's decision aggregator evaluates the credibility, confidence, or cost-benefit weighting of each recommendation before finalizing the applied parameter. The aggregator can use an ensemble approach, voting strategy, or hierarchical priority scheme. Foundries can configure these decision logic policies to align with internal engineering goals. Over time, modules may collect feedback regarding how often their suggestions were adopted and how effectively they reduced defects or increased yield, creating a continuous improvement loop that fosters competition and innovation among third-party plug-ins.

Before a new module is installed in a live fab environment, it undergoes a two-tier validation process. First, there is an offline sandbox environment, often a data simulation platform or “digital twin” environment, which replays historical wafer runs or synthetic data sets. The prospective module is tested on relevant scenarios (e.g., different node technologies or wafer types) to confirm performance, stability, and compatibility with the platform's data schemas. Any abnormal memory usage, timing violations, or spurious parameter overrides are flagged for developer correction. Second, after passing sandbox tests, the module may be deployed in a limited production pilot, running side-by-side with existing modules. During this pilot, real wafer data is provided but the module's recommended control signals are initially labeled “advisory” to the main system. If observed performance meets or exceeds certain thresholds (e.g., yield improvement, defect reduction), the module is promoted to full operational status.

In some embodiments, the system provides multiple sandbox “tiers.” A “simulation sandbox” uses purely historical data, letting modules replay thousands of prior wafer runs in compressed timescale. A “shadow mode sandbox” provides real-time data streams from the production line, but the module's outputs do not affect actual equipment. The platform logs differences between the module's suggestions and the production control signals, assessing alignment, potential improvements, or detrimental divergences. This two-level approach ensures that by the time a module is used actively in production, it has already demonstrated safe and beneficial performance under varied conditions.

The “app store” or marketplace layer manages publication, installation, and licensing of modules. Module developers upload container images and accompanying metadata (e.g., version, supported processes, baseline performance metrics) to a secure registry. Foundry owners access a marketplace interface to browse or search for modules based on keywords (e.g., “EUV overlay,” “3D packaging simulation”). To install a module, an authorized user (e.g., a fab manager) selects it and triggers an automated deployment workflow. The system verifies the module's digital signature or certificate to confirm authenticity and check for tampering. If trust criteria are satisfied, the orchestrator pulls the container image, performs offline sandbox tests if required, and then stands up the module in a restricted environment. This approach ensures that no unverified code can run in the fab, safeguarding proprietary process data and the reliability of mission-critical operations.

A significant feature of this marketplace architecture is the potential for new revenue streams for both the foundry and the module developers. By enabling a licensing model, advanced modules can be offered on a subscription or usage-based fee. For example, a specialized “Advanced Multi-Layer Overlay Correction” module might charge per wafer-lot usage, or monthly access fees, or success-based royalties proportionate to yield improvement. The system can track usage metrics (e.g., how many wafer-lots utilized the module, how many times its recommendations were adopted) and compile usage logs in a tamper-evident ledger. This fosters a robust ecosystem in which third-party researchers, equipment vendors, and software specialists can continuously enrich the fab's capabilities without each foundry needing to develop all functionalities in-house.

A further novelty of the disclosed approach is its emphasis on standardized protocols (e.g., SEMI EDA, OPC UA, or other relevant industry frameworks) for data exchange and equipment interfacing. This openness allows a wide contributor base—including sensor manufacturers, academic labs, and specialized software vendors—to develop modules that plug into the system's data integration and knowledge graph. The container-based deployment ensures modules remain portable across different hardware setups or cloud-edge combinations. Foundries can horizontally scale compute resources to accommodate multiple advanced modules analyzing large volumes of sensor data in near real time, thus supporting expansions into next-generation processes without a fundamental system overhaul.

In multi-fab scenarios, the marketplace can be shared across geographically distributed facilities. This allows best-in-class modules—perhaps developed in collaboration with academic research groups or specialized AI startups—to be tested in one fab and then deployed at scale in other sites if results are promising. The knowledge graph federation ensures that local data compliance rules are respected; only aggregated or anonymized performance metrics might be shared globally. Each fab can maintain autonomy in choosing which modules to install, with the marketplace promoting overall standardization while preserving local customizations.

Because third-party modules may process sensitive wafer data, security measures are integrated at every level. Container isolation ensures that modules do not have direct file system access to the host or other modules. All external communications with the knowledge graph or sensor streams are encrypted, and identity management frameworks (e.g., OAuth, Kerberos, X.509 certificates) restrict data access to necessary resources only. Furthermore, the marketplace itself can implement IP protection strategies, such as encrypted model files or hardware-based trust enclaves. Module developers may embed run-time checks or obfuscation to prevent reverse engineering, while foundries can require code scanning for potential malicious behaviors before granting production access. The system logs all module interactions with wafer data for subsequent audits, ensuring accountability.

The disclosed “app store” style modular architecture allows semiconductor fabs to quickly adapt to emerging process challenges and leverage specialized third-party innovations without endangering existing operational stability. Containerized deployment, robust API frameworks, tiered sandbox testing, and digital signature governance collectively ensure that each module integrates smoothly, remains secure, and can be licensed under flexible commercial models. This design fosters a vibrant ecosystem where advanced wafer analysis or optimization solutions can be continuously contributed, tested, and seamlessly adopted across multiple lines or fabs, ultimately accelerating the pace of process control innovation in the semiconductor industry. In an embodiment system integrates multiple novel features—e.g. multi-layer sensor integration, advanced power management, distributed edge processing, enhanced security, quantum-resistant algorithms, self-healing capabilities, advanced material design, and process optimization learning—into a next-generation “smart tag” platform. Each section provides detailed enablement and implementation strategies to surpass the prior art, including specific hardware, software, and algorithmic aspects.

In one embodiment, a next-generation “smart tag” is affixed to or embedded within semiconductor wafers for real-time tracking, sensing, and process optimization. Unlike traditional RFID or barcode solutions, the disclosed system integrates microelectromechanical (MEMS) sensors, advanced power management methods, and local computation with robust security. These innovations enable each wafer to self-monitor multiple process parameters, perform local anomaly detection, and cooperate with other wafers and manufacturing stations in a distributed, fault-tolerant manner. By addressing the limitations of current wafer tagging systems (e.g., limited sensor coverage, unidirectional data flow, reliance on external power, or insufficient security), the invention provides enhanced resilience, lowered latency, and improved yield across the entire semiconductor manufacturing lifecycle.

A flexible, ultra-thin substrate (e.g., polyimide or a specially designed polymer-ceramic composite) houses multiple sensor types, all laminated or bonded directly to the wafer surface. MEMS Vibration & Acceleration Sensors include microscale accelerometers and gyroscopes that capture wafer handling vibrations, potential mechanical shocks during transport, and tilt/orientation changes. These readings help predict mechanical stress or alignment errors in subsequent lithography stages. Chemical Residue Sensors comprise integrated chemical sensor nodes (e.g., functionalized micro cantilevers or mini-ion-sensitive field-effect transistors) that detect trace amounts of contaminants. If excessive contamination is sensed, the system flags the wafer for additional cleaning or protective steps. Strain Gauges that are printed or deposited measure mechanical deformation arising from rapid thermal cycling or wafer bowing. These strain signals correlate with stress-induced defects, facilitating real-time interventions (e.g., adjusting temperature ramps). Each sensor has a factory calibration stored in a non-volatile memory block within the tag. A calibration manager routine adjusts sensor offsets if the wafer undergoes repeated thermal or mechanical stresses. Sensor fusion algorithms running locally or at station-level controllers integrate vibration, chemical, and strain data to generate a composite wafer “health” metric. These composite metrics feed into the knowledge graph, enabling downstream AI modules to refine overlay corrections or doping parameters.

The disclosed power management subsystem encompasses multiple scavenging sources: radio-frequency (RF) harvesting from station emitters, thermal energy harvesting from wafer temperature gradients, and piezoelectric harvesting from mechanical vibrations. A software class orchestrates dynamic allocation and usage of these sources: class SmartTagPower: def init(self): self.energy_harvesting_sources={‘rf’: RFHarvester( ), ‘thermal’: ThermalHarvester( ), ‘piezo’: PiezoHarvester( )} self.power_states=[‘sleep’, ‘low_power’, ‘active’, ‘burst’] def optimize_power(self, sensor_data, process_stage): if process_stage.requires_continuous_monitoring: return self.power_states[2] return self.calculate_optimal_state(sensor_data).

The system implements Multi-Level Power States, where Sleep mode maintains minimal power draw with only essential circuits remaining active, suitable when wafer is in idle storage; Low Power mode enables periodic sensor polling, used when the wafer is transiting between stations and no critical event is anticipated; Active mode engages full sensor engagement and local processing to detect anomalies in real time; and Burst mode provides short-duration, high-power mode reserved for tasks like local neural network inference or large data transmissions. The system monitors the wafer's environment (e.g., approaching a high-risk lithography step or post-etch cleaning) to decide if continuous monitoring is required. If so, it remains in “Active” mode. Otherwise, it periodically reverts to “Low Power” or “Sleep” to conserve energy. The power manager also takes input from the MEMS sensors (e.g., sudden vibration spike might trigger immediate re-entry into “Active” mode to diagnose potential mechanical damage).

A microcontroller or low-power FPGA integrated on the smart tag hosts a compact neural network (NN) or other ML model that processes critical sensor data in real-time. Examples include a small CNN for pattern recognition in strain waveforms, or a recurrent neural network for time-series anomaly detection (e.g., sudden changes in chemical residue levels). Memory-optimized quantization techniques or binarized neural networks (BNNs) minimize computational overhead, enabling local inference with minimal energy consumption. Neighboring wafers can form an ad hoc mesh network, exchanging partial inference results or sensor signals. For instance, if multiple adjacent wafers sense correlated thermal anomalies, the distributed system can refine detection confidence or pass the aggregated signal upstream. This approach reduces the dependency on centralized controllers. Even if network connectivity to the main fab system is temporarily lost, local cooperation among wafers may continue to identify potential yield threats (e.g., unusual vibrations caused by a misaligned transporter). By conducting anomaly detection locally, the wafer does not wait for a round trip to the central knowledge graph or station-level HPC. This immediate response is critical in detecting fast transient events (e.g., momentary mechanical shock). The local microcontroller includes a fallback routine: if a wafer's tag is partially damaged, it relays data to adjacent wafers, ensuring continuity of monitoring.

A specialized secure protocol class orchestrates encryption and authentication: class SecureTagProtocol: def init(self): self.encryption=AESEncryption( ) self.authentication=ZeroKnowledgeProof( ) def secure_handshake(self, station_id): challenge=self.generate_challenge( ) response=self.station_authenticate(station_id, challenge) return self.verify_response(response). Stations must pass a zero-knowledge proof sequence before reading or writing data to the wafer's memory. This ensures only authorized equipment can access or modify wafer parameters.

The system optionally includes lattice-based cryptography (e.g., NTRU, CRYSTALS-Kyber) to mitigate risks posed by future quantum computers. Key exchanges and digital signatures use post-quantum schemes to prevent interception or forging of wafer data as cryptographic capabilities evolve. The tag features a secure enclave or physically unclonable function (PUF) module for hardware-level key generation. This PUF ensures that each wafer's identity is unique and tamper-resistant, preventing counterfeiting or duplication.

The wafer tag stores data across multiple flash or EEPROM partitions, each with built-in error-correction coding (ECC). If one bank shows unrecoverable errors, the system automatically fails over to a secondary partition, preserving the wafer's process history. The firmware's self-diagnostic routine periodically scans memory, re-mapping bad blocks and applying advanced ECC to slow or reverse data corruption from harsh fab environments. Self-diagnostic circuitry checks sensor calibration drift, power subsystem performance, and memory integrity. If any subsystem is out of tolerance, a partial reconfiguration process attempts to isolate the fault (e.g., disabling a defective sensor array) while preserving minimal functionality. The tag logs these events locally and flags them to the fab's knowledge graph so that station operators or AI modules can handle impacted wafers differently. For severe damage, the system can degrade gracefully by deactivating non-critical sensors or compute functions. For instance, if one side of the wafer or tag is physically cracked, the microcontroller can isolate that region from the bus, continuing to operate the remainder of the sensor suite.

The tag substrate includes embedded phase-change materials (PCMs) or high-conductivity filaments to buffer against extreme thermal spikes. This stabilizes sensor readings, preventing false positives from short thermal shocks. Radiation-hardening measures such as specialized doping or shield layers protect electronics from plasma or ionizing exposures common in advanced lithography or etch processes. The substrate can incorporate microcapsules containing conductive inks. If a minor crack forms, the microcapsules rupture and flow into the damaged area, restoring partial conductivity. A built-in continuity check can detect improved conduction and re-enable that circuit path. Optionally, a multi-layer polymer can provide high tensile strength, ensuring that bending or warping of the wafer does not break tag electronics. Some embodiments use micro-lattice structures to reduce weight and thickness while increasing mechanical resilience.

Each smart tag collects performance data (e.g., sensor readings, final test results) and can participate in a federated learning scheme. Local gradient updates derived from wafer-level experiences are aggregated at station-level or fab-level servers, which update global models without centralizing raw wafer data. This preserves IP and meets privacy constraints. Over time, the system evolves recipe steps (e.g., doping concentration, overlay alignment strategy) based on real-world performance across thousands of wafers. A local reinforcement-learning agent may tune wafer-specific parameters (such as localized heat management or doping exposure time) in collaboration with station instructions. The wafer's tag records reward signals (yield, defect count) for each iteration, enabling iterative improvement in real-time. Genetic algorithms can be deployed to combine “optimal parameter sets” discovered by multiple wafers, evolving better baseline recipes across an entire fab. The aggregated sensor data and final test outcomes feed into an AI-driven yield prediction pipeline. By comparing partial in-process wafer metrics (strain, chemical contamination, micro-circuit alignment) to historical yield records, the system can estimate final pass/fail likelihood early. Operators can thereby intervene or divert the wafer to special rework steps when the risk is too high.

The disclosed invention significantly extends conventional wafer-tagging technology by combining multi-layer MEMS sensors, advanced power management with energy harvesting, robust local intelligence (distributed edge processing), quantum-resistant security protocols, self-healing hardware layers, and AI-based process optimization. These novel features enable real-time, on-wafer decision-making, integrated yield forecasting, and secure chain-of-custody tracking. The architecture is scalable across various node technologies and manufacturing processes, supporting dynamic adaptation to emerging challenges (e.g., extreme ultraviolet lithography, stacked 3D packaging, or ultra-fine doping regimes). By addressing key industry pain points—such as sensor coverage gaps, power constraints, data security, and wafer-level variability—the invention provides an unprecedented level of autonomy and resilience, pushing in-line semiconductor fabrication monitoring and optimization beyond the current state of the art.

In certain embodiments, multiple specialized models—sometimes referred to as a mixture of experts (MoE) —collaborate to handle the complex tasks in advanced semiconductor manufacturing. Each “expert” is a large language model or sub-model fine-tuned to focus on a particular domain: The Mask Management Expert specializes in EUV lithography mask constraints, reticle heat distortion, pellicle management, and focuses on per-layer nuances, mask inspection, and recommended corrections for potential contamination or reflectivity drift. The Layer-Specific Litho Expert optimizes dose, focus, overlay alignment per wafer layer and coordinates partial corrections on alignment marks, field expansions, and scanning speeds. The Metrology & Inspection Expert ingests real-time data from critical dimension (CD) measurements, overlay checks, and optical inspections, and provides early warnings on feature-size drift or overlay anomalies that might compromise yield. The Thermal Wave & Heat Transfer Expert models advanced wave-based thermal phenomena (“second sound”) across multi-die stacks and wafer-level micro-interfaces, integrates diffusive vs. wave-based modes depending on local geometry and quantum-scale device features, and handles multi-scale thermal analysis spanning quantum-scale conduction through package-level fluid cooling. The Stress/Strain & Deformation Expert predicts mechanical warpage, stress concentrations, and potential micro-cracking during advanced packaging steps (e.g., 3D stacking, TSV creation) and integrates fluid-structure interactions (FSI) for cooling systems or chemical flows affecting wafer stress. The Yield Monitoring & Predictive Analytics Expert analyzes real-time yield metrics, scrap rates, process variation trends and projects potential risk factors for upcoming steps based on historical defect clusters.

The system can implement either a Single Model with Nested Experts (a large LLM architecture that internally routes queries to specialized “experts” for thermal, litho, etc., akin to a mixture-of-experts layer) or Separate Expert Models (multiple discrete LLMs, e.g., one per domain, that exchange partial intermediate outputs, which may reduce confusion between domains while maintaining domain-specific fine-tuning). Either approach (or a hybrid) can be used, depending on fab constraints and HPC availability. In some advanced materials (e.g., quantum-scale devices, certain 3D packaging stacks), heat propagates like a wave instead of purely diffusive conduction. The “Thermal Wave Expert” model processes wafer-level sensor data to detect these zones. Dynamic Region Identification allows the model to classify areas that require wave-based modeling vs. classical diffusion. For instance, at the interface of a high thermal conductivity layer and a vacuum or near-vacuum region, wave-based methods are triggered.

The system implements Multi-Scale Physics Integration across different scales: At the Quantum Scale, it captures electron transport and local heat generation in extremely small nodes (e.g., sub-2 nm or below) and predicts localized hotspots due to quantum effects in transistors. At the Mesoscale, it tracks wave propagation through stacked dies (e.g., in a 3D SoIC-X package) and evaluates interface material properties, thermal boundary resistances, wave reflection at layer boundaries. At the System-Level, it monitors package-level heat flow to external cooling solutions (liquid cooling, conduction plates) and merges fluid-structure analysis to see how coolant flow or vapor chambers affect overall heat distribution. During steps like ALD or advanced etch, the “Thermal Expert” might propose adjusting chamber temperature profiles or pulsing sequences if wave-based hotspots risk material damage, while the “Mask Management Expert” cross-checks local mask heating with the wave-based thermal model to avoid reticle distortion.

The system optionally includes lattice-based cryptography (e.g., NTRU, CRYSTALS-Kyber) to mitigate risks posed by future quantum computers. Key exchanges and digital signatures use post-quantum schemes to prevent interception or forging of wafer data as cryptographic capabilities evolve. The tag features a secure enclave or physically unclonable function (PUF) module for hardware-level key generation. This PUF ensures that each wafer's identity is unique and tamper-resistant, preventing counterfeiting or duplication.

The wafer tag stores data across multiple flash or EEPROM partitions, each with built-in error-correction coding (ECC). If one bank shows unrecoverable errors, the system automatically fails over to a secondary partition, preserving the wafer's process history. The firmware's self-diagnostic routine periodically scans memory, re-mapping bad blocks and applying advanced ECC to slow or reverse data corruption from harsh fab environments. Self-diagnostic circuitry checks sensor calibration drift, power subsystem performance, and memory integrity. If any subsystem is out of tolerance, a partial reconfiguration process attempts to isolate the fault (e.g., disabling a defective sensor array) while preserving minimal functionality. The tag logs these events locally and flags them to the fab's knowledge graph so that station operators or AI modules can handle impacted wafers differently. For severe damage, the system can degrade gracefully by deactivating non-critical sensors or compute functions. For instance, if one side of the wafer or tag is physically cracked, the microcontroller can isolate that region from the bus, continuing to operate the remainder of the sensor suite.

The tag substrate includes embedded phase-change materials (PCMs) or high-conductivity filaments to buffer against extreme thermal spikes. This stabilizes sensor readings, preventing false positives from short thermal shocks. Radiation-hardening measures such as specialized doping or shield layers protect electronics from plasma or ionizing exposures common in advanced lithography or etch processes. The substrate can incorporate microcapsules containing conductive inks. If a minor crack forms, the microcapsules rupture and flow into the damaged area, restoring partial conductivity. A built-in continuity check can detect improved conduction and re-enable that circuit path. Optionally, a multi-layer polymer can provide high tensile strength, ensuring that bending or warping of the wafer does not break tag electronics. Some embodiments use micro-lattice structures to reduce weight and thickness while increasing mechanical resilience.

Each smart tag collects performance data (e.g., sensor readings, final test results) and can participate in a federated learning scheme. Local gradient updates derived from wafer-level experiences are aggregated at station-level or fab-level servers, which update global models without centralizing raw wafer data. This preserves IP and meets privacy constraints. Over time, the system evolves recipe steps (e.g., doping concentration, overlay alignment strategy) based on real-world performance across thousands of wafers. A local reinforcement-learning agent may tune wafer-specific parameters (such as localized heat management or doping exposure time) in collaboration with station instructions. The wafer's tag records reward signals (yield, defect count) for each iteration, enabling iterative improvement in real-time. Genetic algorithms can be deployed to combine “optimal parameter sets” discovered by multiple wafers, evolving better baseline recipes across an entire fab. The aggregated sensor data and final test outcomes feed into an AI-driven yield prediction pipeline. By comparing partial in-process wafer metrics (strain, chemical contamination, micro-circuit alignment) to historical yield records, the system can estimate final pass/fail likelihood early. Operators can thereby intervene or divert the wafer to special rework steps when the risk is too high.

The disclosed invention significantly extends conventional wafer-tagging technology by combining multi-layer MEMS sensors, advanced power management with energy harvesting, robust local intelligence (distributed edge processing), quantum-resistant security protocols, self-healing hardware layers, and AI-based process optimization. These novel features enable real-time, on-wafer decision-making, integrated yield forecasting, and secure chain-of-custody tracking. The architecture is scalable across various node technologies and manufacturing processes, supporting dynamic adaptation to emerging challenges (e.g., extreme ultraviolet lithography, stacked 3D packaging, or ultra-fine doping regimes). By addressing key industry pain points—such as sensor coverage gaps, power constraints, data security, and wafer-level variability—the invention provides an unprecedented level of autonomy and resilience, pushing in-line semiconductor fabrication monitoring and optimization beyond the current state of the art.

In certain embodiments, multiple specialized models—sometimes referred to as a mixture of experts (MoE) —collaborate to handle the complex tasks in advanced semiconductor manufacturing. Each “expert” is a large language model or sub-model fine-tuned to focus on a particular domain: The Mask Management Expert specializes in EUV lithography mask constraints, reticle heat distortion, pellicle management, and focuses on per-layer nuances, mask inspection, and recommended corrections for potential contamination or reflectivity drift. The Layer-Specific Litho Expert optimizes dose, focus, overlay alignment per wafer layer and coordinates partial corrections on alignment marks, field expansions, and scanning speeds. The Metrology & Inspection Expert ingests real-time data from critical dimension (CD) measurements, overlay checks, and optical inspections, and provides early warnings on feature-size drift or overlay anomalies that might compromise yield. The Thermal Wave & Heat Transfer Expert models advanced wave-based thermal phenomena (“second sound”) across multi-die stacks and wafer-level micro-interfaces, integrates diffusive vs. wave-based modes depending on local geometry and quantum-scale device features, and handles multi-scale thermal analysis spanning quantum-scale conduction through package-level fluid cooling. The Stress/Strain & Deformation Expert predicts mechanical warpage, stress concentrations, and potential micro-cracking during advanced packaging steps (e.g., 3D stacking, TSV creation) and integrates fluid-structure interactions (FSI) for cooling systems or chemical flows affecting wafer stress. The Yield Monitoring & Predictive Analytics Expert analyzes real-time yield metrics, scrap rates, process variation trends and projects potential risk factors for upcoming steps based on historical defect clusters.

The system can implement either a Single Model with Nested Experts (a large LLM architecture that internally routes queries to specialized “experts” for thermal, litho, etc., akin to a mixture-of-experts layer) or Separate Expert Models (multiple discrete LLMs, e.g., one per domain, that exchange partial intermediate outputs, which may reduce confusion between domains while maintaining domain-specific fine-tuning). Either approach (or a hybrid) can be used, depending on fab constraints and HPC availability. In some advanced materials (e.g., quantum-scale devices, certain 3D packaging stacks), heat propagates like a wave instead of purely diffusive conduction. The “Thermal Wave Expert” model processes wafer-level sensor data to detect these zones. Dynamic Region Identification allows the model to classify areas that require wave-based modeling vs. classical diffusion. For instance, at the interface of a high thermal conductivity layer and a vacuum or near-vacuum region, wave-based methods are triggered.

The experts collectively output recommended changes to process optimization subsystem 400. For instance, if the “Thermal Expert” detects a wave-based hotspot in the middle of an EUV scan, it sends partial tokens instructing the “Layer-Specific Litho Expert” to reduce local exposure time or shift scanning steps. When these experts share the same foundation architecture, a baseline model might handle wafer-state input (temperature, alignment data, etc.) and store the resulting low-level KV caches. Each specialized domain LLM (e.g., “Mask Management Expert”) reuses the non-domain-specific caches, only re-computing specialized layers. This reduces prefill latency through less repeated context embedding and supports parallel inference where additional sub-models (stress/strain, yield monitoring) can quickly spin up once the baseline caches are available. Incremental token outputs occur as each expert partially completes an inference step (e.g., partial update to recommended doping or scanning parameters), those tokens get streamed to the next stage (maybe the “Yield Monitor Expert”). This enables faster reaction where if partial data reveals a potential yield risk, the “Yield Monitor Expert” can inject feedback early—without waiting for a full set of tokens—allowing a swift course correction.

The Mask Specialist focuses on reticle temperature uniformity, pellicle integrity, and reflection uniformity. The Layer Specialist optimizes step-and-scan parameters for each wafer layer, tuning focus offsets, exposure dose, and overlay correction. Shared or Nested Experts mean a single litho model can host a “mask sub-expert” and a “layer sub-expert,” or these can be separate micro-models exchanging partial embeddings. The Metrology Monitoring Model ingests real-time measurements from overlay marks, critical dimension (CD) checks, reflectivity sampling, and generates anomaly flags or localized dimension-drift warnings in partial token streams. The “Layer Expert” uses these partial streams to refine local alignment or dose. The Heat/Stress Models include a Thermal Wave sub-model that monitors wave/diffusive transitions, while the Stress/Strain sub-model correlates thermal cycles with potential mechanical warpage or micro-fractures—particularly relevant in advanced packaging (3D-stacks, TSV-based solutions). Shared HPC routines can unify these sub-models at a system or wafer scale. Yield Monitoring aggregates real-time metrics from metrology, thermal, stress, and process logs, predicts near-future defect density or scrap probability, and alerts the main process optimization subsystem if risk thresholds are crossed, prompting immediate recipe changes.

During Atomic Layer Deposition, wave-based thermal anomalies can degrade uniform film thickness. The system identifies local hotspots or interface reflectivity changes, adjusting precursor pulses in real time. In Advanced Etch, real-time endpoint detection may be cross-validated by the “Thermal Expert” (monitoring wave-driven temperature changes in the plasma region) and the “Metrology Expert” (tracking dimension changes). The “Epitaxy Expert” fine-tunes doping profiles for layered crystal growth, while the Stress/strain sub-model tracks mechanical expansion as doping processes generate local heat, preventing delamination. Wave-based thermal calculations confirm that doping steps do not inadvertently create hotspots near TSV boundaries. The “Thermal Expert” extends analysis to package-level fluid cooling channels or vapor chambers. If wave-based conduction is predicted to cause localized hot zones, real-time adjustments in cooling flow or thermal interface materials are triggered.

Thermo-mechanical cycles can degrade adhesives and lead to warpage, which the stress/strain sub-model tracks these thresholds. For sub-2 nm devices, wave-based conduction may significantly affect doping precision. Each mixture-of-experts agent outputs confidence scores for its inferences, and the process optimization subsystem merges these scores to produce robust setpoints. If the uncertainty is high, more frequent or specialized measurements (e.g., “just-in-context/just-in-place metrology checks”) are triggered. The yield monitoring model aggregates partial tokens from all domain experts, computing a “manufacturability index” that represents the likelihood of success at each step. The system can stop or rework wafers before incurring excessive costs if the index drops below a threshold.

The workflow begins when a wafer enters the litho stage, where the “Layer-Specific Litho Expert” begins prefill, reusing baseline KV caches from a universal wafer-state model, and the “Mask Specialist” similarly reuses partial embeddings for thermal data. When a wave-based thermal anomaly occurs, the “Thermal Expert” identifies a wave-based heat spike near the reticle interface, streams partial tokens indicating “Potential distortion risk at reticle corner D3,” and the “Mask Specialist” receives these partial tokens, modifying the reticle scanning approach for that region. During metrology feedback, mid-scan, the “Metrology Expert” sees an unexpected overlay drift and streams partial alerts to the “Yield Monitor Expert,” which warns that yield might drop if overlay >2 nm out of tolerance. For rapid parameter adjustment, the “Layer Expert” updates scanning speed and dose for the next pass, partial KV caches are reused, so minimal overhead in producing an updated recipe, and the stress model briefly checks if these changes cause mechanical strain on the wafer edges. During the ALD step, after litho, the wafer moves to an ALD chamber, the “Thermal Expert” re-checks wave-based conduction, while the “ALD Expert” reuses the same low-level wafer-state caches. If wave conduction threatens film uniformity, partial tokens instruct “reduce precursor injection in Region A3.” For final yield projection, the yield model aggregates partial results from all steps, providing a near-real-time projection. If the wafer remains within risk thresholds, the system continues; otherwise, it suggests rework or route to a different process line.

The benefits include Multi-Expert Efficiency where each sub-model (mask, layer, metrology, thermal, stress, yield) focuses on specialized tasks yet shares baseline context via partial KV-caches, which reduces repeated prefill computations, accelerating AI-driven decision cycles. Hybrid Thermal Modeling ensures wave-based plus diffusive modeling ensures comprehensive coverage from quantum scale to package scale, crucial for advanced packaging and sub-2 nm nodes. Real-Time Corrections enable streaming partial inferences allows immediate mid-process interventions, especially in time-critical steps like EUV lithography or advanced etch endpoint detection. Enhanced Yield & Reliability means stress/strain checks, thermal wave analysis, and metrology data feed into a dedicated yield monitor that proactively flags at-risk wafers, improving throughput and decreasing scrap. Scalability for Next-Gen Fabs is achieved as the mixture-of-experts approach is modular: new experts (e.g., future gate-all-around transistor models) can be added without overhauling the entire pipeline.

This refined embodiment augments the originally disclosed adaptive semiconductor process control platform by introducing a multi-LLM (or nested mixture-of-experts) architecture, each agent specialized for tasks like lithography sub-steps (mask vs. layer), thermal wave analysis, stress/strain prediction, metrology feedback, and yield monitoring. Efficiency mechanisms such as partial KV-cache reuse and incremental streaming reduce computational overhead while enabling fast, fine-grained control adjustments. The integration of wave-based thermal modeling at quantum and mesoscale, plus multi-scale physics coupling, ensures robust real-time process optimization for advanced semiconductor fabrication—particularly in ALD, advanced etch, epitaxy, and EUV lithography steps with complex 3D stacked packaging.

Next is an augmented, technical embodiment describing how temporal dynamics and specialty multi-model integrators-inspired by Mirasol3B (multimodal time-aligned vs. contextual), Titans (long-term memory at test time), and DeepSeek-R1 (RL-driven advanced reasoning) —can further refine the multi-expert, multi-scale semiconductor process control system. This expanded design focuses on advanced, dynamic models that integrate wave-based thermal modeling, stress/strain prediction, lithography sub-tasks, and yield monitoring, while handling time-aligned data streams and large memory contexts during test-time operation.

In prior sections, we introduced a mixture-of-experts (MoE) or team-of-models approach for advanced process control in semiconductor manufacturing, covering ALD, advanced etch, epitaxy, EUV lithography (mask vs. layer tasks), thermal wave phenomena (e.g. “second sound”), stress/strain analysis for 3D packaging, and yield monitoring with real-time feedback. We now augment these experts with temporal modeling and test-time memory+reasoning enhancements, leveraging Mirasol3B for multimodal integration for time-aligned data (e.g., high-frequency sensor streams) vs. contextual data (e.g., textual instructions, design docs), Titans for long-term memory at test time, enabling adaptive retrieval and memorization of relevant states across extended wafer runs, and DeepSeek-R1 for reinforcement-learning-enhanced advanced reasoning, enabling iterative self-improvement, chain-of-thought validations, and dynamic reward signals for improved yield or minimized thermal stress.

During wafer processing, we often collect time-aligned signals including high-frequency sensor streams (thermal scans, acoustic or vibrational signals, plasma endpoint traces) and asynchronous contextual data including lithography recipes, mask design files, engineering change orders, textual “notes” or process logs. Mirasol3B's architecture helps integrate these with a specialized Combiner Module that “fuses” high-frequency sensor data chunks (e.g., wave-based thermal mapping, real-time wafer images) while the textual domain experts handle higher-level control instructions or post-process logs. For example, video-based wafer-inspection cameras or IR scanning could be chunked by time steps, then partially summarized into compact embeddings for downstream “Thermal Wave Expert” or “Layer-Specific Litho Expert.” The time-aligned sub-model processes sensor “windows” (e.g., each second's thermal map, each pulse in ALD), while the textual sub-model handles meta-data about the wafer's recipe steps or debrief logs from previous runs. Streaming allows the system to stream partial outputs from the time-aligned sub-model (e.g., detecting a “thermal wave anomaly” mid-chunk) back to the contextual sub-model (for a recipe adjustment explanation). This synergy yields lower-latency process corrections.

Fabs run extended lot cycles, storing massive historical data including long wafer sequences (thousands of steps, each with partial metrology) and cross-lot referencing (wafer #234 from batch A might share pattern defects with wafer #197 in a prior batch). Titans introduces neural long-term memory with an adaptive forgetting mechanism, deployed with Short-Term Memory for normal “attention-based” context for local decisions (e.g., next few litho steps) and Long-Term Memory that accumulates historical anomalies, wave-based hotspots, mechanical warpage episodes, yields from prior runs, etc. at test time—meaning the model dynamically updates memory in the live fab environment. Memory Integration Types include Memory as Context (MAC) where the “Stress/Strain Expert,” for instance, can retrieve old boundary conditions or doping steps from earlier in the wafer's life cycle using large memory states, enabling more accurate stress predictions; Memory as a Layer (MAL) which is a simpler approach where we insert a “Titans memory layer” in each specialized domain model, letting them store and recall patterns from extended runs; and Adaptive Forgetting where if the system sees a repeated extraneous fault signature, it can degrade its importance in memory, preventing bloat or confusion. The potential gains include Wafer-Spanning Consistency where the model can recall prior process offsets (dose correction 2 wafers ago) if it is relevant to the current wafer's alignment, and Reduced Rework with fewer repeated “learning curves” across multiple wafer lots or new mask sets, as the memory architecture ensures experience accumulates at inference time.

In addition to standard supervised or unsupervised training, the system can adopt DeepSeek-R1's multi-stage RL approach to improve chain-of-thought refinement where the model tries different optimization strategies for thermal wave management or stress minimization, receiving rewards (e.g., “did yield improve?”), and self-correction/reflection where when the “Thermal Expert” sees an unexpected wave spike, it attempts alternate control actions, measuring real-time improvements. Multi-Stage RL Training includes Stage 1 with baseline data from standard domain experts (some partial SFT), Stage 2 with RL fine-tuning with real or simulated wafer outcomes (yields, defect rates, time overhead), and Stage 3 with distillation into smaller domain sub-models for sub-10B param experts used in edge computing near the equipment. Reward Schemes include Accuracy Rewards if predicted overlay or stress matches measured data, Throughput/Cost Rewards for minimizing cycle time or energy usage, and Safety Factor Rewards for avoiding catastrophic wafer damage or large warpage. This fosters an iterative self-improving environment where each domain sub-model learns new “policies” to handle anomalies better.

The Global Orchestrator with Multi-Expert, Multi-Modal Modules includes a Mirasol3B-Style Combiner that processes time-chunked sensor data (heat maps, wave signals) and streams partial embeddings to relevant domain experts (e.g., “Thermal Wave Expert,” “Stress Expert”); Titans Memory that provides a long-term memory module accessible by each domain model, maintains cross-wafer or cross-lot historical contexts, and adapts and “remembers” anomalies from prior runs, so each new wafer can benefit from this evolving knowledge base in real time; DeepSeek-R1 RL that contributes advanced chain-of-thought reasoning, letting experts test new recipe adjustments or scanning patterns and periodically merges these revised “policies” into a stable checkpoint used by the entire pipeline; and Process Optimization Subsystem (400) that gathers partial inferences from all domain experts, combines them into final control signals (dose, alignment, temperature setpoints, doping concentration, etc.), and minimizes cost, risk, or time across the entire fab process.

For example, in an EUV Litho Step with Thermal Anomalies: Time-Aligned Sensor Data means IR scanner yields temperature frames at 100 Hz, and the Mirasol3B chunk-based approach extracts relevant wave dynamics. Titans Memory allows the system to recall that a similar hotspot pattern was observed 5 wafers ago, correlated with reticle distortion if not corrected early. RL Reasoning means the “Layer-Specific Litho Expert,” trained with DeepSeek-R1, hypothesizes a mild scanning speed reduction+local dose tweak, and the policy yields a reward if overlay errors drop without slowing throughput too much. On Update, it logs the event in Titans Memory, increasing future confidence, or if it fails, it tries an alternate approach next time.

For ALD or Etch with Dynamic Pulse Timing, the system chunk-encodes the real-time plasma or precursor injection signals. Mirasol3B Combiner yields compact representations, Titans Memory references prior wafer runs to recall similar anomalies, and DeepSeek-R1 RL logic tries adjusting pulse lengths for better uniformity. In Stress/Strain Monitoring Over Full 3D Stack Build, the “Stress Expert” uses multi-day data streams from thermal cycles, doping steps, bonding steps. If a repeated warpage pattern emerges, Titans Memory allows the system to recall the best mitigation strategy, and RL-based adaptive control can modify cooling ramp rates or clamp conditions to reduce stress.

Implementation Details & Technical Nuances include Partial KV-Cache Reuse where the baseline HPC cluster hosts a universal wafer-state “pre-embed,” each domain model reuses partial embeddings and KV caches where possible, cutting overhead, and Mirasol3B-based modules can chunk video/sensor data but still share textual embeddings with other sub-models. For Real-Time vs. Batch processes, time alignment for sensors is primarily real-time, while textual or historical logs may be asynchronous, and the system orchestrator merges them based on setpoints or events that the partial streams trigger. Adaptive Memory Management means Titans memory modules run gradient-based updates even at inference time, requiring HPC or local edge resources, and the forgetting mechanism ensures memory usage does not explode for large wafer volumes. RL Distillation as a final step distills advanced RL policies into smaller sub-models that run on the manufacturing floor hardware, enabling near-instant corrections without saturating the central HPC.

The key advantages and outcomes include Scalable Handling of Time-Aligned Data where the Mirasol3B style chunk-based approach efficiently processes large IR/video frames or high-frequency sensor data; Persistent, Evolving Knowledge where Titans memory ensures the system “learns from experience” across extended wafer batches, capturing subtle patterns that static models might miss; Adaptive RL for High-Stakes Optimization where DeepSeek-R1's reinforcement learning yields advanced chain-of-thought, letting domain experts refine recipes in a self-correcting loop; Improved Yield & Reduced Surprises where real-time wave-based thermal data+large memory+RL-driven corrections ensure fewer catastrophic defects; and Dynamic Resource Usage where partial KV-cache reuse plus chunk-based combiner strategies keep HPC costs manageable.

The Representative Operation Flow begins with Initialization where the HPC environment loads domain experts (ALD, Litho, Stress, etc.) plus the Mirasol3B module for real-time sensor chunking, and Titans memory is initialized with prior wafer knowledge. During Data Ingestion, as wafer #5000 enters the line, sensors (optical, thermal, acoustic) produce streams chunked at time intervals, and Mirasol3B transforms them into compact embeddings. For Contextual Queries, the textual sub-model ingest new recipe changes or operator notes, and cross-attention merges time streams and textual context. During Expert Inference, each domain model consults Titans memory to see if a pattern matches prior anomalies, and if so, relevant retrieval steps are integrated. In RL Reasoning, the system tries incremental adjustments based on prior feedback, and if yield or thermal stability improves (measured by near-live metrology), the system logs an RL reward. For Control Actions, Process optimization subsystem 400 issues updated setpoints or scanning instructions. During Memory Update, Titans memory updates or decays stored embeddings to reflect outcomes, and sizable positive reward means the relevant chain-of-thought is reinforced for future wafers. Distillation (Periodic) means the HPC offline distills new RL-improved strategies into smaller sub-models for real-time usage in local equipment controllers.

By incorporating temporal dynamics and specialty multi-model integrators from Mirasol3B (time-aligned vs. contextual), Titans (test-time memory), and DeepSeek-R1 (reinforcement learning for deeper chain-of-thought), the multi-expert semiconductor process control system gains powerful new capabilities including seamlessly fusing continuous sensor streams with asynchronous data for advanced wave-based thermal analysis and stress predictions, maintaining a dynamic, long-term memory across wafer batches to accelerate adaptation, and refining process steps in real time with RL-driven policies that maximize yield and throughput. This synergy paves the way for next-generation semiconductor fabs, leveraging advanced AI to handle the ever-growing complexity of ALD, advanced etch, epitaxy, and EUV lithography—while continuously improving and learning from ongoing manufacturing runs. Here is a set of additional technical embodiments and example passages focusing on Automated Equipment Retargeting—that is, switching an entire tool or toolset from one technology node (e.g., 14 nm) to a smaller node (e.g., 7 nm) with minimal re-ramp time to demonstrate how control platform helps handles node-to-node transitions through advanced scheduling, real-time parameter re-calibration, and knowledge graph integration. This is particularly relevant in cases like 2 nm to 18 A that are upcoming (longer term future variants at smaller scales).

In one aspect, the disclosed adaptive semiconductor process control platform is configured to retarget entire equipment sets (e.g., switching a lithography scanner or etch chamber from 14 nm to 7 nm mode) with minimal downtime and reduced re-ramp times. Traditional equipment retargeting often involves lengthy qualification and calibration procedures that interrupt production schedules and degrade throughput. By contrast, the disclosed system leverages advanced scheduling algorithms, real-time parameter re-calibration, and knowledge graph integration to manage multi-node transitions dynamically. Through synergy between the Upper Confidence Tree (UCT) optimization, particle-based state estimation, and economic analysis subsystems, the platform intelligently sequences and executes retargeting steps, minimizing the requalification overhead while ensuring that each piece of equipment meets the tighter process windows of the smaller node.

According to one embodiment, a scheduling coordinator module within the process optimization subsystem 400 monitors upcoming production demands for both the 14 nm and 7 nm lines. The system identifies windows of opportunity—such as periods of lower equipment utilization or aligned wafer batch completions—to initiate retargeting of specific tools. This scheduling coordinator accesses the knowledge graph manager (330) to retrieve node-specific calibration profiles, historical ramp metrics, and equipment states. For example, the knowledge graph may store the recommended initial dose offsets, overlay correction factors, and thermal compensation baselines unique to 7 nm processes. The scheduling coordinator uses these references to generate a time-sequenced retargeting plan that includes: Pre-Shutdown Calibration, which involves collecting final 14 nm sensor baselines to update historical performance trends; Refocus & Re-bias, which involves applying recommended stage realignment or optical offsets derived from a 7 nm node profile in the knowledge graph; Incremental Qualification, which involves running a shortened test wafer batch to validate critical parameters at the 7 nm node, checking overlay accuracy or sidewall angle; and Production Ramp, which involves commencing high-volume 7 nm wafer processing while the system continuously refines calibration parameters through real-time multi-modal sensor feedback. During re-ramp, particle filter engine 310 tracks a multi-hypothesis model for the tool's new node-specific state, considering factors such as thermal and mechanical differences due to changes in wafer thickness or reflectivity at the 7 nm node, overlay drift resulting from more stringent alignment tolerances, and new dose or focus offsets to handle different photoresist materials.

To manage these node-specific changes, the state estimation processor 320 updates both short-term and long-term calibration vectors (e.g., lens heating profiles, reticle alignment data) in near real time. The system employs an adaptive resampling strategy to increase the density of “particles” exploring the new process window so that the most likely node-specific states quickly dominate the distribution. Whenever sensor readings (e.g., optical overlay signals, wafer-level film thickness data) diverge substantially from predicted 7 nm baselines, the system triggers a localized re-calibration routine, dynamically adjusting lens alignments or stage velocities. This approach avoids the exhaustive, full-scale qualification typical of traditional node re-targeting procedures.

In a further embodiment, the knowledge graph acts as a repository for node-specific recipes and “best-known methods” (BKMs). For instance, when retargeting from 14 nm to 7 nm, the system queries the knowledge graph for recommended step-and-scan speeds for 7 nm that yield minimal edge-placement error, temperature control heuristics that mitigate the narrower thermal budget of the smaller geometry, and economic factors for 7 nm wafer runs (e.g., higher wafer value, increased maintenance intervals for smaller-node reticles). The UCT optimization engine 410 balances these node-specific recipes against real-time data, adjusting them if a particular tool exhibits an atypical drift or if the economic analysis processor 420 indicates that certain throughput improvements outweigh the incremental risk of higher defect rates.

When retargeting a tool, the measurement timing controller 240 transitions from 14 nm measurement schemes to newly configured 7 nm measurement strategies. This may include higher-frequency alignment scans to capture smaller tolerances, additional optical measurements for critical dimension (CD) control, and real-time dose validation at the wafer edge. Using just-in-time (JIT) approaches, the system ramps up measurement intensity only during the requalification sequence and the initial 7 nm production runs, gradually relaxing to normal sampling levels once stable operation is confirmed. This selective measurement intensification reduces overhead and shortens the overall re-ramp timeline.

The economic analysis processor 420 considers the market demand for 14 nm versus 7 nm wafers, the cost of extended downtime, and predicted yield differentials at each node. If the system's machine learning models anticipate a surge in 7 nm wafer orders or a premium in pricing, the optimization will favor accelerated re-ramp, even if that means incurring slightly higher short-term risk or maintenance costs. Conversely, if 14 nm demand remains high and the margin gain at 7 nm is marginal, the system might schedule a more gradual transition. This method ensures that re-targeting decisions are not only technically feasible but also economically optimal for the fab's current market conditions.

As the equipment transitions into full 7 nm production, the process optimization subsystem 400 monitors yield data, defect density, and key performance metrics (e.g., overlay error, wafer throughput). Risk assessment engine 440 checks for abnormally high defect rates—suggesting incomplete ramp or calibration mismatch. If anomalies persist, the system dispatches a partial revert or additional calibration steps from the knowledge graph's set of archived retargeting events. Once the platform identifies stable, high-yield operation, it flags the retargeting as complete, freeing resources to handle subsequent node transitions.

The operational flow for a scanner transition begins when the scheduling coordinator detects an upcoming 7 nm wafer batch needing immediate production. Then, the Knowledge Graph Query retrieves recommended lens heating profiles, alignment offsets, and step rates for 7 nm. During Controlled Shutdown & Baseline Capture, the tool finishes its 14 nm lot, and final sensor snapshots are recorded to update the knowledge graph. For Quick Startup at 7 nm, the tool is restarted with partial calibration loaded from prior 7 nm recipes, and the system runs a short test wafer lot. Real-Time Adjustments occur if mismatch arises (e.g., measured overlay error>X nm), triggering local re-calibration of lens tilt or temperature setpoints. During Confidence Accumulation, as the particle filter model 310 converges on stable 7 nm parameters, the system lowers sampling intensity to normal JIT levels. Finally, in Full Production, the tool enters high-volume 7 nm production, with the UCT optimization engine balancing yield, throughput, and maintenance factors.

By combining these automated scheduling and real-time re-calibration methods, the disclosed approach significantly cuts re-ramp durations, allowing the fab to meet demands for next-generation nodes without protracted qualification cycles that can stall throughput and inflate costs.

These capabilities demonstrate the broad industrial applicability of the system and its ability to address the challenges of modern semiconductor manufacturing. The system's adaptability and performance improvements make it a valuable solution for achieving precision and efficiency in high-demand production environments.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

As used herein, “multi-modal sensor data” refers to information collected from multiple types of sensors including, but not limited to, thermal sensors, position sensors, optical sensors, and environmental sensors operating simultaneously during semiconductor manufacturing processes.

As used herein, “particle-based estimation” refers to a probabilistic state estimation technique where the current state of a manufacturing process is represented by a collection of weighted particles, each representing a possible system state.

As used herein, “topology-aware features” refers to characteristics extracted from process data that preserve geometric and topological relationships across multiple scales using persistent homology calculations and feature matching techniques.

As used herein, “knowledge graph” refers to a structured representation of process relationships, constraints, and dependencies that captures causal relationships, temporal dependencies, and spatial correlations between manufacturing parameters.

As used herein, “upper confidence tree (UCT) optimization” refers to a decision-making algorithm that explores possible process adjustments through tree-based search with super-exponential regret bounds and risk-weighted value calculations.

As used herein, “just-in-context measurements” refers to baseline measurements taken before critical process steps to establish initial conditions.

As used herein, “just-in-time measurements” refers to real-time measurements taken during process execution to enable immediate detection of deviations.

As used herein, “just-in-place measurements” refers to location-specific measurements targeted at particular regions of interest on a wafer.

As used herein, “super-exponential regret bounds” refers to mathematical constraints in optimization algorithms that limit the cumulative difference between chosen actions and optimal actions, decreasing faster than an exponential function to ensure rapid convergence to optimal decisions in process control.

As used herein, “process window” refers to the range of acceptable operating parameters within which a semiconductor manufacturing process maintains required quality and performance specifications, including but not limited to exposure dose, focus, temperature, and overlay tolerances.

As used herein, “adaptive resampling” refers to a dynamic technique in particle-based estimation where particles representing possible system states are selectively duplicated or eliminated based on their weights to maintain effective state representation while optimizing computational resources.

As used herein, “hierarchical feature fusion” refers to the integration of process-related features at multiple scales and levels of abstraction, combining low-level sensor measurements with high-level derived characteristics through confidence-weighted matching and aggregation techniques.

As used herein, “persistent homology” refers to a mathematical method for analyzing topological features of data across multiple scales, identifying stable patterns and relationships that persist across different resolution levels in manufacturing process data.

### Conceptual Architecture of Adaptive Semiconductor Process Control Platform

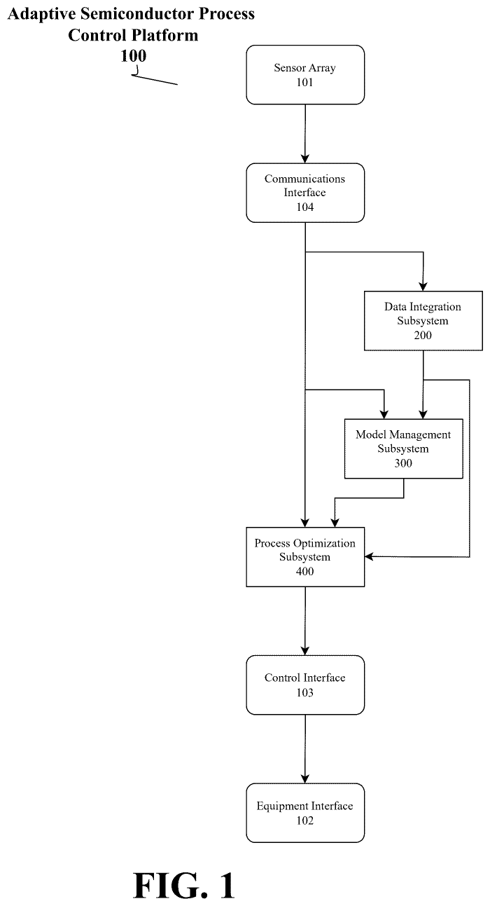

FIG. 1 is a block diagram illustrating exemplary architecture of adaptive semiconductor process control platform 100, in an embodiment. Adaptive semiconductor process control platform 100 includes data integration subsystem 200, model management subsystem 300, process optimization subsystem 400, sensor array 101, equipment interface 102, control interface 103, and communications interface 104. These elements are configured to work together to enable data acquisition, analysis, optimization, and control in semiconductor manufacturing processes.

Sensor array 101 collects multi-modal data during operation, including thermal, positional, optical, and environmental measurements. Data generated by sensor array 101 is transmitted to data integration subsystem 200 for processing and analysis. Communications interface 104 enables seamless data exchange between subsystems, ensuring synchronized operations across the platform.

Data integration subsystem 200 receives raw sensor data and processes it to generate actionable information. This subsystem integrates data streams from sensor array 101 through sensor fusion techniques and generates coherent measurements. Feature extraction within data integration subsystem 200 identifies significant characteristics in the raw data, while topology-aware analysis generates persistent features that provide insights into process stability and performance. Data integration subsystem 200 also coordinates measurement timing using strategies like just-in-context, just-in-time, and just-in-place, ensuring that data collection aligns with operational requirements. Temporary data is stored in real-time buffers, while long-term data is archived for future analysis.

Processed data flows from data integration subsystem 200 to model management subsystem 300, where it is incorporated into state models and knowledge graphs. Particle filter engine within model management subsystem 300 maintains probabilistic state representations that reflect real-time process conditions. Knowledge graph manager generates and updates process relationships, constraints, and dependencies, representing this information in a structured format for use by other subsystems. Learning adaptation processes within model management subsystem 300 refine models over time, using real-world data and outcomes to improve future predictions.

Optimization operations are performed within process optimization subsystem 400. This subsystem receives inputs from model management subsystem 300, including current state estimates and contextual process data. Optimization algorithms implemented within process optimization subsystem 400, such as upper confidence tree searches with super-exponential regret bounds, determine optimal process adjustments based on operational, quality, and economic factors. Economic analysis processes evaluate considerations such as wafer value, energy costs, and maintenance scheduling, ensuring that optimization decisions align with overall production objectives. Control decisions generated by process optimization subsystem 400 are transmitted to control interface 103 via control signal generators, enabling real-time adjustments to manufacturing equipment.

Control interface 103 communicates with equipment interface 102 to ensure precise execution of control signals. Equipment interface 102 serves as the bridge between adaptive semiconductor process control platform 100 and manufacturing equipment, enabling the system to implement adjustments in real time. Control feedback and updated process conditions are relayed from equipment interface 102 back to sensor array 101, ensuring that data collection reflects current manufacturing states.

Communications interface 104 facilitates data flow and synchronization across the entire platform, enabling coordinated operation between data integration subsystem 200, model management subsystem 300, process optimization subsystem 400, sensor array 101, equipment interface 102, and control interface 103. Adaptive semiconductor process control platform 100 thus provides a structured and integrated approach to data-driven decision-making and control in semiconductor manufacturing environments.

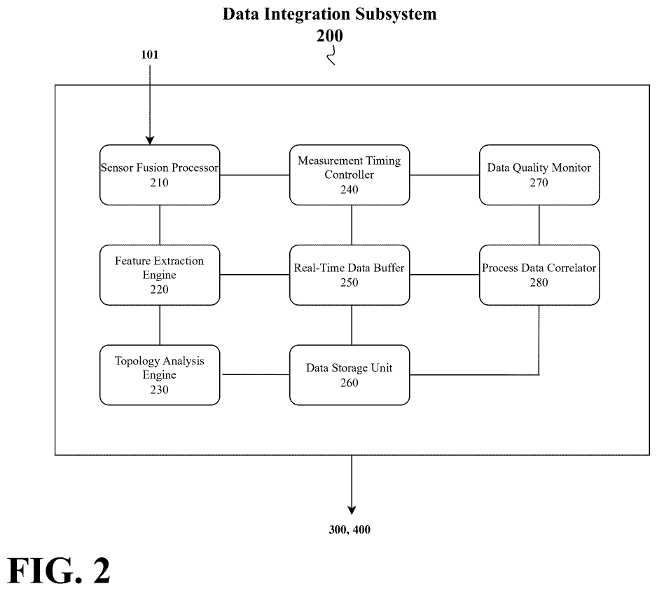

FIG. 2 is a block diagram illustrating exemplary architecture of data integration system 200, in an embodiment. Data integration system 200 includes sensor fusion processor 210, feature extraction engine 220, topology analysis engine 230, measurement timing controller 240, real-time data buffer 250, data storage unit 260, data quality monitor 270, and process data correlator 280. These components work together to process multi-modal sensor data collected from sensor array 101, providing actionable insights for model management system 300 and process optimization system 400.

Sensor fusion processor 210 receives data streams from sensor array 101 and integrates measurements from thermal, positional, optical, and environmental sensors into coherent datasets. This integration may include, in an embodiment, aligning data from sensors with different sampling rates and resolutions, using interpolation techniques or resampling algorithms to achieve temporal and spatial consistency. For example, positional data collected at high frequency may be synchronized with lower-frequency optical measurements to provide a unified dataset for downstream processing. Sensor fusion processor 210 may also apply sensor calibration adjustments to account for variations in sensitivity or drift over time, ensuring accuracy in the combined output. Fused data is transmitted to feature extraction engine 220, which identifies and refines key characteristics for further analysis.

Feature extraction engine 220 analyzes raw sensor inputs to identify significant process features that are critical for manufacturing control. This may include, in an embodiment, detecting thermal gradients using advanced heatmap analysis or identifying positional shifts through edge detection algorithms applied to optical images. Surface irregularities, such as deviations in wafer topography, may be detected using frequency-based analyses or machine learning models trained on historical defect patterns. Feature extraction engine 220 may refine these features by filtering out noise or irrelevant data, ensuring that only the most pertinent characteristics are passed on to topology analysis engine 230.

Topology analysis engine 230 performs persistent homology calculations and topology-aware feature generation using the processed data from feature extraction engine 220. This engine may, for example, analyze spatial relationships between identified features to detect stable regions, transient patterns, or anomalies within the manufacturing process. Persistent homology may be used to identify topological structures that persist across multiple scales, providing insights into patterns that are robust to variations in process conditions. In an embodiment, topology analysis engine 230 may generate scale-specific features, such as clusters of misalignment or thermal hotspots, that are fed into models maintained by model management system 300 for accurate state estimation and predictive analysis.

Measurement timing controller 240 coordinates the timing of data collection to align with just-in-context, just-in-time, and just-in-place strategies. For example, just-in-context timing may ensure that baseline measurements are captured before a critical process begins, such as pre-bonding alignment verification. Just-in-time measurements may be dynamically triggered during high-precision operations, such as lithography or etching, to detect and correct deviations in real time. Just-in-place strategies may focus on localized data collection at specific regions of the wafer, such as areas with known defect density, to support targeted adjustments. In an embodiment, measurement timing controller 240 may dynamically adjust its priorities based on process feedback, ensuring that data collection efforts are focused on areas with the highest potential impact on manufacturing outcomes.

Real-time data buffer 250 provides temporary storage for streaming data from sensor fusion processor 210 and feature extraction engine 220, ensuring uninterrupted data flow during processing. In an embodiment, the real-time data buffer may implement first-in-first-out (FIFO) queueing to handle high-frequency data streams without loss or delays. Data storage unit 260 archives processed features and historical measurements for long-term use, providing access to datasets needed for training, validation, and refinement of models within model management system 300. For example, data storage unit 260 may store historical process data that is used to analyze trends over time or to validate predictive models under varying conditions.

Real-time data buffer 250 temporarily stores streaming data received from sensor fusion processor 210 and feature extraction engine 220, ensuring uninterrupted data flow during processing. In an embodiment, real-time data buffer 250 may include a first-in-first-out (FIFO) queueing mechanism to manage high-frequency data streams, allowing data to be processed in the order it is received while preventing delays or loss of information. Real-time data buffer 250 may, for example, include logic for prioritizing critical data streams, such as those associated with dynamic process conditions or high-precision operations, ensuring that these are available to downstream systems without interruption.

Real-time data buffer 250 may also employ error detection and correction techniques to maintain data integrity during transmission. For example, checksums or parity bits may be used to identify corrupted data packets, which can then be flagged or corrected before they are passed to subsequent components. In an embodiment, real-time data buffer 250 may dynamically adjust its storage allocation based on the current processing load, increasing buffer capacity during periods of high data throughput to prevent overflow or data loss.

Real-time data buffer 250 may interact closely with measurement timing controller 240, ensuring that sensor data is synchronized with the timing of critical process phases. For instance, during a high-frequency data collection event, real-time data buffer 250 may prioritize streaming data from specific sensors associated with those events, discarding less relevant data if buffer capacity is exceeded. This ensures that the most critical data is always available for real-time analysis and decision-making within data integration system 200.

Data quality monitor 270 continuously evaluates the integrity of incoming sensor data, detecting and flagging anomalies that may affect process accuracy. This monitoring may include, in an embodiment, applying statistical outlier detection to identify abnormal sensor readings or using machine learning algorithms to detect patterns indicative of sensor faults. Missing data may be identified and addressed using interpolation techniques or data imputation models. Process data correlator 280 identifies relationships between different process measurements, creating contextual connections that support predictive modeling and process optimization. For example, process data correlator 280 may analyze correlations between temperature variations and alignment accuracy, generating insights that are used by process optimization system 400 to refine control strategies. In an embodiment, process data correlator 280 may apply multi-variable regression or causal inference methods to understand how different process parameters influence one another, further enhancing the predictive and analytical capabilities of the platform.

Process data correlator 280 may, for example, analyze data relationships across multiple sensor inputs and operational states to identify dependencies, trends, and correlations relevant to manufacturing processes. This component may employ statistical techniques, such as Pearson correlation or mutual information analysis, to determine how variations in one parameter, such as temperature, influence another parameter, such as alignment accuracy. In an embodiment, process data correlator 280 may apply machine learning models, such as graph-based neural networks or Bayesian networks, to represent and infer complex interactions among process variables. For instance, process data correlator 280 may detect that fluctuations in environmental humidity are consistently associated with dimensional deviations in critical features, enabling the system to predict and compensate for these effects in real time.

Process data correlator 280 may also support causal inference by analyzing historical and real-time data to distinguish correlation from causation, identifying actionable relationships that inform process optimization. For example, this component may determine that a certain threshold of energy input during a lithography step directly impacts edge placement accuracy, allowing model management system 300 to refine state estimates accordingly. By creating and updating contextual connections among diverse datasets, process data correlator 280 enhances the system's ability to generate predictive insights and supports dynamic, data-driven decision-making within process optimization system 400.

Data integration system 200 communicates with model management system 300 and process optimization system 400 via communications interface 104, ensuring that processed data is available for state estimation, knowledge graph updates, and optimization decisions. Data integration system 200 also interacts with control interface 103 to ensure that real-time data flows reflect the current operational state of manufacturing equipment. These coordinated operations enable data integration system 200 to provide comprehensive support for adaptive semiconductor process control platform 100.

In an embodiment, machine learning models may be employed throughout data integration system 200 to enhance data processing, feature extraction, and anomaly detection. These models may include, for example, convolutional neural networks (CNNs) for analyzing spatial features in optical or positional sensor data, recurrent neural networks (RNNs) for modeling temporal patterns in environmental measurements, and support vector machines (SVMs) for classifying anomalies in multi-modal datasets. Hybrid models, such as physics-informed neural networks, may also be used to incorporate domain-specific knowledge into machine learning predictions, improving accuracy and interpretability.

Machine learning models within data integration system 200 may be trained on historical datasets stored in data storage unit 260. These datasets may include, for example, historical measurements from sensor array 101, annotated examples of defect patterns, or process conditions associated with known manufacturing outcomes. Training may involve supervised learning techniques, where labeled data is used to teach the models to recognize specific patterns or anomalies. For instance, a supervised learning approach may involve training a CNN to detect surface irregularities using a dataset of optical images labeled with regions of defects.

In addition to supervised learning, machine learning models may also be trained using unsupervised methods, where the goal is to identify underlying patterns or clusters in unlabeled data. For example, an autoencoder may be used to compress and reconstruct sensor data, enabling the detection of unusual patterns that deviate from normal operation. Reinforcement learning may be employed in certain embodiments to optimize measurement timing strategies by rewarding actions that result in more accurate or efficient data collection. The training process may be enhanced by incorporating synthetic data generated through process simulations. For example, synthetic datasets may include simulated sensor outputs under varying conditions, such as thermal gradients, positional misalignments, or overlay errors. This approach may augment real-world data, providing additional training samples for rare or extreme scenarios that are difficult to capture during normal operations. In an embodiment, federated learning techniques may be used to train machine learning models collaboratively across multiple facilities without requiring raw data to be shared, preserving data privacy while leveraging diverse datasets. Once trained, these machine learning models may be deployed within data integration system 200 to perform real-time tasks such as detecting anomalies in incoming data streams, prioritizing features for analysis, or adapting measurement strategies based on evolving process conditions. For example, a trained model may monitor positional data in real time to detect deviations from expected alignment patterns, triggering immediate adjustments through measurement timing controller 240 or process optimization system 400. These machine learning models, by analyzing complex datasets and adapting to changing conditions, support the efficient and reliable operation of adaptive semiconductor process control platform 100.

In an embodiment multi-fab federated coordination within an advanced AI-driven semiconductor manufacturing platform with federated learning, real-time inter-fab recipe sharing and yield improvement data, models or configurations, supply chain constraints or statuses, and the extension of distributed EDA/design software across different tooling from companies such as ASML (EUV litho), KLA (inspection/etch), and ASM (ALD). By enabling interoperability at scale, fabs worldwide can coordinate production optimization, accelerate new process adoption, and reduce overall time-to-market.

In this federated approach, each fabrication facility operates an instance of the AI-driven process control platform, containing local data integration and optimization subsystems. Instead of combining all data into a single global repository, each fab retains sensitive production data—such as wafer defect logs, equipment status, or advanced packaging runs—within its own secure environment. Periodically, local training updates or model parameters (e.g., neural network weights) are encrypted and shared among participating fabs, preventing the disclosure of raw or proprietary data. This arrangement leverages privacy-preserving techniques (homomorphic encryption, secure multiparty computation) to align with corporate or governmental regulations, ensuring that aggregated knowledge of advanced process control flows across multiple sites without compromising confidentiality. Consequently, when one fab discovers a new overlay correction strategy that improves yield on a certain litho step, the relevant “policy updates” or partial model weights can be integrated back into the global model and disseminated to other fabs using compatible processes.

Beyond model training, the federated system supports real-time recipe exchange and cross-fab synergy. When a fab's local optimization engine identifies a particularly effective doping schedule, wave-based thermal compensation, or ALD precursor pulsing pattern, it shares this partial “recipe snippet” with other sites running similar tools. For example, if one fab refines an advanced ALD step using ASM equipment, that updated recipe can be tested or adapted at another fab—ensuring consistent performance for a global product line. A standard interface for recipe packaging and validation is essential, allowing each receiving fab to confirm the alignment of this snippet with local constraints: e.g., line/space capabilities, mask materials, or reticle differences. This mechanism also accelerates continuous improvement cycles, as each fab can incorporate the best-known recipe elements from the entire network, thereby raising collective yield efficiency. Additionally, real-time streaming of partial or incremental recipe updates can be done when a local RL engine indicates improved yield or reliability, letting remote sites incorporate the tweak rapidly, subject to local verification.

An integral extension in this federated environment is factoring in global supply chain data and constraints. The system, integrated with external logistical and inventory management tools, can automatically ingest updates on critical material availability (e.g., specialized photoresists, rare precursor chemicals, or advanced reticles) from across a corporate supply chain. If one fab's local stock of a crucial chemical is temporarily low, the system's global scheduler can shift certain production steps to alternate facilities that have ample stock, or it can propose a recipe variant that uses a slightly different chemical composition. Similarly, if shipping times or customs hold-ups threaten a fab's production schedule, local optimization can adapt. By weaving these supply chain signals into real-time multi-fab coordination, the system mitigates downtime and ensures wafer lots remain on schedule even under dynamic global conditions such as trade issues or local disruptions.

The federated coordination also extends to EDA/design software used for advanced node developments or 2.5D/3D packaging tasks. Traditionally, each fab or design center might employ different EDA flows—some specialized for EUV lithography, others for advanced packaging or co-packaged optics. In this multi-fab architecture, these distributed EDA tools share partial netlists, library data, or device constraints in a secure, modular format. A design team working on an HPC SoC package in one facility can, for instance, harness “cloud-based design seeds” from a sister facility specialized in photonic integration. Meanwhile, the AI-driven process manager, receiving real-time design constraint updates (like reticle layout or advanced waveguide alignment), can adapt the local process steps. By bridging EDA software and the multi-expert control modules, design changes can trigger immediate process model recalibrations, effectively synchronizing design and manufacturing knowledge at scale.

To ensure multi-fab synergy works seamlessly, the federated platform must normalize data and coordinate control across a wide range of equipment from different vendors (ASML for EUV litho, KLA for inspection/etch, ASM for ALD, and so forth). Each machine type or brand may provide unique data formats, recipe structures, and run-time parameters. Through carefully defined abstraction layers, the AI-driven system translates local tool commands or sensor outputs into a standard “interoperability protocol.” Hence, a wafer's recipe to correct overlay in an ASML EUV scanner at one fab can be transformed and applied to a partially different EUV scanner model at another site. Similarly, a KLA-based etch inspection workflow that discovered a novel fault signature can share that pattern with other sites running different KLA or even partially compatible tools. This standardization ensures that the advanced RL-based policies or sensor orchestration logic can replicate successes from one domain across multiple lines or vendor systems. By bridging vendor-specific differences, the platform effectively merges machine-level feedback with multi-fab coordination, amplifying cross-site learning while respecting each vendor's operational constraints.

Another crucial factor is the capacity to run an adaptive, distributed RL process that accumulates knowledge from multiple sites. Each fab's RL agent can train locally on its specialized tasks (e.g., advanced etch, new ALD precursor usage, or wave-based thermal phenomena in large reticles). Periodically, partial policy parameters are merged or averaged in the global aggregator—enabling synergy while preventing raw data leakage. Over time, this distributed RL loop fosters a diverse and robust policy set that can handle slight variations in local tool calibrations, wafer supply differences, or region-specific power constraints. The result is a globally informed set of process control strategies that drastically shortens the time required to adopt new technologies or ramp new product lines.

By implementing multi-fab federated coordination, manufacturing networks gain faster ramp-up times for new products, real-time intelligence for coping with supply chain hiccups, and a unified approach that harnesses best practices from each site. On the EDA and design side, real-time feedback from wafer results can be piped back into iterative design cycles, ensuring more precise layout decisions or advanced packaging constraints are addressed earlier. Interoperability across leading equipment vendors becomes a powerful force multiplier, with the AI-driven platform acting as a universal translator and aggregator of machine feedback. Overall, multi-fab synergy means that breakthroughs at one site can be exploited by the entire network, leading to improved yields, cost savings, and accelerated product development cycles in an increasingly complex semiconductor landscape.

This multi-fab federated coordination approach complements the intelligent sensor orchestration and multi-expert AI architecture, extending the platform's benefits across an entire corporate manufacturing ecosystem. Secure model-sharing ensures IP protection while letting local sites learn from each other's real-world process data. Interoperable tooling frameworks standardize the application of advanced RL-based optimizations, bridging top-tier equipment vendors and specialized design flows. By harnessing aggregated global knowledge and supply chain intelligence, semiconductor manufacturers can unify design, process, and logistics in a single adaptive framework—ultimately delivering more consistent device performance, faster time-to-market, and greater resilience in the face of shifting global conditions.

Data flows through data integration system 200 in a coordinated and structured manner to transform raw sensor data into actionable insights. Data generated by sensor array 101 is first received by sensor fusion processor 210, which integrates measurements from various sensor types into coherent datasets, accounting for differences in sampling rates, resolutions, and calibration. The fused data is then transmitted to feature extraction engine 220, where key characteristics, such as thermal gradients or positional shifts, are identified and refined. These features are further analyzed by topology analysis engine 230, which performs persistent homology calculations and generates topology-aware features that reveal stable patterns and anomalies across multiple scales.

The processed data flows into real-time data buffer 250, where it is temporarily stored to ensure continuity and prevent data loss during high-throughput operations. Measurement timing controller 240 coordinates the collection and flow of data, synchronizing it with critical process phases through just-in-context, just-in-time, and just-in-place strategies. Processed data and identified features are archived in data storage unit 260 for long-term use, such as model training and validation. Data quality monitor 270 continuously evaluates the integrity of incoming and processed data, flagging anomalies and ensuring only reliable information is passed downstream.

Finally, process data correlator 280 analyzes relationships between different datasets, uncovering dependencies and trends that are communicated to model management system 300 and process optimization system 400. This structured data flow enables data integration system 200 to provide consistent, high-quality inputs for adaptive semiconductor process control platform 100, supporting precise state estimation, predictive modeling, and optimization.

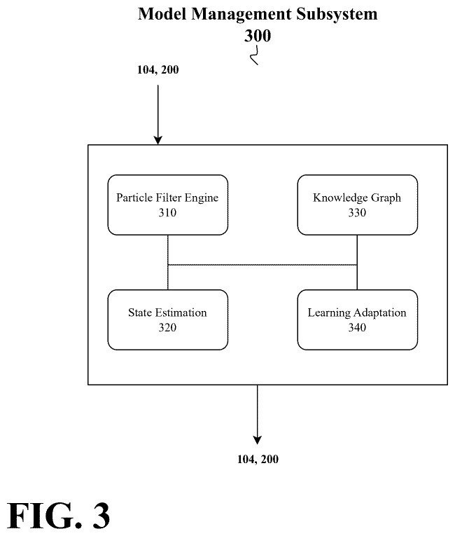

FIG. 3 is a block diagram illustrating exemplary architecture of model management subsystem 300, in an embodiment. Model management subsystem 300 includes particle filter engine 310, state estimation processor 320, knowledge graph manager 330, and learning adaptation unit 340. These components work together to maintain accurate state estimation, represent complex process relationships, and enable continuous learning and adaptation in semiconductor manufacturing operations.

Particle filter engine 310 receives processed data from data integration subsystem 200, including topology-aware features and correlations identified by process data correlator 280. This engine implements particle-based state estimation techniques, where the current state of the manufacturing process is represented as a probabilistic distribution of particles. Each particle may represent, for example, a potential combination of thermal, positional, and alignment states, with weights assigned based on the likelihood of each state given the incoming data. In an embodiment, particle filter engine 310 may include algorithms for multi-hypothesis tracking, allowing it to maintain several plausible state representations simultaneously. These hypotheses are updated dynamically as new data arrives, ensuring that the most probable states are emphasized. To optimize computational efficiency, particle filter engine 310 may employ adaptive resampling strategies, where particles with low weights are replaced by duplicates of higher-weight particles to maintain an accurate representation of the process state. Additionally, dynamic particle count adjustment may be used to allocate more particles during periods of high variability or uncertainty and fewer particles during stable process phases.

State estimation processor 320 receives particle distributions from particle filter engine 310 and computes state estimates that summarize the current conditions of the manufacturing process. These estimates may include, for example, detailed thermal profiles of the wafer, positional alignments across multiple layers, and overlay accuracy between features. In an embodiment, state estimation processor 320 may use statistical aggregation techniques, such as weighted averages or Bayesian inference, to derive high-confidence estimates from the probabilistic data. Real-time measurements from data integration subsystem 200 may be incorporated to refine these estimates further, ensuring that the outputs are consistent with live process conditions. State estimation processor 320 may also employ machine learning models, such as regression networks or decision trees, to enhance its ability to interpret complex data patterns and reduce noise in the inputs. For instance, these models may identify subtle trends or deviations in the data that would be difficult to detect using traditional statistical methods.

Knowledge graph manager 330 generates and maintains a knowledge graph that represents relationships, constraints, and dependencies between process parameters, equipment states, and environmental conditions. The knowledge graph may include, in an embodiment, nodes representing parameters such as temperature, alignment accuracy, and energy input, with edges indicating causal, temporal, or correlative relationships. For example, the graph may identify that a temperature increase in one region of the wafer is correlated with alignment errors in adjacent regions, providing insights into potential process optimizations. Knowledge graph manager 330 may update the graph dynamically based on incoming data from data integration subsystem 200 and feedback from process optimization subsystem 400. This updating process may include, for example, incorporating new causal relationships discovered through machine learning models or adjusting edge weights to reflect the latest process outcomes. The knowledge graph provides a structured and interpretable format for representing complex process knowledge, enabling more informed state estimation and optimization decisions. In an embodiment, knowledge graph manager 330 may support advanced functionalities such as graph traversal algorithms to identify dependencies and vector similarity searches to find comparable process conditions from historical data.

Learning adaptation unit 340 updates models within model management subsystem 300 based on new data and operational outcomes. This unit may use supervised learning to refine prediction models using labeled datasets stored in data storage unit 260, enabling continuous improvement in model accuracy. For example, historical datasets annotated with known defect patterns or successful control adjustments may be used to train classification or regression models. Unsupervised learning may be applied to discover new patterns or clusters in incoming data, such as identifying previously unrecognized correlations between environmental factors and process deviations. In an embodiment, learning adaptation unit 340 may employ reinforcement learning, where the system iteratively improves its decision-making by interacting with process optimization subsystem 400 and receiving feedback on the success of control actions. This feedback loop may include, for example, adjustments to overlay correction or dose optimization strategies that lead to measurable improvements in process yield. Additionally, learning adaptation unit 340 may utilize transfer learning to apply knowledge gained from one manufacturing scenario to similar processes, reducing training time and improving adaptability. This continuous learning capability enables model management subsystem 300 to adapt to evolving process conditions, maintain predictive accuracy, and support the broader functionality of adaptive semiconductor process control platform 100.

Machine learning models present in model management subsystem 300 may include, for example, supervised, unsupervised, and reinforcement learning models, as well as hybrid approaches that combine machine learning with domain-specific knowledge. In an embodiment, supervised learning models may include decision trees, support vector machines, and neural networks trained to predict process outcomes based on labeled datasets. For instance, a neural network may be trained to detect anomalies in overlay alignment using historical sensor data annotated with known alignment issues. Unsupervised learning models, such as k-means clustering or autoencoders, may be used to identify patterns or clusters in unlabeled data. For example, autoencoders may be employed to detect deviations in thermal profiles by reconstructing normal patterns and flagging unusual differences.

Reinforcement learning models may be used, in an embodiment, to optimize control strategies by learning from interactions with process optimization subsystem 400. For instance, a reinforcement learning agent may iteratively adjust process parameters, such as dose or field size, and receive feedback based on improvements in yield or defect reduction. This feedback loop enables the system to refine its decision-making policies over time, adapting to evolving manufacturing conditions. Hybrid models, such as physics-informed neural networks, may incorporate domain-specific physical equations into machine learning architectures to enhance predictive accuracy and interpretability.

The training of these machine learning models may be conducted using datasets stored in data storage unit 260, which may include historical sensor measurements, process outcomes, and environmental conditions. In an embodiment, training data may be augmented with synthetic datasets generated through process simulations, providing additional examples for rare or extreme scenarios. For instance, simulations of extreme temperature fluctuations or rapid positional misalignments may be used to train models to recognize and respond to these events. Training processes may include cross-validation to ensure model generalizability and out-of-sample testing to evaluate performance under unseen conditions.

Machine learning models may also be trained using distributed or federated learning techniques. For example, training data from multiple facilities may be used collaboratively without transferring raw data, preserving privacy while leveraging diverse datasets to improve model robustness. During operation, models may be continuously updated through online learning, where incoming data is used to refine model parameters in real time. This approach ensures that the models remain aligned with current process conditions and can adapt to gradual shifts or sudden changes in the manufacturing environment.

Once trained, machine learning models may be deployed within model management subsystem 300 to support tasks such as state estimation, anomaly detection, and predictive modeling. For example, a trained model may monitor thermal data in real time to predict regions of potential misalignment and trigger corrective actions through process optimization subsystem 400. These models provide the foundation for adaptive and intelligent decision-making, enhancing the overall performance and reliability of adaptive semiconductor process control platform 100.

Model management subsystem 300 interacts closely with data integration subsystem 200 and process optimization subsystem 400. Processed data from data integration subsystem 200 provides the inputs for state estimation and knowledge graph updates, while optimization decisions from process optimization subsystem 400 are used to validate and refine models. This bidirectional flow of information ensures that model management subsystem 300 remains aligned with current process requirements and operational goals. By maintaining accurate state representations and continuously adapting to new data, model management subsystem 300 supports the overall functionality of adaptive semiconductor process control platform 100.

Data flows through model management subsystem 300 in a structured manner to ensure accurate state estimation, predictive modeling, and continuous learning. Processed data from data integration subsystem 200, including topology-aware features and correlations identified by process data correlator 280, is received by particle filter engine 310. Particle filter engine 310 uses this data to maintain probabilistic representations of the current process state, which are transmitted to state estimation processor 320. State estimation processor 320 refines these representations, incorporating real-time measurements from data integration subsystem 200 to compute high-confidence state estimates that summarize the current conditions of the manufacturing process. These state estimates, along with additional inputs such as historical process data and real-time feedback, are used by knowledge graph manager 330 to update the knowledge graph, representing relationships and dependencies among process parameters, equipment states, and environmental factors. The updated knowledge graph is then utilized by learning adaptation unit 340 to refine machine learning models, incorporating new data and process outcomes to improve predictive accuracy and adapt to evolving manufacturing conditions. The outputs of model management subsystem 300, including refined state estimates and updated models, are communicated to process optimization subsystem 400, enabling informed decision-making and optimization of manufacturing operations. This continuous flow of data and feedback ensures that model management subsystem 300 remains responsive and aligned with the dynamic requirements of adaptive semiconductor process control platform 100.

Model management subsystem 300 also receives real-time data through communications interface 104, supplementing the processed data provided by data integration subsystem 200. For example, communications interface 104 may transmit raw or minimally processed thermal, positional, or optical measurements directly from sensor array 101. These direct inputs may, in an embodiment, bypass portions of data integration subsystem 200 to provide immediate feedback for high-priority tasks, such as anomaly detection or real-time state adjustments. This direct data flow ensures that model management subsystem 300 has access to the most up-to-date measurements, which may be especially important during transient manufacturing events or rapid changes in process conditions. The integration of both processed data from data integration subsystem 200 and real-time inputs through communications interface 104 enables model management subsystem 300 to maintain an accurate and responsive representation of the manufacturing process.

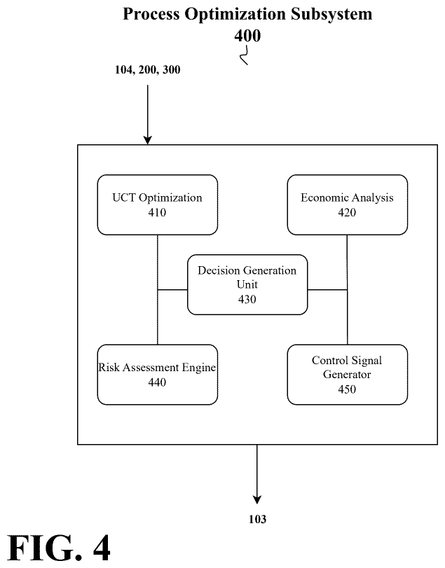

FIG. 4 is a block diagram illustrating exemplary architecture of process optimization subsystem 400, in an embodiment. Process optimization subsystem 400 includes UCT optimization engine 410, economic analysis processor 420, decision generation unit 430, risk assessment engine 440, and control signal generator 450. These components work together to analyze data, evaluate optimization strategies, and generate actionable control decisions that guide semiconductor manufacturing processes.

UCT optimization engine 410 receives state estimates and knowledge graph data from model management subsystem 300, along with processed and real-time data from data integration subsystem 200 through communications interface 104. UCT optimization engine 410 uses upper confidence tree search techniques to evaluate potential process adjustments by exploring various decision paths. For example, the engine may simulate adjustments to thermal compensation, overlay alignment, or process timing to identify strategies that maximize yield or reduce defects. In an embodiment, UCT optimization engine 410 implements super-exponential regret minimization algorithms to balance the need to explore new strategies with the need to exploit known successful strategies. This balancing ensures that optimization decisions are both innovative and grounded in proven practices. The engine may dynamically adjust exploration parameters, such as tree depth or node expansion criteria, based on feedback from ongoing operations. For instance, when data indicates high process stability, the engine may favor exploitation, whereas during periods of variability, it may increase exploration to identify novel solutions.

Economic analysis processor 420 evaluates economic factors and constraints that influence optimization decisions, incorporating inputs such as wafer value, energy costs, material usage, and maintenance schedules. For example, economic analysis processor 420 may prioritize adjustments that enhance throughput while minimizing operational costs, ensuring the overall profitability of the manufacturing process. In an embodiment, economic analysis processor 420 may use predictive models, such as regression models or decision trees, to forecast the long-term financial impacts of proposed control strategies. These forecasts may account for variables such as equipment wear, energy consumption, and material efficiency. The processor may also evaluate trade-offs between short-term gains and long-term operational sustainability. For instance, it may recommend reduced throughput in the short term to extend equipment life and avoid costly repairs. This economic evaluation ensures that optimization strategies align with both technical performance metrics and financial objectives.

Measurement strategies, including just-in-context, just-in-time, and just-in-place, play an integral role in informing the operations of process optimization subsystem 400. These strategies provide real-time, context-specific data that supports the functions of UCT optimization engine 410, economic analysis processor 420, and risk assessment engine 440. For example, JIC measurements may deliver baseline data to UCT optimization engine 410 before a critical process begins, such as pre-bonding alignment verification. JIT measurements may provide real-time updates during operations, such as lithography or wafer bonding, enabling the optimization engine to make dynamic adjustments to process parameters. JIP measurements may supply localized data for risk assessment engine 440 to evaluate potential anomalies or deviations in specific regions of the wafer. In an embodiment, these measurement strategies ensure that process optimization subsystem 400 has access to timely and precise data, allowing it to adapt quickly to changing conditions and maintain high manufacturing performance.

Decision generation unit 430 synthesizes outputs from UCT optimization engine 410 and economic analysis processor 420 to generate control decisions tailored to the specific needs of the manufacturing process. These decisions may include, for example, adjustments to thermal compensation to address localized temperature variations, overlay correction to improve alignment accuracy, or dose optimization to maintain critical dimension control. In an embodiment, decision generation unit 430 may incorporate constraints and priorities defined by process parameters or external conditions, such as equipment capacity or environmental factors. The unit may also use real-time data to refine its decisions, ensuring that they remain feasible and effective under current operational conditions. For instance, decision generation unit 430 may modify a proposed adjustment if updated sensor data indicates a change in wafer position or alignment during processing.

Risk assessment engine 440 evaluates the potential risks associated with proposed control decisions, using inputs from UCT optimization engine 410, economic analysis processor 420, and real-time data. For example, risk assessment engine 440 may identify scenarios where a proposed optimization could lead to a higher likelihood of defects, increased cycle time, or other undesirable outcomes. In an embodiment, risk assessment engine 440 may use probabilistic modeling techniques, such as Monte Carlo simulations or Bayesian networks, to quantify the likelihood and severity of potential risks. The engine may also incorporate machine learning models trained on historical process data to identify risk patterns or predict the consequences of specific adjustments. For instance, risk assessment engine 440 may flag a proposed dose adjustment as high risk if similar adjustments in the past have been associated with increased defect density. Based on this analysis, the engine may recommend alternative strategies or mitigation measures, ensuring that decisions are robust and aligned with process objectives.

Control signal generator 450 converts finalized optimization decisions into actionable control signals that are transmitted to control interface 103. These signals enable manufacturing equipment to implement process adjustments in real time, ensuring that the system responds effectively to both planned and unforeseen changes in process conditions. In an embodiment, control signal generator 450 may include mechanisms for validating control signals to ensure compatibility with specific equipment interfaces. For example, the generator may encode signals using standardized communication protocols or apply error-checking algorithms to detect and correct transmission errors. Control signal generator 450 may also prioritize the delivery of signals based on the urgency of the corresponding adjustments. For instance, a signal for correcting an overlay error may be transmitted immediately, while a non-critical adjustment to energy usage may be queued for later execution. By ensuring precise and reliable communication with manufacturing equipment, control signal generator 450 supports the effective implementation of optimization strategies.

Machine learning models present in process optimization subsystem 400 may include, for example, supervised learning models for classification and regression tasks, reinforcement learning models for decision-making, and unsupervised learning models for pattern recognition. In an embodiment, supervised learning models may include neural networks, random forests, or gradient boosting algorithms trained to predict the effects of specific process adjustments on outcomes such as yield, defect density, or cycle time. These models may use labeled datasets that include historical process data, sensor measurements, and corresponding manufacturing outcomes. For instance, a regression model may be trained to predict critical dimension deviations based on parameters such as exposure dose, wafer temperature, and environmental humidity.

Reinforcement learning models may, for example, be employed within UCT optimization engine 410 to refine decision-making policies over time. These models may learn by interacting with simulated or real manufacturing processes, receiving rewards based on metrics such as yield improvement or cost reduction. For instance, a reinforcement learning agent may iteratively adjust overlay correction parameters and receive feedback based on the resulting alignment accuracy. In an embodiment, these models may be trained using a combination of real-world data and synthetic data generated through simulations, enabling them to explore a wider range of scenarios, including rare or extreme conditions.

Unsupervised learning models, such as clustering algorithms or autoencoders, may be used to identify patterns in data without explicit labels. For example, an autoencoder may analyze thermal profiles from sensor array 101 to detect subtle deviations indicative of potential anomalies. These patterns may inform risk assessments or provide additional context for decision generation unit 430. In an embodiment, unsupervised learning models may also be used to group process conditions into clusters, helping to identify similar scenarios that have occurred in the past and guide optimization strategies accordingly.

The training of machine learning models within process optimization subsystem 400 may use datasets provided by data storage unit 260, including historical sensor measurements, manufacturing outcomes, and economic factors. For example, training data may include relationships between wafer alignment and defect rates, or between energy input and yield under different environmental conditions. In an embodiment, training may incorporate cross-validation techniques to evaluate model performance and ensure generalization across diverse operating conditions. Synthetic data generated by simulations may be used to augment real-world datasets, providing additional examples for edge cases or extreme scenarios that are difficult to capture during routine operations.

Once trained, machine learning models may be deployed to support various functions within process optimization subsystem 400. For example, supervised models may assist economic analysis processor 420 in predicting the cost implications of different process strategies, while reinforcement learning models may optimize decision paths explored by UCT optimization engine 410. Unsupervised models may enhance the capabilities of risk assessment engine 440 by identifying hidden patterns in data that could indicate potential risks. These models enable process optimization subsystem 400 to continuously adapt to changing conditions and support intelligent, data-driven decision-making within adaptive semiconductor process control platform 100.

Process optimization subsystem 400 interacts continuously with data integration subsystem 200 and model management subsystem 300, using inputs from these systems to inform optimization and validate outcomes. The outputs of process optimization subsystem 400 provide direct guidance to manufacturing equipment, forming the final step in the decision-making process within adaptive semiconductor process control platform 100. By combining optimization algorithms, economic considerations, and risk assessment, process optimization subsystem 400 supports dynamic and efficient process control.

Data flows through process optimization subsystem 400 in a structured manner, enabling it to generate informed and actionable control decisions. State estimates and knowledge graph data from model management subsystem 300, along with processed data from data integration subsystem 200 received through communications interface 104, are transmitted to UCT optimization engine 410. UCT optimization engine 410 evaluates potential process adjustments by exploring various decision paths, incorporating feedback from real-time process conditions and historical outcomes. Outputs from UCT optimization engine 410 are sent to economic analysis processor 420, which assesses the financial implications of proposed strategies using data such as wafer value, energy costs, and maintenance schedules. The results from economic analysis processor 420, combined with the optimization outputs, are synthesized by decision generation unit 430 to create control decisions tailored to current manufacturing needs. These proposed decisions are evaluated by risk assessment engine 440, which identifies potential risks and recommends modifications if necessary. Finalized control decisions are converted into control signals by control signal generator 450 and transmitted to control interface 103 for implementation by manufacturing equipment. This continuous flow of data ensures that process optimization subsystem 400 remains responsive and aligned with the dynamic requirements of adaptive semiconductor process control platform 100.

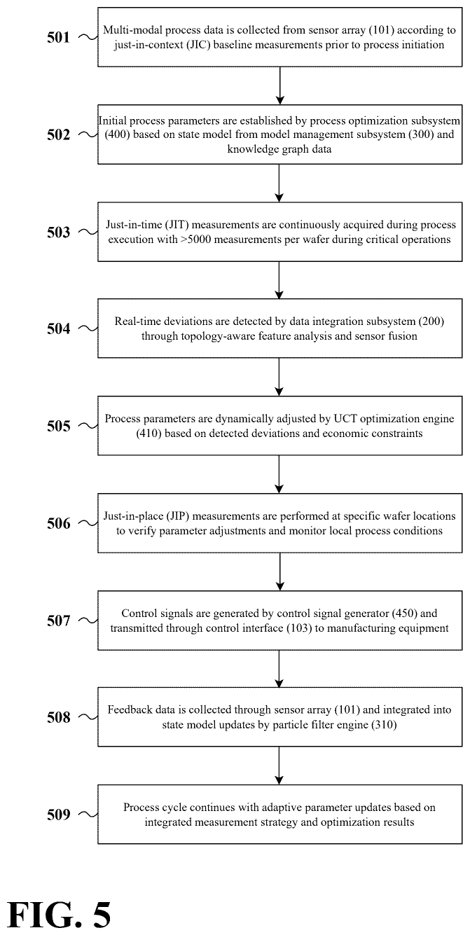

FIG. 5 is a method diagram illustrating the process parameter adjustments of adaptive semiconductor process control platform 100, in an embodiment. Multi-modal process data streams including thermal, positional, and optical measurements are collected from sensor array 101 according to just-in-context baseline measurements, with particular emphasis on pre-bonding alignment verification and initial process conditions 501. Initial process parameters including thermal compensation, overlay correction, and field size adaptation are established by process optimization subsystem 400 using state estimation data and knowledge graph relationships derived from model management subsystem 300 502. Just-in-time measurements are continuously acquired during process execution, with more than 5000 measurements per wafer collected during critical operations such as wafer bonding and lithography steps 503. Real-time deviations in process conditions are detected by data integration subsystem 200 through topology-aware feature analysis, persistent homology calculations, and multi-modal sensor fusion techniques 504. Process parameters are dynamically adjusted by UCT optimization engine 410 based on detected deviations, economic factors including wafer value and energy costs, and risk-weighted calculations using super-exponential regret bounds 505. Just-in-place measurements are performed at specific wafer locations to verify parameter adjustments and monitor local process conditions, with particular focus on regions requiring critical dimension control or overlay accuracy 506. Control signals incorporating thermal compensation, dose optimization, and field size adjustments are generated by control signal generator 450 and transmitted through control interface 103 to the semiconductor manufacturing equipment 507. Feedback data including updated process states and performance metrics is collected through sensor array 101 and integrated into state model updates by particle filter engine 310 using adaptive resampling strategies and multi-hypothesis tracking 508. The process cycle continues with adaptive parameter updates based on the integrated measurement strategy and optimization results, maintaining continuous improvement through real-time feedback loops 509.

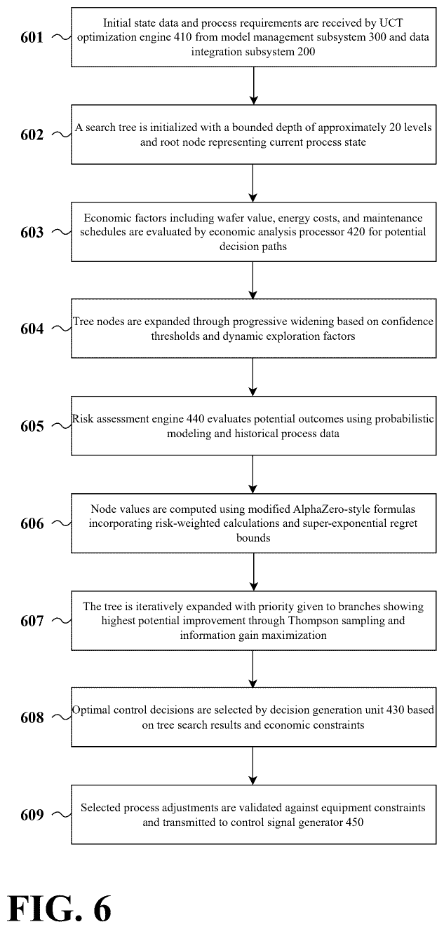

FIG. 6 is a method diagram illustrating the UCT optimization of adaptive semiconductor process control platform 100, in an embodiment. Initial state data comprising particle-based estimations, topology-aware features, and current process requirements are received by UCT optimization engine 410 from model management subsystem 300 and data integration subsystem 200 601. A search tree structure is initialized with a bounded depth of approximately 20 levels and root node representing the current manufacturing process state, including thermal conditions, overlay alignment, and critical dimensions 602. Economic factors including wafer value, energy consumption patterns, maintenance schedules, and material costs are evaluated by economic analysis processor 420 for each potential decision path through the tree 603. Tree nodes are expanded through progressive widening techniques based on dynamic confidence thresholds, exploration factors, and contextual process parameters, enabling multi-scale sampling of the decision space 604. Risk assessment engine 440 evaluates potential outcomes of each decision path using probabilistic modeling, Bayesian networks, and historical process data to quantify uncertainty and potential impacts on yield 605. Node values are computed using modified AlphaZero-style formulas that incorporate risk-weighted calculations and super-exponential regret bounds, ensuring balanced exploration of the decision space while minimizing potential losses 606. The tree is iteratively expanded with priority given to branches showing highest potential improvement, using Thompson sampling for exploration-exploitation balance and information gain maximization to identify valuable decision paths 607. Optimal control decisions are selected by decision generation unit 430 based on tree search results, economic constraints, and predicted process outcomes, with particular emphasis on maintaining process stability and throughput 608. Selected process adjustments are validated against equipment constraints, operational limits, and safety parameters before being transmitted to control signal generator 450 for implementation 609.

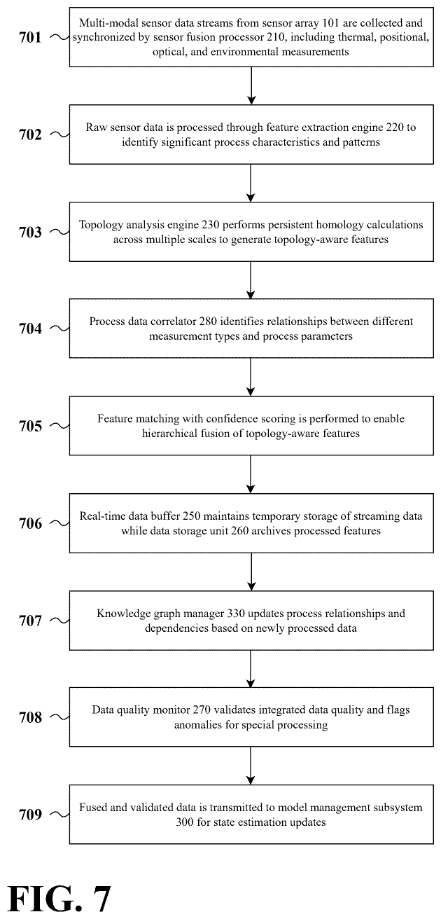

FIG. 7 is a method diagram illustrating the multi-modal data integration of adaptive semiconductor process control platform 100, in an embodiment. Multi-modal sensor data streams from sensor array 101 are collected and synchronized by sensor fusion processor 210, integrating thermal, positional, optical, and environmental measurements through calibration adjustments and temporal alignment techniques 701. Raw sensor data is processed through feature extraction engine 220 to identify significant process characteristics and patterns, including thermal gradients, positional shifts, and surface irregularities using frequency-based analyses and machine learning models 702. Topology analysis engine 230 performs persistent homology calculations across multiple scales to generate topology-aware features, identifying stable regions, transient patterns, and process anomalies through multi-scale topological analysis 703. Process data correlator 280 identifies relationships between different measurement types and process parameters using statistical techniques, mutual information analysis, and causal inference methods to distinguish correlation from causation 704. Feature matching with confidence scoring is performed to enable hierarchical fusion of topology-aware features, using advanced heatmap analysis and edge detection algorithms to refine feature representations 705. Real-time data buffer 250 maintains temporary storage of streaming data using first-in-first-out queueing while data storage unit 260 archives processed features for long-term analysis and model training 706. Knowledge graph manager 330 updates process relationships and dependencies based on newly processed data, incorporating causal relationships, temporal dependencies, and spatial correlations through vector similarity searches and hybrid retrieval strategies 707. Data quality monitor 270 validates integrated data quality and flags anomalies for special processing using statistical outlier detection and machine learning algorithms to identify abnormal sensor readings 708. Fused and validated data is transmitted to model management subsystem 300 for state estimation updates, enabling continuous refinement of process control strategies 709.

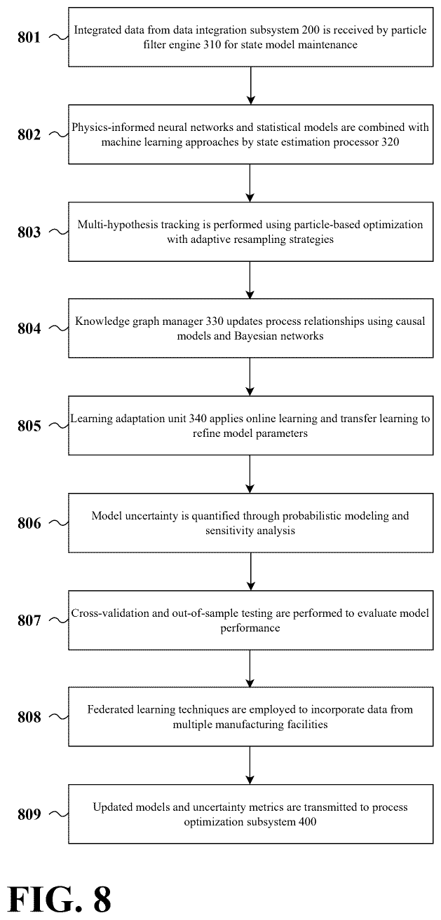

FIG. 8 is a method diagram illustrating the model management method of adaptive semiconductor process control platform 100, in an embodiment. Integrated data from data integration subsystem 200 is received by particle filter engine 310 for state model maintenance, incorporating topology-aware features and real-time sensor measurements into probabilistic state representations 801. Physics-informed neural networks and statistical models are combined with machine learning approaches by state estimation processor 320, embedding physical constraints and domain knowledge directly into the network structure while maintaining adaptability to changing process conditions 802. Multi-hypothesis tracking is performed using particle-based optimization with adaptive resampling strategies, maintaining multiple potential representations of the process state with associated probability weights 803. Knowledge graph manager 330 updates process relationships using causal models and Bayesian networks, enabling vector similarity searches and hybrid retrieval strategies for context-aware process optimization 804. Learning adaptation unit 340 applies online learning and transfer learning to refine model parameters, adapting to new process conditions while leveraging knowledge gained from similar manufacturing scenarios 805. Model uncertainty is quantified through probabilistic modeling and sensitivity analysis, identifying which variables have the greatest impact on process outcomes and establishing confidence intervals for predicted states 806. Cross-validation and out-of-sample testing are performed to evaluate model performance under varying conditions, including stress testing under extreme scenarios and real-world verification of predictions 807. Federated learning techniques are employed to incorporate data from multiple manufacturing facilities while preserving data privacy, enabling collaborative model improvement without sharing raw process data 808. Updated models and uncertainty metrics are transmitted to process optimization subsystem 400 for incorporation into real-time decision-making and control strategies 809.

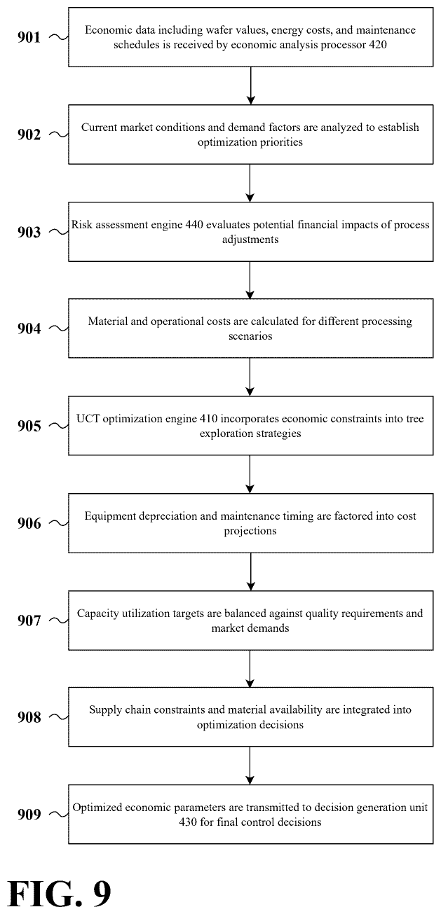

FIG. 9 is a method diagram illustrating the economic optimization method of adaptive semiconductor process control platform 100, in an embodiment. Economic data including wafer values, energy consumption patterns, maintenance schedules, and labor costs is received by economic analysis processor 420 for integration into the optimization framework 901. Current market conditions and demand factors are analyzed to establish optimization priorities, incorporating price premium opportunities and competitive market positioning into throughput decisions 902. Risk assessment engine 440 evaluates potential financial impacts of process adjustments using probabilistic modeling and historical cost data to quantify the likelihood and severity of economic risks 903. Material and operational costs are calculated for different processing scenarios, including consumables usage, energy requirements, and labor allocations across varying production volumes 904. UCT optimization engine 410 incorporates economic constraints into tree exploration strategies, adjusting exploration factors and tree width progression based on risk-weighted value calculations that consider both immediate costs and long-term financial implications 905. Equipment depreciation and maintenance timing are factored into cost projections, enabling decisions that balance immediate performance needs against long-term equipment sustainability and reliability 906. Capacity utilization targets are balanced against quality requirements and market demands, optimizing production schedules to maximize profitability while maintaining required quality standards 907. Supply chain constraints and material availability are integrated into optimization decisions, allowing dynamic adjustment of production strategies based on resource availability and cost fluctuations 908. Optimized economic parameters are transmitted to decision generation unit 430 for incorporation into final control decisions, ensuring that process adjustments align with both technical and financial objectives 909.

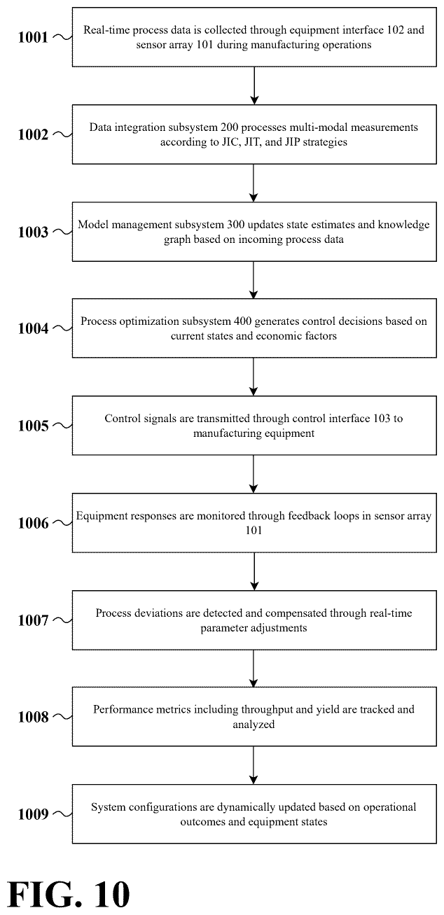

FIG. 10 is a method diagram illustrating manufacturing integration method of adaptive semiconductor process control platform 100, in an embodiment. Real-time process data including thermal, positional, and optical measurements is collected through equipment interface 102 and sensor array 101 during active manufacturing operations 1001. Data integration subsystem 200 processes multi-modal measurements according to just-in-context, just-in-time, and just-in-place strategies, with over 5000 measurements per wafer during critical operations 1002. Model management subsystem 300 updates state estimates and knowledge graph based on incoming process data, using particle-based estimation and topology-aware feature analysis to maintain accurate process representations 1003. Process optimization subsystem 400 generates control decisions based on current states and economic factors through UCT optimization with super-exponential regret bounds and risk-weighted calculations 1004. Control signals incorporating thermal compensation, overlay correction, and field size adaptations are transmitted through control interface 103 to manufacturing equipment for real-time process adjustments 1005. Equipment responses and process outcomes are monitored through comprehensive feedback loops in sensor array 101, enabling continuous validation of control effectiveness 1006. Process deviations from target parameters are detected and compensated through real-time parameter adjustments, with particular emphasis on critical dimension control and overlay accuracy 1007. Performance metrics including wafer throughput, yield stability, edge placement accuracy, and defect density are tracked and analyzed to validate system effectiveness 1008. System configurations including measurement strategies, model parameters, and optimization constraints are dynamically updated based on operational outcomes and equipment states to maintain optimal performance 1009.

In a non-limiting use case example of adaptive semiconductor process control platform 100, the platform is applied to large field lithography optimization in advanced semiconductor manufacturing. Multi-modal sensor array 101 collects real-time measurements during the lithography process, with thermal sensors detecting temperature variations across the expanded field size and optical sensors monitoring critical dimensions at nanometer scales. Data integration subsystem 200 processes over 5000 measurements per wafer during exposure, with measurement timing controller 240 coordinating just-in-time measurements at critical overlay alignment points and just-in-place measurements in regions prone to thermal variation. Topology analysis engine 230 performs persistent homology calculations to identify stable patterns in field edge effects and thermal gradients across multiple scales. Model management subsystem 300 maintains particle-based state estimates incorporating field size variations and thermal expansion effects, with particle filter engine 310 tracking multiple hypotheses about thermal compensation requirements. Process optimization subsystem 400 dynamically adjusts exposure parameters through UCT optimization engine 410, using super-exponential regret bounds to balance exploration of new parameter combinations against exploitation of known stable processes. Economic analysis processor 420 continuously evaluates throughput implications of parameter adjustments, while risk assessment engine 440 monitors potential impacts on yield. The system achieves consistent critical dimension control across field sizes exceeding traditional limits, maintaining 3-sigma overlay accuracy while increasing throughput by reducing the number of exposure steps required per wafer.

In another non-limiting use case example of adaptive semiconductor process control platform 100, the platform manages mixed technology node processing on shared lithography equipment spanning multiple process generations. Sensor array 101 simultaneously monitors multiple process windows corresponding to different technology nodes, collecting position measurements for overlay accuracy, optical measurements for critical dimension control, and thermal measurements for process stability. The topology-aware sensor fusion framework within data integration subsystem 200 identifies node-specific features and process variations, with feature extraction engine 220 applying different detection thresholds appropriate to each technology node's requirements. Real-time data buffer 250 maintains separate data streams for each node, while process data correlator 280 identifies interactions between different process windows. Knowledge graph manager 330 maintains separate but interrelated process models for each technology node, enabling context-aware optimization that accounts for equipment state dependencies. State estimation processor 320 computes confidence-weighted estimates of critical parameters for each node, while learning adaptation unit 340 continuously refines the models based on process outcomes. UCT optimization engine 410 implements parallel decision trees for different nodes, adjusting exploration factors based on the criticality and economic value of each process. Economic analysis processor 420 balances resource allocation based on wafer value and market demand, while control signal generator 450 ensures smooth transitions between different process windows. The system successfully maintains appropriate process conditions for each technology node while optimizing overall equipment utilization, achieving a 25% improvement in equipment efficiency compared to traditional single-node optimization approaches.

In another non-limiting use case example of adaptive semiconductor process control platform 100, the platform is implemented in a high-volume manufacturing environment processing over 10,000 wafers per month across multiple process steps. Sensor array 101 operates continuously across parallel manufacturing lines, with measurement timing controller 240 coordinating data collection to optimize sampling efficiency without creating throughput bottlenecks. Just-in-context measurements establish baseline conditions at the start of each lot, while over 5000 just-in-time measurements per wafer are collected during critical process steps such as lithography and etching. Data integration subsystem 200 processes this high-volume sensor data in real-time, with sensor fusion processor 210 combining inputs from multiple tools running identical processes. Feature extraction engine 220 identifies systematic variations across tools and lots, while topology analysis engine 230 generates persistent features that characterize process stability at different production scales. Real-time data buffer 250 maintains separate streams for each production line while process data correlator 280 identifies cross-tool patterns and drift signatures.

Model management subsystem 300 maintains dynamic state models for each parallel production line, with particle filter engine 310 tracking process states across multiple tools simultaneously. Knowledge graph manager 330 captures relationships between tool-specific behaviors and overall process windows, enabling rapid transfer of optimized parameters across similar tools. Learning adaptation unit 340 implements federated learning techniques to share insights across production lines while maintaining tool-specific optimizations. Process optimization subsystem 400 balances throughput targets against quality requirements, with UCT optimization engine 410 developing separate but coordinated control strategies for each tool. Economic analysis processor 420 continuously evaluates cost-performance tradeoffs, incorporating real-time yield data, energy consumption patterns, and maintenance scheduling across the full production fleet. Risk assessment engine 440 monitors process stability across all lines, triggering preventive adjustments before yield excursions can impact production volumes.

The system achieves consistent wafer-to-wafer and tool-to-tool matching while maintaining maximum throughput, reducing process variability by 40% compared to traditional high-volume manufacturing control approaches. Through dynamic adjustment of sampling strategies and real-time parameter optimization, the platform enables sustained high-volume production while reducing quality excursions and unplanned maintenance events by over 30%.

While several specific embodiments and use cases have been described, one skilled in the art would recognize that adaptive semiconductor process control platform 100 may be applied to numerous other semiconductor manufacturing scenarios. These may include, but are not limited to: advanced packaging applications requiring precise overlay control, three-dimensional integration processes, flexible manufacturing environments with frequent product changes, and specialized process optimization for memory or logic device fabrication. The specific configuration of sensor array 101, data integration subsystem 200, model management subsystem 300, and process optimization subsystem 400 may be adapted based on particular manufacturing requirements, equipment configurations, and economic constraints. Furthermore, the implementation of particle-based estimation, topology-aware feature generation, and UCT optimization strategies may vary while maintaining the core functionality of the platform. The number and type of sensors, measurement strategies, modeling approaches, and optimization parameters may be modified to suit specific applications while remaining within the scope of the invention. Variations in the specific algorithms, neural network architectures, knowledge graph structures, and control strategies may be employed based on the particular requirements of different manufacturing environments and process technologies. Additional components, subsystems, or functional modules may be added, or existing components may be modified or removed, while maintaining the essential characteristics and advantages of the adaptive semiconductor process control platform 100 described herein.

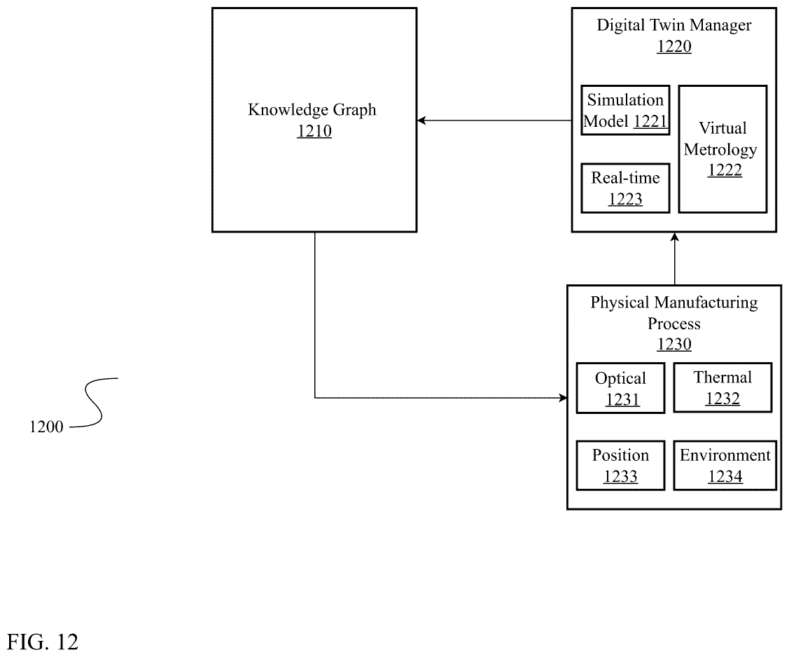

FIG. 12 is a block diagram illustrating exemplary architecture of the digital twin and virtual metrology framework 1200, in an embodiment. This subsystem represents an advanced semiconductor manufacturing control system that operates through continuous real-time monitoring and predictive analysis. At its core, the system integrates three primary components that work in synchronous operation to maintain optimal manufacturing conditions and product quality.

The Physical Manufacturing Process 1230 may employ a sophisticated multi-modal sensor network that continuously monitors wafer processing conditions. Optical sensors 1231 perform real-time surface inspections, detecting pattern variations, defects, and critical dimension measurements at nanometer scales. Thermal sensors 1232 create detailed temperature distribution maps across the wafer surface, monitoring both global and localized heating patterns that could affect process outcomes. Positional sensors 1233 track precise equipment movements, monitoring stage positions, alignment accuracy, and overlay measurements. The environmental sensor network 1234 provides comprehensive monitoring of cleanroom conditions, including temperature, humidity, particle counts, and gas flow rates, all of which can impact process stability.

The Digital Twin Manager 1220 serves as the system's analytical core, processing incoming sensor data through multiple sophisticated algorithms. The Simulation Model 1221 continuously updates finite-element and fluid-structure interaction models that accurately predict wafer behavior under current processing conditions. These models account for complex physical phenomena such as thermal diffusion, mechanical stress distribution, and chemical reaction kinetics. The Virtual Metrology module 1220 performs real-time analysis of critical parameters including effective exposure dose, thickness uniformity, and critical dimension measurements. It processes data in multiple representation formats-vectorized feature sets for rapid analysis, pixelized maps for surface characteristics, and voxelized models for three-dimensional structures. The real-time calibration engine 1223 implements a sophisticated feedback control system that continuously compares predicted outcomes against actual measurements. When deviations are detected, it employs Upper Confidence Tree (UCT) optimization algorithms to determine optimal adjustment strategies. These adjustments might include modifications to scanner overlay corrections, thermal compensation parameters, or exposure dose settings. The system can preemptively adjust processing parameters before deviations become significant enough to impact yield.

The Knowledge Graph 1210 serves as both a historical database and a dynamic learning system. It stores time-series “snapshots” of wafer states, processing conditions, and outcome measurements. This data is structured to enable both immediate process optimization and long-term trend analysis. The graph maintains complex relationships between process parameters, equipment states, and quality outcomes, enabling the system to learn from historical patterns and improve its predictive capabilities over time.

Data flows through the system in multiple pathways. Primary sensor data streams are processed in real-time, with critical parameters being immediately analyzed for potential deviations. Simultaneously, this data is compared against historical patterns stored in the Knowledge Graph to identify any developing trends or potential issues. The real-time calibration loop provides immediate feedback for process control, while longer-term data analysis enables continuous improvement of the prediction models and control strategies. This integrated system enables predictive maintenance, early detection of process drifts, and optimal control of complex manufacturing processes. By maintaining a continuous digital representation of the physical manufacturing process, the system can optimize production parameters in real-time while building a comprehensive understanding of process behavior over time. This results in improved yield, reduced variability, and enhanced process control in advanced semiconductor manufacturing operations.

The system implements multiple complementary data representation methodologies for comprehensive wafer analysis and monitoring, each optimized for specific aspects of semiconductor processing and metrology. These representations enable efficient processing of complex measurement data while maintaining high fidelity for critical process control decisions. The vectorized representation encodes wafer characteristics through precise coordinate-value pairs, where each measurement point is represented by a multi-dimensional feature vector. Each vector contains spatial coordinates (x, y) combined with measured parameters such as film thickness, critical dimensions, or overlay offsets. This representation enables rapid numerical processing and is particularly efficient for machine learning algorithms. The system maintains these feature vectors in a structured array format, allowing for quick comparisons across different wafer regions and process steps. Key measurements at specific locations are preserved with their exact coordinates, enabling precise tracking of site-specific variations.

The pixelized representation transforms wafer surface measurements into a discrete two-dimensional grid, where each pixel corresponds to a defined physical area of the wafer. This grid-based approach enables efficient processing of surface-level measurements such as thickness variations, temperature distributions, or defect patterns. The implementation utilizes a regular matrix structure where each cell contains aggregated measurement data for its corresponding wafer region. This representation is particularly valuable for applying convolutional neural network algorithms for pattern recognition and anomaly detection, as it preserves spatial relationships while providing a standardized input format for analysis.

The voxelized representation extends the spatial analysis into three dimensions, crucial for advanced packaging and through-silicon via (TSV) applications. This volumetric data structure divides the wafer space into cubic elements, each containing measurements of internal characteristics such as stress distributions, void detection, or interlayer alignment. The system implements this using a three-dimensional array structure, where each voxel maintains multiple parameters including density variations, structural integrity measurements, and thermal profiles. This representation is particularly effective for analyzing complex 3D structures and internal defects that cannot be captured by surface-level measurements alone.

The mesh-based representation employs adaptive triangular or tetrahedral elements that conform to the wafer's physical geometry and features. This approach is particularly valuable for modeling irregular structures or regions requiring variable resolution. Each mesh node stores local parameters while the mesh elements define the interpolation space between measured points. The system dynamically adjusts mesh density based on feature complexity, providing finer resolution in areas of high variability or critical importance while maintaining computational efficiency in more uniform regions. This representation excels in finite element analysis applications, enabling accurate simulation of mechanical stress, thermal gradients, and other physical phenomena.

These four representation methods operate in parallel within the subsystem, with automated conversion mechanisms enabling seamless translation between formats as required for different analysis tasks. The system maintains synchronization between representations, ensuring that updates in one format are appropriately reflected in the others. This multi-representation approach enables optimal processing efficiency while preserving measurement fidelity across different analysis contexts.

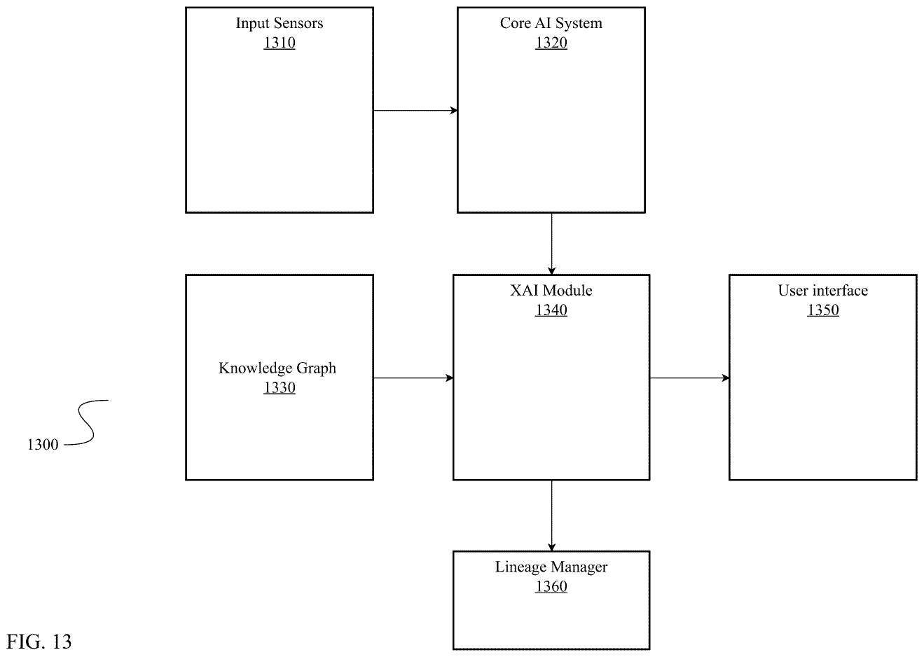

FIG. 13 is a block diagram illustrating exemplary architecture of an explainable artificial intelligence (XAI) subsystem for semiconductor manufacturing control 1300, in an embodiment. The subsystem integrates multiple components designed to enhance transparency and interpretability of AI-driven manufacturing decisions while maintaining high performance and regulatory compliance.

The input sources 1310 may receive and process multiple data streams essential for semiconductor manufacturing control. These inputs may include real-time sensor data from fabrication equipment, process parameters that define manufacturing specifications, and knowledge graph data containing historical process information and relationships. This multi-modal data forms the foundation for both control decisions and their subsequent explanations.

The core AI system 1320 comprises a processing unit that implements multiple artificial intelligence algorithms. This unit houses the Upper Confidence Tree (UCT) optimization engine, particle filters for state estimation, and neural networks for pattern recognition and prediction. The system processes these various input streams to generate optimized control decisions for the semiconductor manufacturing process. Each algorithm contributes specific capabilities: the UCT optimization engine handles complex decision spaces, particle filters manage uncertainty in sensor data, and neural networks identify patterns in process variations.

The XAI Module 1340 represents the central interpretability component of the system. This module contains the Interpretability Engine which processes the intermediate decision states, parameters, and confidence values generated by the UCT optimization engine. The engine implements multiple explanation algorithms including SHAP (SHapley Additive explanations) for feature attribution, LIME (Local Interpretable Model-agnostic Explanations) for local interpretation, Grad-CAM for visualization of neural network decisions, and Saliency Mapping for highlighting critical regions. In response to operator requests, audit triggers, or anomaly alerts, the Interpretability Engine retrieves relevant AI model states and process data from the knowledge graph, then executes interpretability algorithms that map decision nodes to ranked significance scores.

The Knowledge Graph 1330 maintains a structured database of explanation nodes that contain Causal Assertions documenting cause-effect relationships, Model Version information tracking AI system iterations, Confidence Values quantifying decision reliability, and Explanatory Links connecting process parameters to outcomes. Each explanation node contains causal assertions that state the causal chain discovered by the AI, such as correlations between temperature variations and film thickness defects. The nodes also store model version and confidence values, referencing specific AI model versions used to compute effect magnitudes. This structure enables engineers and auditors to trace back from parameter changes to the underlying sensor anomalies or topological features that triggered them.

The User Interface 1350 provides comprehensive visualization and interaction capabilities through saliency maps, color-coded wafer overlays, explanatory text, and confidence metrics. The interface displays color-coded overlays and saliency maps for rapid human interpretation, allowing lithography engineers to quickly identify critical regions through an explanation panel. Red or orange shading denotes areas associated with high confidence in imminent defects, while green shading signifies stable zones. Tooltips provide additional context by explaining which sensor signals triggered specific concerns.

The Lineage Manager 1360 implements audit and tracking functionality through comprehensive audit logs, model history tracking, and explanation records. This component ensures tamper-evident storage through cryptographic hashing and secure timestamps for each explanation record. When AI models are updated, the system logs differences between old and new models, automatically comparing changes in explanation patterns. This approach fulfills traceability requirements and enables fab operators to demonstrate consistency in process decisions before and after model updates.

The system employs a sophisticated scheduling algorithm to manage explanation generation, determining which explanations or saliency maps require near real-time processing versus deferred batch processing. This ensures operators can act confidently on system recommendations without experiencing excessive delays. The XAI subsystem extends beyond the UCT engine to include particle filters and deep neural networks used for real-time sensor fusion, capturing intermediate states that influence wafer process decisions.

Implementation variations include Lightweight vs. Comprehensive Explanations for different throughput conditions, Hierarchical Explanation Trees for navigating complex optimization problems, and Modular Deployment options for separate hardware resource allocation. This architecture seamlessly integrates interpretability and transparency into the AI-driven semiconductor control environment, improving trust, debugging efficiency, and readiness for regulatory oversight. By incorporating specialized interpretability features, comprehensive lineage tracking, and advanced visualization capabilities, the system addresses the critical need for manufacturing professionals to understand, validate, and refine AI-driven control signals while ensuring accountability and regulatory compliance.

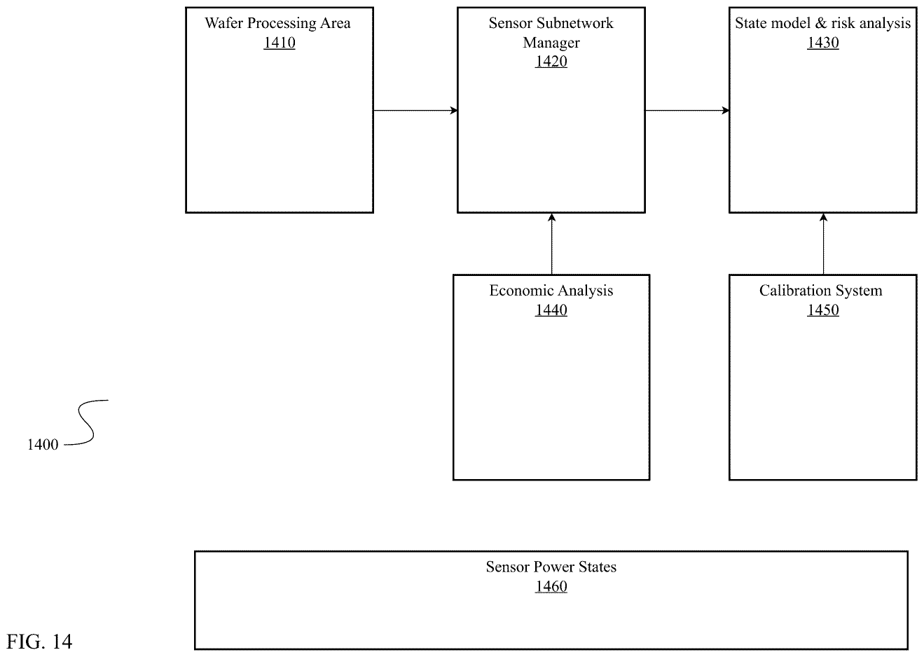

FIG. 14 is a block diagram illustrating exemplary architecture of an energy-aware sensor orchestration system for adaptive power management and contextual activation in semiconductor manufacturing 1400, in an embodiment. The system implements a sophisticated approach to dynamically manage sensor usage based on predicted data utility, extending beyond conventional static gating or fixed sampling schedules. The architecture employs AI-driven decision logic, including reinforcement learning and multi-armed bandits, to selectively power or adjust sensor subsets in real time, ultimately reducing overall energy consumption while maintaining high wafer yield and low defect rates.

The system centers around a specialized software module, the “sensor subnetwork manager” 1420, which continuously monitors incoming data from multiple sensor modalities within the wafer processing area 1410. These sensors include thermal, optical, positional, and chemical sensors, each represented as distinct nodes in the sensor network. The subnetwork manager 1420 employs AI-based heuristic algorithms, such as Q-learning, policy-gradient reinforcement learning, or multi-armed bandit strategies, treating each sensor as an “arm” that yields a time-varying reward corresponding to its marginal contribution to reducing uncertainty in process parameters or improving yield predictions.

Working in concert with the sensor subnetwork manager 1420, an economic analysis processor 1440 continuously evaluates sensor energy costs, maintenance overhead, and wafer value. These parameters are stored in the knowledge graph for real-time retrieval, with sensors requiring frequent calibration or having high power draw being assigned higher “cost coefficients.” The system performs ongoing cost-benefit analyses, seeking to maximize yield improvements while minimizing total sensor operation costs. This economic perspective allows the platform to make informed decisions about whether enabling expensive sensors is justified based on potential yield gains.

The state model and risk analysis 1430 integrates seamlessly with the UCT optimization engine to track potential risk hotspots on the wafer. When the system predicts higher probabilities of overlay misalignment, local thermal runaway, or doping inconsistencies in specific regions or process phases, it implements “just-in-place” activation or “just-in-time” sampling strategies. For example, if the UCT engine detects a wafer edge approaching critical temperature uniformity limits, the system dynamically activates multiple thermal sensors in that region while maintaining lower-power monitoring modes in unaffected areas.

A comprehensive calibration system 1450 operates in parallel, implementing continuous calibration and drift compensation loops. This component compares real-time sensor data against reference baselines and cross-checks multiple overlapping sensors for redundancy and consistency. Upon detecting significant deviations from expected tolerances or breakdowns in sensor correlations, the system either initiates automated re-calibration procedures or transitions affected sensors to lower activity states pending manual servicing.

The system supports multiple power states 1460 for each sensor through hardware-level control signals, communicated via I²C, SPI, or custom fieldbus protocols. These states include fully powered operation for high-frequency sampling, idle mode for ultra-low power consumption, and partial sleep states where only internal housekeeping functions remain active. The subnetwork manager maintains precise control over these states, capable of adjusting sampling rates from hundreds of samples per second to tens of samples per second, or modifying bit-depth for analog-to-digital converters as needed.

Operating at multiple levels, the system implements both real-time adjustments at the individual sensor level and broader strategic changes at the batch or shift level. For standard logic devices exhibiting consistent, stable conditions, the system might define a “low-power sensor mode,” activating only the highest utility sensors except during anomalies. Conversely, for advanced or high-value wafers with tight overlay requirements, the system maintains full sensor activation. This multi-level approach ensures optimal balancing of cost, risk, and throughput under dynamic manufacturing demands.

The architecture includes fail-safe mechanisms that trigger sensor reactivation if the model management subsystem detects intolerable spikes in uncertainty. Additionally, the system synergizes with predictive maintenance functions, incorporating sensor reliability estimates into activation decisions to prevent corrupted readings from unreliable sensors. Through this comprehensive approach to sensor orchestration, the system achieves a balance between data fidelity and energy efficiency while maintaining robust wafer quality and yield in large-scale manufacturing environments.

The operational flow demonstrates how the system dynamically adapts sensor orchestration during wafer processing. The system initiates with all sensors operating at nominal rates to establish baseline data for wafer alignment, temperature, and thickness measurements. As processing continues, the AI heuristic system detects minimal variations across several wafers and determines that certain sensors, particularly high-resolution thermal arrays, are providing low marginal gains in data utility. In response, the manager reduces the sampling rates of these arrays and transitions them into partial sleep states, achieving a significant 60% reduction in power consumption. The scenario then progresses to demonstrate the system's adaptive capabilities when midway through processing, a new wafer type begins production. The UCT algorithm identifies a potential overlay drift in a specific wafer region, prompting the manager to reactivate additional positional sensors near the affected area. The system's economic analysis module evaluates this change, noting a slight increase in energy consumption but determines that the potential yield savings from mitigating overlay errors justifies the cost of sensor reactivation. The example concludes with an on-demand calibration scenario where routine monitoring discovers a humidity sensor drifting beyond acceptable parameters. The system responds by either initiating automatic recalibration, if supported by the hardware, or flagging the sensor for manual maintenance intervention. During this period, the platform maintains operational continuity by utilizing correlation data from a backup humidity sensor to partially compensate for the drift, demonstrating the system's robust fault management capabilities.

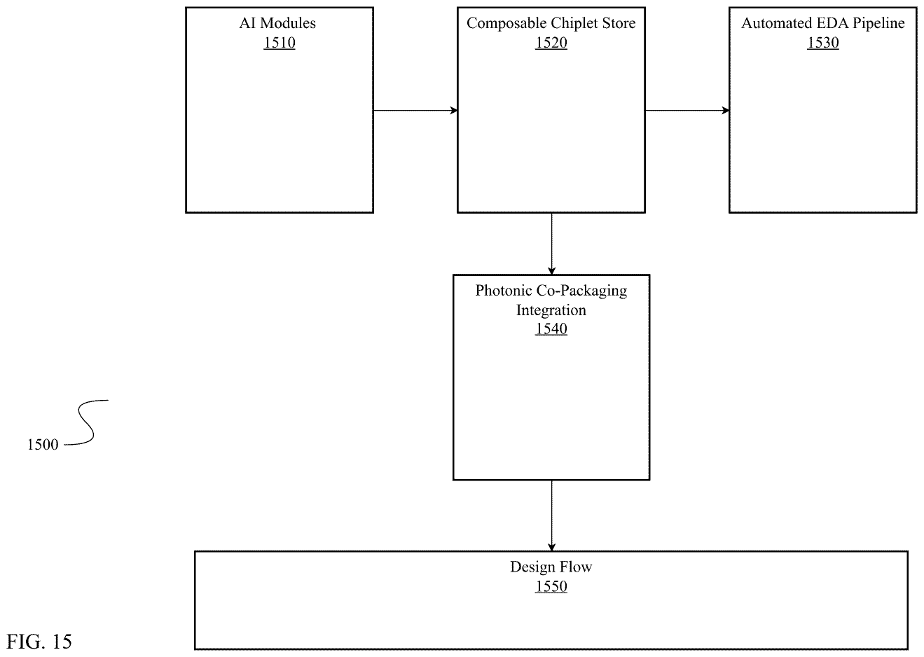

FIG. 15 is a block diagram illustrating exemplary architecture of an AI-driven composable chiplet store and automated EDA pipeline system designed to improve modularity, composability, and interoperability in semiconductor packaging, particularly for chiplet-based designs and advanced packaging applications 1500, in an embodiment. The system integrates multiple AI modules 1510, a standardized chiplet store 1520, and an automated EDA pipeline 1530 to streamline the creation of a comprehensive chiplet ecosystem with standardized solutions.

The system's foundation comprises several specialized AI modules 1510 that work in concert to enable sophisticated package design and analysis. A thermal wave expert and stress/strain expert provide advanced modeling capabilities for thermal behavior and mechanical warpage analysis, which are crucial for evaluating how new chiplets will perform in defined 2.5D or 3D package environments. The system incorporates Mirasol3B-based chunking for processing time-aligned sensor data alongside contextual design information, while a Titans memory component enables long-term storage of successful packaging recipes and floorplans. The DeepSeek-R1 reinforcement learning module continuously optimizes different aspects of package design, from floorplan arrangements to interposer designs and co-packaged optics alignments.

The composable chiplet store (CCS) 1520, serves as a comprehensive catalog of modular chiplets. This store maintains standardized specifications for each chiplet, including UCIe or AIB interface specifications, thermal and power profiles, optical waveguide alignment guidelines for photonic components, and mechanical attachment specifications such as bump pitch and warpage tolerances. The store features an automated compatibility checking system that evaluates potential interactions between selected chiplets, verifying I/O compliance, assessing pin assignment conflicts, and analyzing potential warpage issues through quick multi-physics simulations.

The automated EDA pipeline 1530 represents the system's execution layer, implementing a hierarchical flow that begins with system-level floorplanning. The AI engine leverages multi-modal data and reinforcement learning to arrange chiplets on interposers or in 3D stacks while respecting various constraints including height limitations, waveguide alignment for photonics, and heat zones in high-performance computing applications. The pipeline performs comprehensive packaging analysis, including automated 2.5D or 3D route planning, warpage and stress evaluations, thermal wave simulation for temperature gradient analysis, and real-time design rule checks for mechanical reliability.

A specialized photonic co-packaging integration layer 1540 manages the unique challenges of optical I/O implementation. This component handles waveguide routing in the interposer while monitoring alignment sensitivity and thermal drift. The thermal wave model ensures that high-power components do not compromise photonic coupling precision, while the reinforcement learning system explores alternative floorplans to maintain alignment stability across predicted thermal cycles.

The system implements a clear design flow progression 1550, beginning with chiplet import from the store, proceeding through AI-driven floorplanning and automated EDA processes, and culminating in final signoff and package assembly documentation. Throughout this flow, the system generates comprehensive documentation including a Package Assembly Design Kit (PADK) that specifies bills of materials, precise component positioning, and detailed coupling strategies. The process concludes with a feedback loop where actual manufacturing data is fed back into the Titans memory, enabling continuous refinement of design heuristics for future iterations.

This integrated approach significantly reduces customization overhead while enhancing interoperability across the chiplet ecosystem. The system's wave-based modeling and comprehensive stress/strain analysis ensure reliable final assemblies, encouraging broader adoption of chiplet-based designs. Through multi-physics simulation at scale and continuous refinement via real-time updating, the system achieves enhanced reliability and performance while maintaining the flexibility to accommodate rapid changes in advanced packaging technologies, particularly in AI, HPC, and photonics applications.

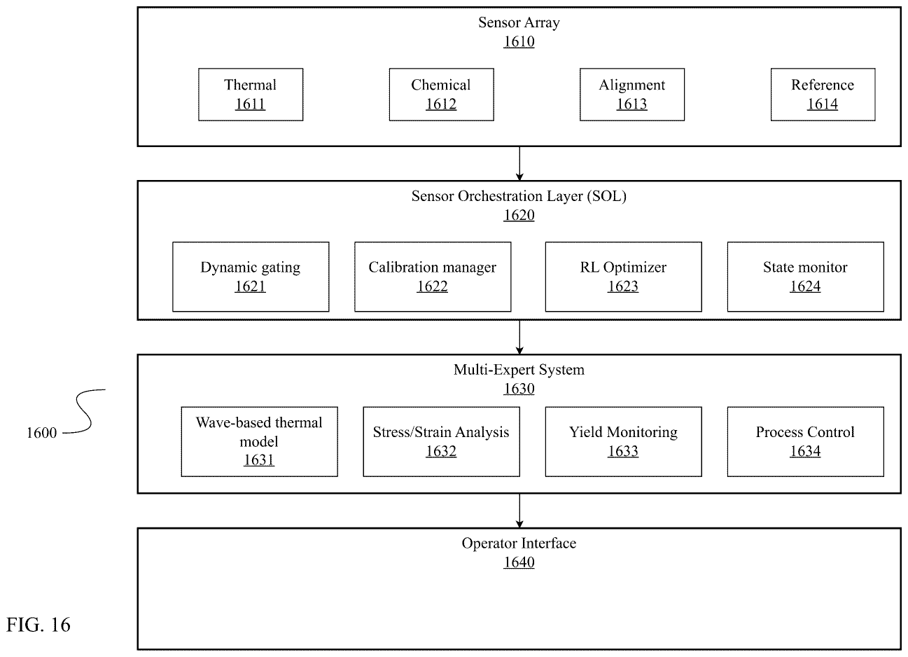

FIG. 16 is a block diagram illustrating exemplary architecture of an intelligent sensor orchestration subsystem designed for dynamic sensor management in semiconductor manufacturing environments, 1600, in an embodiment. The system implements a hierarchical approach to sensor control, calibration, and power optimization, integrated within a multi-expert AI-driven process control platform. This architecture enables sophisticated management of sensor arrays while maintaining measurement fidelity and optimizing energy consumption.

The sensor array 1610 consists of multiple sensor groups categorized by functionality. These groups include thermal sensors 1611, chemical sensors 1612, alignment sensors 1613, and reference sensors 1614, each supporting multiple power states (active, idle, and sleep) for granular power management. The reference sensors 1614 serve as calibration standards, providing baseline measurements for system-wide accuracy verification. Each sensor group operates independently yet remains coordinated through the central orchestration layer, allowing for precise control of measurement density and power consumption across the manufacturing environment.

The Sensor Orchestration Layer (SOL) 1620, may implement four key components working in concert. Dynamic Gating 1621 manages individual sensor control and cluster management, determining which sensors should be active based on real-time manufacturing requirements. The calibration manager 1622 handles drift detection and automatic correction, continuously monitoring sensor accuracy through cross-correlation and particle filter-style state estimation. The Reinforcement Learning Optimizer 1623 balances power optimization with measurement quality, employing a custom reward function to discover optimal gating patterns. The State Monitor 1624 tracks sensor health and generates status reports, maintaining comprehensive oversight of the entire sensor network.

The Multi-Expert System 1630 provides specialized domain knowledge and analytical capabilities that inform sensor orchestration decisions. This layer includes a Wave-Based Thermal Model 1631 for heat distribution analysis, Stress/Strain Analysis 1632 for mechanical deformation monitoring, Yield Monitoring 1633 for quality control, and Process Control 1634 for manufacturing optimization. These expert systems collaborate with the SOL to ensure that sensor activation patterns align with current process requirements and potential risk factors. For instance, when the thermal model indicates stable conditions, the system can reduce thermal sensor sampling rates, while increased stress readings might trigger enhanced monitoring in specific regions.

The Operator Interface 1640 may provide comprehensive diagnostics, manual override capabilities, and status monitoring functionality. This interface displays real-time sensor health metrics and calibration status, allowing human operators to observe system behavior and intervene when necessary. The interface supports both automated operation and manual control, ensuring flexibility in responding to unexpected situations or special processing requirements.

Through this hierarchical architecture, the system achieves intelligent sensor orchestration that adapts to changing manufacturing conditions while preserving measurement accuracy and energy efficiency. The combination of dynamic gating strategies, automated calibration mechanisms, and reinforcement learning optimization creates a robust platform capable of managing complex sensor networks in advanced semiconductor manufacturing environments.

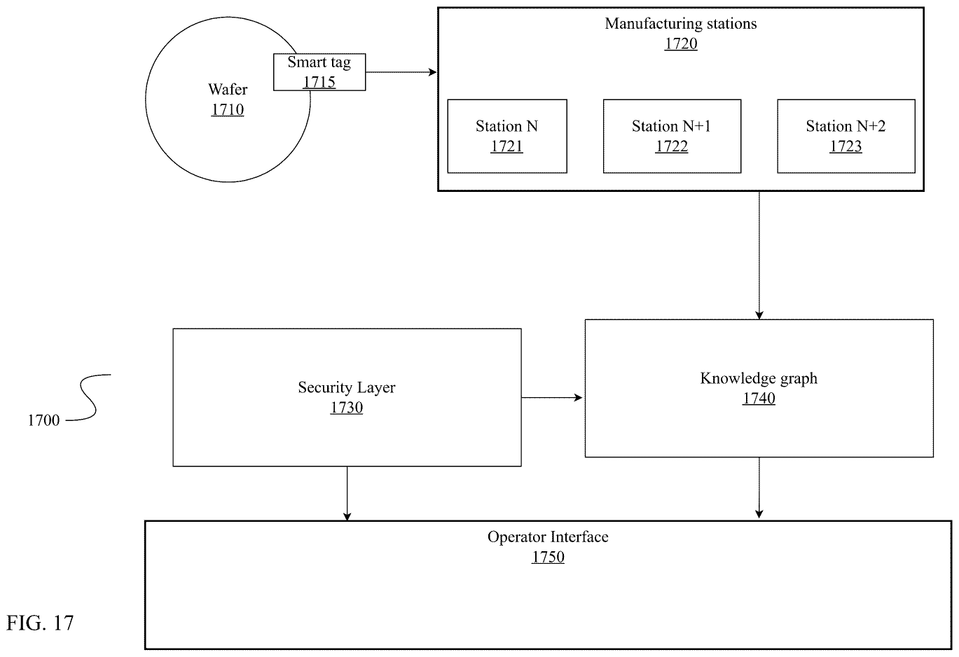

FIG. 17 is a block diagram illustrating exemplary architecture of a wafer-level smart tag system architecture designed for real-time identification, data capture, and lifecycle tracking within a semiconductor manufacturing environment 1700, in an embodiment. The system implements a comprehensive approach to wafer tracking and process management through the integration of physical smart tags with a distributed control and monitoring infrastructure.

The system centers around a wafer 1710 equipped with an ultra-thin, flexible smart tag 1715 module positioned on or near the wafer surface. This smart tag 1715 incorporates non-volatile memory and a low-power wireless transceiver, capable of storing and transmitting critical wafer data throughout the manufacturing process. The tag's hardware configuration includes EEPROM or flash memory with capacity ranging from kilobytes to megabytes, sufficient for storing essential parameters, sensor logs, and recipe instructions. The tag may optionally include embedded sensors for environmental monitoring, all contained within a substrate designed to withstand repeated thermal cycles, chemical exposure, and mechanical stress.

Multiple manufacturing stations 1720 form a key component of the system, each equipped with tag readers and writers for wireless data exchange. As illustrated, Station N 1721, Station N+1 1722, and Station N+2 1723 represent sequential processing steps, each capable of both reading existing wafer data and writing new process information to the tag. These stations implement closed-loop communication mechanisms using near-field or short-range protocols, including ISO/IEC 14443 NFC or custom low-power RFID channels. When a wafer enters a station, the system retrieves stored identifiers and process data, while simultaneously updating the tag with new instructions for subsequent processing steps.

The Knowledge Graph 1740 serves as the system's central data repository, maintaining comprehensive records of process history, correlations, and yield analysis. This graph structure stores long-term relationships and hierarchical process flows for each wafer, synchronizing with the smart tags at each station to ensure data consistency. The system implements a sophisticated synchronization routine that maintains consistency between the wafer tag's local data and the knowledge graph, even during periods of intermittent network connectivity.

A dedicated security layer 1730 implements robust supply chain protection through blockchain or distributed ledger technology. This layer creates cryptographic proofs of manufacturing steps, equipment usage, and test results, establishing an immutable record of each wafer's journey through the fabrication process. The security implementation includes encrypted communications between tags and station readers, with authentication handshakes protecting intellectual property and manufacturing secrets.

The Operator Interface 1750 provides comprehensive visibility and control over the entire system. Through this interface, operators can access real-time status dashboards, implement manual overrides when necessary, and manage process flows. The interface displays wafer identification, last process step, sensor anomaly flags, and next-step instructions, enabling immediate operator response to process variations or quality concerns.

This integrated approach ensures unbroken chain of wafer-specific data throughout the manufacturing lifecycle, from initial lithography through final testing. The system accommodates high-volume production environments through sophisticated data management strategies, including compression, rolling logs, and intelligent data retention policies. Through this comprehensive architecture, the system enables dynamic recipe adaptation, enhanced yield analysis, and robust supply chain security while maintaining efficient, error-resistant manufacturing operations.

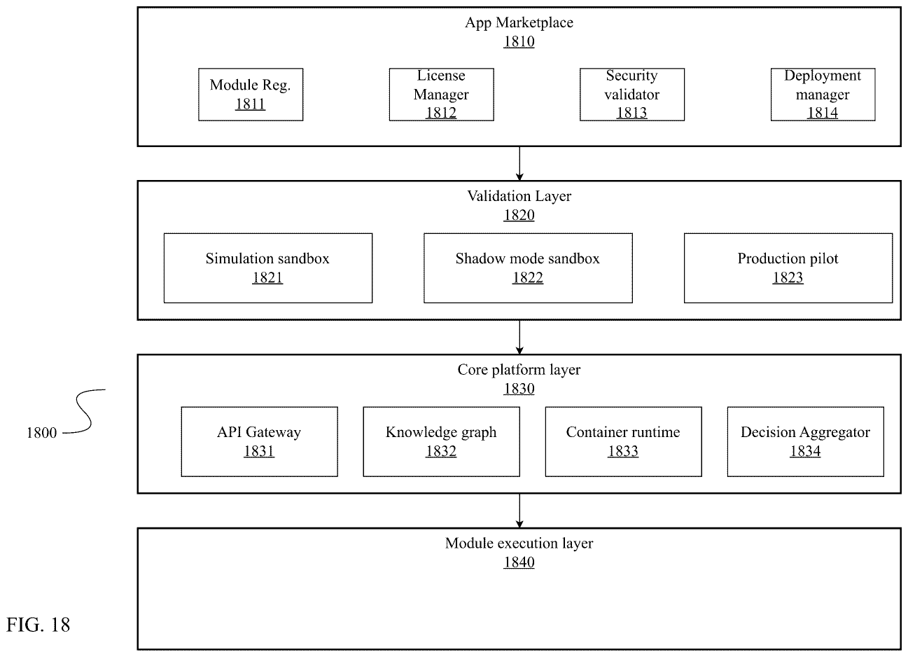

FIG. 18 is a block diagram illustrating exemplary architecture of a modular “app store” architecture designed for integrating third-party process control extensions into a semiconductor manufacturing platform 1800, in an embodiment. The system implements a hierarchical approach to module management, validation, and execution, comprising multiple specialized layers that work in concert to ensure secure and efficient integration of external components.

The App Marketplace Layer 1810 incorporates a module registry 1811 for version control and component tracking, a License Manager 1812 that handles usage tracking and monetization, a Security Validator 1813 that processes digital signatures and authentication, and a Deployment Manager 1814 responsible for container orchestration. These components collectively ensure that third-party modules are properly registered, validated, and prepared for deployment within the manufacturing environment.

The validation layer 1820 implements a comprehensive three-tier testing and verification system. The first tier consists of a Simulation Sandbox 1821 that utilizes historical data replay and performance testing to evaluate modules in a controlled environment. The second tier comprises a Shadow Mode Sandbox 1822 that processes real-time data streams while operating in an advisory capacity, allowing for performance evaluation without affecting production systems. The final tier involves a Production Pilot 1823 environment where modules undergo limited deployment with active monitoring to verify their performance under real manufacturing conditions.

The Core Platform Layer 1830 provides the fundamental infrastructure for module execution and integration. An API Gateway 1831 supports REST/gRPC endpoints and SEMI standards, enabling standardized communication between modules and the platform. The Knowledge Graph 1832 manages data integration and state management, while the Container Runtime 1833 handles resource management and module isolation. A decision aggregator 1834 implements conflict resolution and parameter optimization, ensuring coherent operation when multiple modules provide competing recommendations.

At the foundation lies the Module Execution Layer 1840, where third-party modules operate within their containerized environments. This layer supports diverse applications ranging from EUV overlay optimization and defect detection to 3D packaging analysis and custom analytics solutions. Each module operates independently within its defined container while maintaining secure communication channels with the platform through the standardized API.

This integrated approach enables semiconductor manufacturers to leverage specialized third-party innovations while maintaining operational integrity. The platform's containerized deployment strategy, combined with comprehensive validation protocols and secure API frameworks, ensures that each module can be safely integrated into the production environment. Through this architecture, the system facilitates a dynamic ecosystem where advanced process control solutions can be developed, tested, and deployed across multiple manufacturing facilities while maintaining strict security and performance standards.

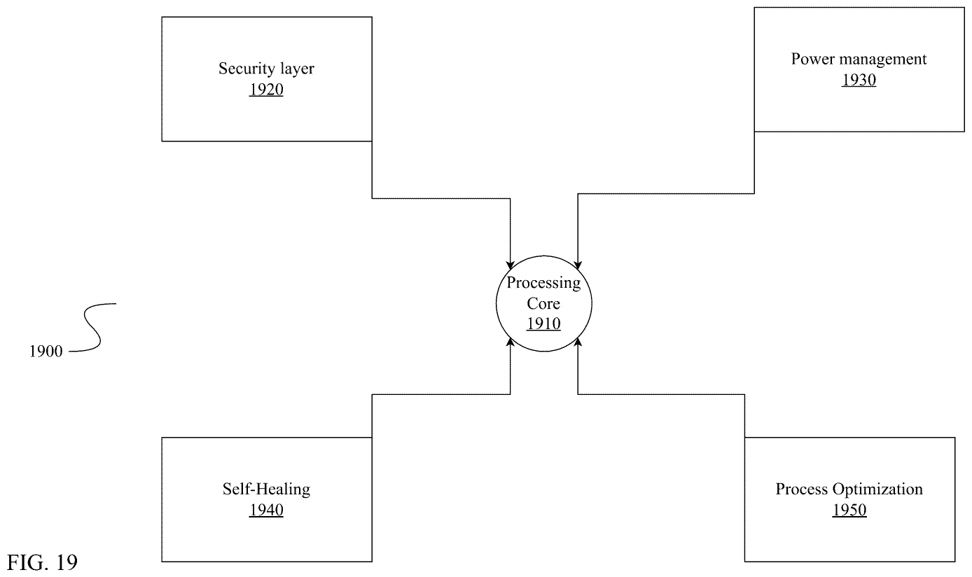

FIG. 19 is a block diagram illustrating exemplary architecture of an enhanced smart tag system architecture for semiconductor wafer tracking and process optimization 1900, in an embodiment. The system implements a multi-layered approach to sensor integration, data processing, and security, all contained within an ultra-thin substrate directly bonded to or embedded within the semiconductor wafer surface.

At the foundation of the system lies the silicon wafer, upon which multiple specialized sensor arrays are strategically positioned. These include MEMS-based vibration and acceleration sensors for detecting mechanical disturbances and handling anomalies, chemical residue sensors utilizing functionalized micro cantilevers or mini-ion-sensitive field-effect transistors for contamination detection, and distributed strain gauges for measuring mechanical deformation and wafer bowing. Complementing these sensors are energy harvesting components that capture power from various sources including radio-frequency emissions, thermal gradients, and mechanical vibrations.

The system's central processing core 1910, houses advanced edge computing capabilities and neural network implementations. This core contains a microcontroller or low-power FPGA that executes local inference tasks, processes sensor data, and manages security operations. The processing unit supports multiple operational states, from full active mode for critical processing steps to low-power sleep states during idle periods, all orchestrated by sophisticated power management algorithms.

The security layer 1920 implements quantum-resistant cryptographic protocols and hardware-based security measures. This includes a physically unclonable function (PUF) module for generating unique wafer identities, secure enclaves for protecting sensitive data, and advanced encryption mechanisms resistant to both classical and quantum computing attacks. The security architecture ensures authenticated access to wafer data while preventing unauthorized modification or counterfeiting attempts.

Power management 1930 is handled through a dedicated subsystem that implements multi-level power states and adaptive switching mechanisms. The system dynamically adjusts its power consumption based on process requirements, environmental conditions, and available energy harvesting opportunities. This sophisticated power management enables extended operational periods without requiring external power sources, while ensuring critical monitoring functions remain active during high-risk processing steps.

The self-healing 1940 capabilities are implemented through redundant memory banks with error-correction coding (ECC), fault isolation mechanisms, and adaptive reconfiguration capabilities. When damage or errors are detected, the system can isolate affected components and redistribute functionality to maintain essential operations. Additionally, the substrate incorporates advanced materials such as phase-change materials for thermal management and self-repairing conductive pathways for maintaining electrical connectivity.

Process optimization 1950 features are integrated through a combination of federated learning capabilities, genetic algorithms, and real-time yield prediction mechanisms. The system participates in distributed learning schemes, sharing aggregated performance data while maintaining wafer-specific privacy. Genetic algorithms optimize process parameters based on historical performance, while real-time analysis of sensor data enables early yield prediction and process intervention.

The system maintains continuous communication between sensor arrays, the processing core, and various subsystems, ensuring rapid response to anomalies while optimizing power consumption and processing resources. This integrated approach enables autonomous monitoring, real-time decision making, and process optimization throughout the wafer manufacturing lifecycle.

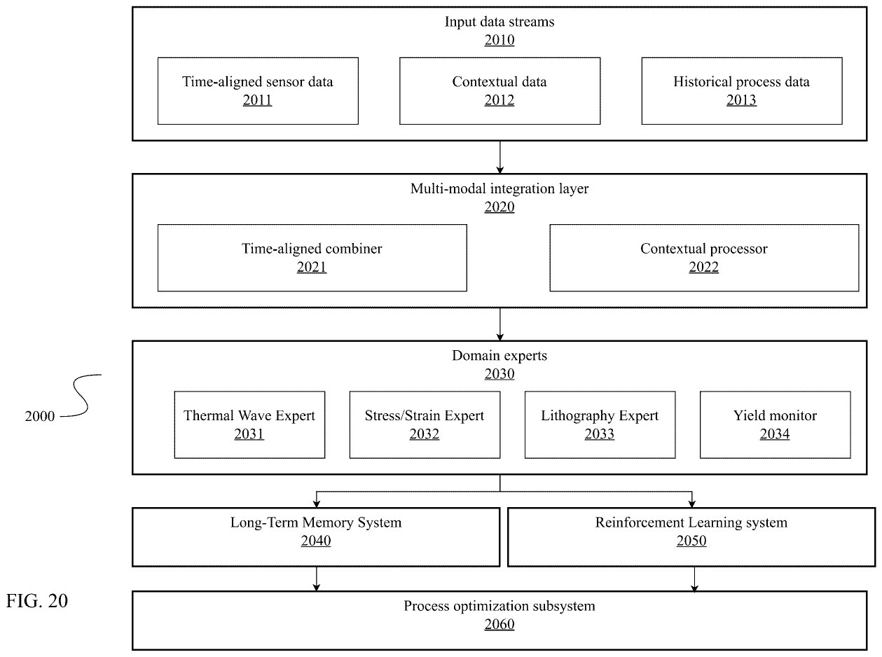

FIG. 20 is a block diagram illustrating exemplary architecture of a temporal dynamics and multi-model integration system for semiconductor process control, implementing an advanced architecture that combines multiple data streams, expert systems, and adaptive learning mechanisms 2000, in an embodiment. The system enables sophisticated process control through the integration of time-aligned sensor data, contextual information, and historical process knowledge.

The system begins with the Input Data Streams layer 2010, which processes three distinct types of information: time-aligned sensor data 2011 comprising high-frequency measurements from various sensors, contextual data 2012 including recipe specifications and engineering documentation, and historical process data 2013 from previous manufacturing runs. These diverse data streams provide comprehensive coverage of the manufacturing process from multiple temporal and operational perspectives.

The Multi-Modal Integration Layer 2020 serves as a sophisticated data fusion mechanism, incorporating two primary components. The Time-Aligned Combiner 2021 processes and synchronizes high-frequency sensor data streams through chunk-based processing, while the Contextual Processor 2022 handles recipe information and log analysis. This layer enables seamless integration of both real-time and historical data, creating unified representations for downstream processing.

The Domain Experts layer 2030 encompasses examples of specialized processing modules for different aspects of semiconductor manufacturing. A Thermal Wave Expert 2031 may analyze heat distribution and thermal dynamics, a Stress/Strain Expert 2032 may evaluate mechanical deformations and material responses, the Lithography Expert 2033 may focus on precision patterning processes, and the Yield Monitor 2034 may track and predict manufacturing outcomes. Each expert module maintains its own specialized processing algorithms while sharing information through standardized interfaces.

A Long-Term Memory System 2040 implements advanced data retention and retrieval mechanisms, enabling test-time memory management with adaptive capabilities. This system maintains historical knowledge of process parameters, anomalies, and outcomes, allowing the system to learn from past experiences and apply this knowledge to current manufacturing operations. The memory system implements sophisticated retrieval mechanisms and can adaptively adjust its storage based on the relevance and importance of information.

The Reinforcement Learning System 2050 provides advanced reasoning capabilities through chain-of-thought validation and iterative improvement. This component enables the system to learn from outcomes and refine its decision-making processes over time. It implements sophisticated reward mechanisms based on manufacturing yields, quality metrics, and efficiency parameters, allowing continuous optimization of process controls.

At the foundation of the system, the Process Optimization Subsystem 2060 generates final control signals and recipe adjustments based on the integrated outputs from all upper layers. This subsystem combines recommendations from domain experts, historical insights from the memory system, and learned optimizations from the reinforcement learning component to produce coherent control decisions.

This integrated approach enables sophisticated process control while maintaining the flexibility to accommodate new manufacturing technologies and requirements. The system's modular architecture allows for the addition or modification of expert modules as new processing technologies emerge, while the underlying memory and learning systems ensure continuous improvement in manufacturing efficiency and yield.

The system's operation can be illustrated through a representative example of an EUV lithography step with thermal anomalies. Initially, an IR scanner captures temperature frames at 100 Hz, with the time-aligned combiner extracting relevant wave dynamics. The memory system then recalls that a similar hotspot pattern was observed five wafers ago, which correlated with reticle distortion if not corrected early. The Layer-Specific Lithography Expert, utilizing reinforcement learning, proposes a mild scanning speed reduction combined with a local dose adjustment. If this intervention successfully reduces overlay errors without significantly impacting throughput, the event is logged in memory to increase future confidence. In cases where the intervention fails, the system attempts alternative approaches in subsequent operations.

For ALD or etch processes with dynamic pulse timing, the system encodes real-time plasma or precursor injection signals. The combiner generates compact representations of these signals, while the memory system references prior wafer runs to identify similar anomalies. The reinforcement learning logic then attempts to adjust pulse lengths to achieve better uniformity.

The system leverages several advanced AI architectures. The Mirasol3B approach enables multimodal integration of time-aligned data (such as high-frequency sensor streams) with contextual data (including textual instructions and design documents). This architecture allows streaming of partial outputs from the time-aligned sub-model back to the contextual sub-model for rapid process corrections. The Titans memory architecture implements neural long-term memory with adaptive forgetting mechanisms, providing both short-term context for local decisions and long-term memory that accumulates historical anomalies, wave-based hotspots, and mechanical warpage episodes. This approach enables wafer-spanning consistency and reduced rework through accumulated experience at inference time.

The DeepSeek-R1 reinforcement learning implementation enables chain-of-thought refinement and self-correction capabilities. The system employs a multi-stage approach, beginning with baseline data from standard domain experts, followed by reinforcement learning fine-tuning with real or simulated wafer outcomes, and finally distillation into smaller domain sub-models for edge computing applications near the equipment.

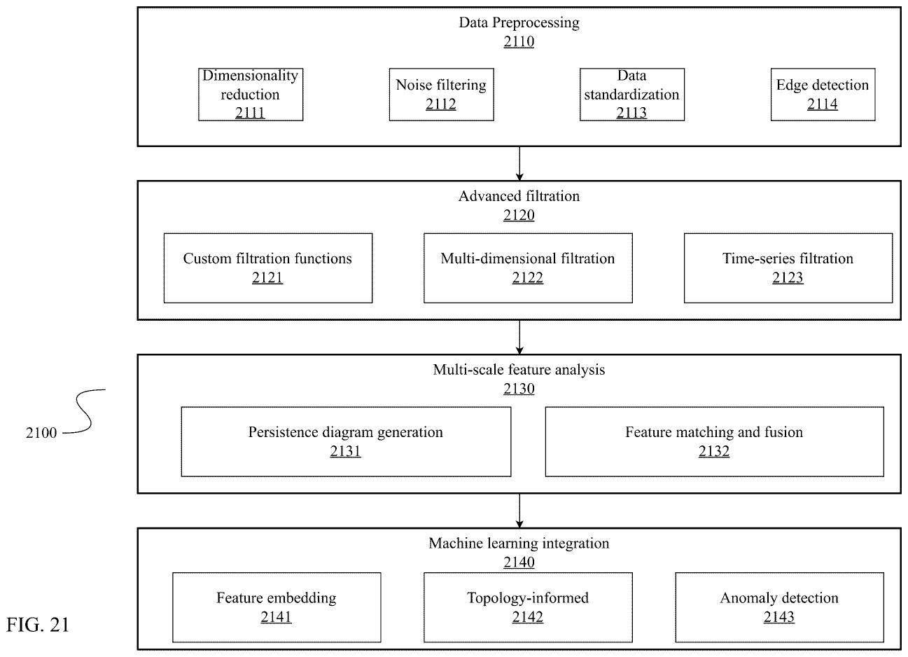

FIG. 21 is a block diagram illustrating exemplary architecture of a persistent homology optimization system for semiconductor manufacturing, implementing a multi-layered approach to topology-aware feature extraction and analysis 2100, in an embodiment. The system enables sophisticated process monitoring and control through the integration of advanced data preprocessing, filtration techniques, multi-scale analysis, and machine learning capabilities.

The Data Preprocessing 2110 Layer forms the foundation of the system, implementing multiple sophisticated data preparation techniques. Dimensionality reduction 2111 methods, such as Principal Component Analysis (PCA) or t-SNE, focus on extracting the most relevant aspects of high-dimensional sensor data. Noise filtering 2112 employs wavelet transforms and Gaussian smoothing to enhance signal quality across thermal, positional, and optical sensor inputs. Data standardization 2113 ensures consistent scaling across different sensor modalities, while edge detection 2114 algorithms process optical images to enhance feature clarity for topological analysis.

The Advanced Filtration Layer 2120 implements sophisticated techniques for calculating topological features across multiple scales. Custom filtration functions 2121 are designed specifically for semiconductor processes, incorporating temperature gradients, alignment error metrics, and defect density maps. Multi-dimensional filtration 2122 enables simultaneous analysis of multiple parameters, such as temperature and pressure correlations, while time-series filtration 2123 captures dynamic changes in the process across consecutive time steps. These filtration techniques enable the system to identify persistent features such as connected components, holes, and voids that characterize the manufacturing process state.

The Multi-Scale Feature Analysis Layer 2130 processes the filtered data to generate and analyze topological features across different scales. The persistence diagram generation 2131 identifies and tracks topological features, including connected components, holes, and voids, across multiple scales of analysis. Feature matching and fusion 2132 capabilities enable the system to integrate information from local, regional, and global scales, creating comprehensive representations of process conditions. This multi-scale approach allows for the detection of both fine-grained anomalies and large-scale process deviations.

The Machine Learning Integration Layer 2140 enhances the system's analytical capabilities through advanced computational techniques. Neural network-based feature embedding 2141 converts topological data into optimized feature spaces for predictive tasks such as yield prediction and defect localization. Topology-informed 2142 clustering leverages topological features to identify regions with similar process characteristics or failure modes. Anomaly detection 2143 employs supervised and unsupervised learning models to identify deviations from normal process behavior and predict potential failures.

The system implements specialized use cases for semiconductor manufacturing, including defect localization through the identification of stable regions of high defect density, thermal compensation through analysis of topological features in thermal gradients, and process drift monitoring through the tracking of persistent topological features across multiple batches. These applications enable targeted process adjustments, dynamic cooling control during lithography, and preemptive equipment recalibration.

Each layer of the system communicates through standardized interfaces, indicated by directional arrows in the diagram, enabling seamless data flow and integration of analysis results. The system maintains computational efficiency through parallelization, approximation techniques, and sparse representations, ensuring scalability for high-volume manufacturing environments. Continuous validation against real-world manufacturing data enables iterative refinement of the system's analytical capabilities and ensures reliable correlation between topological insights and physical process phenomena.

The quality of topology-aware features depends on the preprocessing of raw data. Steps to improve preprocessing include Dimensionality Reduction by applying techniques like Principal Component Analysis (PCA) or t-SNE to focus on the most relevant aspects of high-dimensional sensor data before persistent homology calculations; Noise Filtering by using denoising methods such as wavelet transforms or Gaussian smoothing to reduce noise in thermal, positional, or optical sensor data; and Standardization and Scaling by normalizing data across sensor modalities to ensure consistent input for topological analysis. For example, preprocessing optical images of wafer surfaces with edge-detection algorithms can enhance feature clarity, allowing persistent homology to better capture critical dimension deviations.

Persistent homology calculates topological features (e.g., connected components, holes, voids) across multiple scales using filtration functions. Improvements in filtration techniques can enhance feature extraction through Customized Filtration Functions by designing domain-specific filtrations, such as temperature gradients, alignment error metrics, or defect density maps, to emphasize relevant features in semiconductor processes; Multi-Dimensional Filtrations by applying multi-parameter persistence, which considers multiple filtrations simultaneously (e.g., temperature vs. pressure) to uncover complex relationships; and Time-Series Filtration by including temporal dimensions by applying filtrations across consecutive time steps to capture dynamic changes in the process. For example, use filtration functions based on defect density gradients to identify persistent hotspots across wafer regions and optimize thermal compensation strategies.

Persistent homology is inherently multi-scale, but further refinement can enhance its utility through Feature Matching Across Scales by matching topological features (e.g., connected components or voids) across scales to identify stable patterns that persist over time or process variations, and Hierarchical Feature Fusion by combining features at local, regional, and global scales to create a comprehensive representation of process conditions. For example, analyze wafer alignment at multiple resolutions (nanometer to micrometer scales) to detect both fine-grained and large-scale deviations, improving overlay correction.

Raw topological data (e.g., persistence diagrams or barcodes) can be difficult to interpret directly. Transform these outputs into actionable insights through Vectorization by converting persistence diagrams into feature vectors using methods like persistence landscapes, Betti curves, or template matching, enabling integration with machine learning algorithms; Feature Weighting by assigning importance scores to topological features based on their persistence, scale, or correlation with process outcomes; and Domain-Specific Mappings by mapping topological features to physical properties (e.g., hotspots to thermal gradients or voids to alignment errors) for better interpretability. For example, use persistence landscapes to quantify how thermal hotspots persist across multiple time steps and correlate this with wafer defect rates.

Machine learning can enhance persistent homology by automating feature extraction, pattern recognition, and anomaly detection through Deep Learning for Feature Embedding by training neural networks to embed persistence diagrams into feature spaces optimized for predictive tasks (e.g., yield prediction, defect localization); Topology-Informed Clustering by using topological features to guide clustering algorithms, identifying regions on wafers with similar process characteristics or failure modes; and Anomaly Detection by training supervised or unsupervised models (e.g., autoencoders) on topological data to detect deviations from normal process behavior. For example, a neural network processes persistence diagrams from thermal sensor data to classify wafer regions into high- and low-risk zones for overlay errors.

Tailor persistent homology to semiconductor manufacturing by incorporating domain knowledge through Process Constraints by integrating manufacturing constraints (e.g., acceptable temperature ranges, alignment tolerances) into filtration functions to prioritize relevant features, and Physics-Based Models by combining persistent homology with physics-informed models, such as thermal expansion equations or material deformation simulations, to refine feature generation. For example, use a hybrid approach where persistent homology identifies regions of interest, and physics-based models simulate the impact of process conditions on those regions.

Persistent homology calculations can be computationally expensive for large-scale data. Optimize computational pipelines to ensure scalability through Parallelization by implementing parallelized algorithms for filtration and feature computation, leveraging GPUs or distributed computing platforms; Approximation Techniques by using fast approximations of persistence diagrams for real-time applications, such as during high-volume wafer processing; and Sparse Representations by focusing computations on regions with significant changes or anomalies, reducing unnecessary processing. For example, apply a sparse persistence algorithm to analyze only regions of the wafer with known defect density variations, reducing processing time without sacrificing accuracy.

To ensure relevance and reliability, validate topology-aware features in real-world manufacturing scenarios through Benchmarking by comparing the effectiveness of persistent homology-based features against traditional metrics, such as mean squared error in alignment predictions or defect rate improvements; Continuous Feedback by using process outcomes to iteratively refine filtration functions and feature extraction methods; and Explainability by collaborating with domain experts to interpret topological results and correlate them with known physical phenomena. For example, validate topological insights by comparing predicted hotspots with defect locations identified through post-process inspection.

Advanced Use Cases of Persistent Homology in Semiconductor Manufacturing include Defect Localization where persistent homology identifies stable regions of high defect density, guiding targeted adjustments to exposure dose or cooling strategies; Thermal Compensation where analysis of topological features of thermal gradients across wafers enables dynamic adjustment of cooling mechanisms during lithography; and Process Drift Monitoring where detection of long-term process drifts by tracking persistent topological features across batches enables preemptive recalibration of equipment.

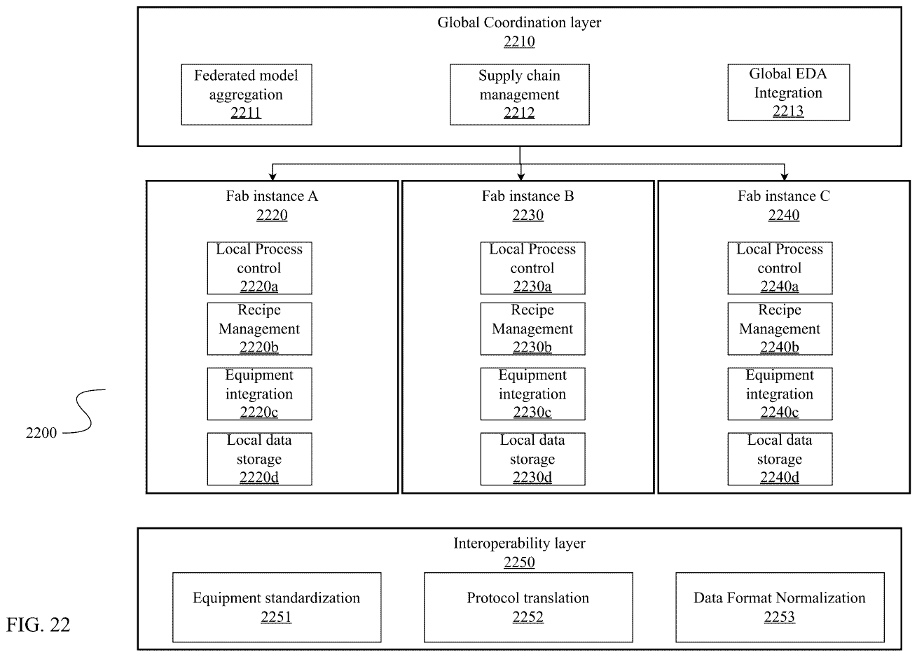

FIG. 22 is a block diagram illustrating exemplary architecture of a multi-fab federated coordination system for semiconductor manufacturing, implementing a distributed architecture that enables secure collaboration and process optimization across multiple fabrication facilities while maintaining local data sovereignty and operational independence 2200, in an embodiment. The system facilitates coordinated production optimization, accelerated process adoption, and reduced time-to-market through sophisticated data sharing and standardization mechanisms.

The Global Coordination Layer 2210 forms the highest level of the system, implementing three primary coordination mechanisms. Federated Model Aggregation 2211 manages the secure exchange of model parameters and training updates between facilities, utilizing encryption to protect proprietary information while enabling collective learning. The Supply Chain Management 2212 coordinates resource allocation and material availability across the network, enabling dynamic adaptation to supply constraints. The Global EDA Integration 2213 facilitates the sharing of design constraints and requirements across facilities, ensuring consistent implementation of complex manufacturing processes.

Multiple Fab Instances 2220, 2230, 2240 operate independently within the system, each maintaining its own secure environment and operational control. Each fab instance incorporates a Local Process Control system 2220a, 2230a, 2240a with AI-driven optimization capabilities, a Recipe Management system 2220b, 2230b, 2240b for validating and implementing process recipes, an Equipment Integration 2220c, 2230c, 2240c for managing vendor-specific tools, and a Local Data Storage 2220d, 2230d, 2240d system that securely maintains sensitive production data. This architecture ensures that each facility maintains control over its proprietary information while participating in the broader federation.

The Interoperability Layer 2250 serves as the foundation for cross-facility coordination, implementing sophisticated protocol translation and data normalization capabilities. The Equipment Standardization 2251 enables consistent operation across different vendor tools, while Protocol Translation 2252 facilitates communication between diverse systems and equipment types. Data Format Normalization 2253 ensures that information shared between facilities maintains consistency and usability across different platforms and processes.

The system implements secure data flows, indicated by directional arrows, that enable coordinated operation while preserving data privacy. Local training updates and model parameters are encrypted before being shared with the global coordination layer, which aggregates and redistributes optimized parameters to participating facilities. This approach enables facilities to benefit from collective learning experiences without exposing sensitive process data.

Real-time coordination mechanisms enable immediate sharing of process improvements and recipe optimizations. When one facility discovers an effective process modification, such as an improved doping schedule or thermal compensation strategy, the relevant parameters can be securely shared with other facilities using compatible equipment. The system's validation mechanisms ensure that shared process improvements align with local capabilities and constraints before implementation.

The federated architecture extends to design software and process management, enabling distributed EDA workflows across facilities. Design teams can share partial netlists, library data, and device constraints in a secure, modular format, while the AI-driven process management system adapts local manufacturing steps based on real-time design updates. This integration ensures synchronization between design and manufacturing processes across the network.

This coordinated approach enables semiconductor manufacturers to leverage collective expertise and resources while maintaining operational security and independence. The system's architecture supports rapid adoption of process improvements, efficient resource allocation, and coordinated response to supply chain challenges, ultimately improving manufacturing efficiency and product quality across the entire network.

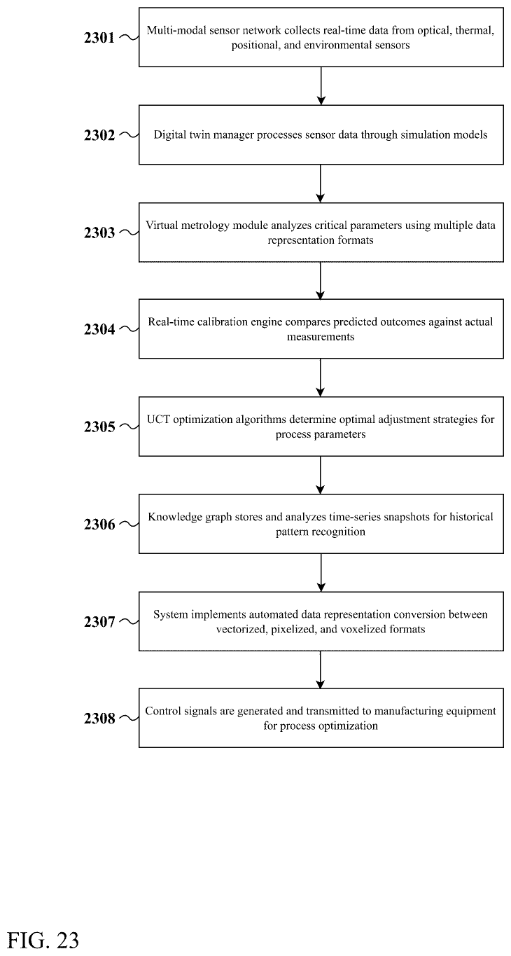

FIG. 23 is a method diagram illustrating the operational sequence of a digital twin and virtual metrology framework for semiconductor manufacturing control. This method demonstrates the step-by-step process of real-time monitoring, analysis, and control optimization.

The multi-modal sensor network collects real-time data from various sensor types deployed throughout the manufacturing process 2301. Optical sensors perform surface inspections and detect pattern variations, thermal sensors monitor temperature distributions, positional sensors track equipment movements, and environmental sensors monitor cleanroom conditions including temperature, humidity, and particle counts. The Digital Twin Manager processes the collected sensor data through sophisticated simulation models designed to predict wafer behavior under current processing conditions 2302. These models incorporate finite-element analysis and fluid-structure interaction calculations to account for complex physical phenomena including thermal diffusion, mechanical stress distribution, and chemical reaction kinetics.

The Virtual Metrology module analyzes critical parameters using multiple complementary data representation formats 2303. This includes vectorized feature sets for rapid analysis, pixelized maps for surface characteristics, and voxelized models for three-dimensional structures, enabling comprehensive evaluation of manufacturing quality metrics. The real-time calibration engine performs continuous comparison of predicted outcomes against actual measurements from the physical manufacturing process 2304. This comparison enables immediate detection of deviations and provides the foundation for process adjustment decisions.

UCT optimization algorithms process the comparison data to determine optimal adjustment strategies for various process parameters 2305. These algorithms consider multiple factors including overlay corrections, thermal compensation parameters, and exposure dose settings to maintain optimal manufacturing conditions. The Knowledge Graph component stores and analyzes time-series snapshots of wafer states, processing conditions, and outcome measurements 2306. This historical data storage enables both immediate process optimization and long-term trend analysis, while maintaining complex relationships between process parameters and quality outcomes.

The system implements automated conversion mechanisms between different data representation formats 2307, ensuring seamless translation between vectorized, pixelized, and voxelized representations while maintaining synchronization and measurement fidelity across all analysis contexts. Finally, optimized control signals are generated and transmitted to the manufacturing equipment 2308, implementing the determined process adjustments to maintain optimal production parameters and ensure high-quality manufacturing outcomes. This closed-loop control system enables continuous optimization of the manufacturing process based on real-time data analysis and historical performance patterns.

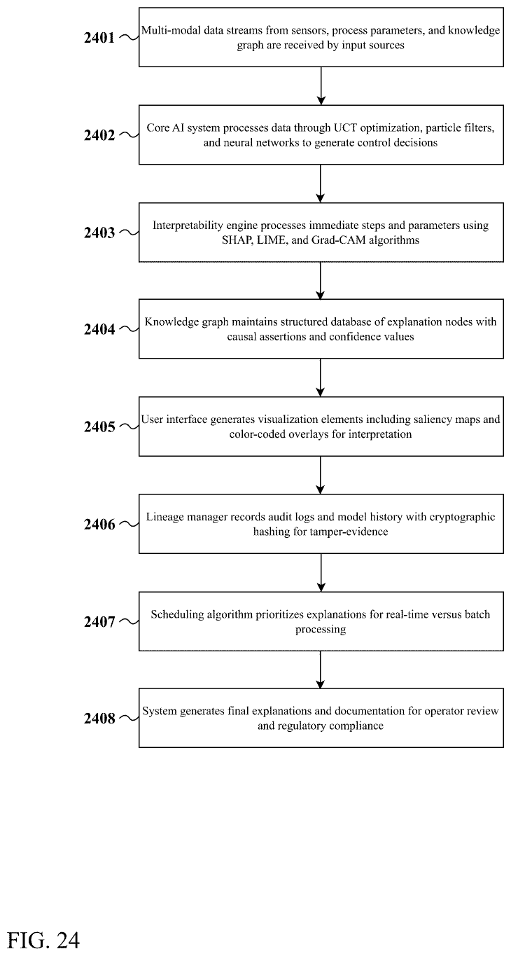

FIG. 24 is a method diagram illustrating the operational sequence of an explainable artificial intelligence (XAI) subsystem for semiconductor manufacturing control. This method demonstrates the step-by-step process of generating interpretable explanations for AI-driven manufacturing decisions while maintaining system performance and regulatory compliance.

Multiple data streams from sensors, process parameters, and knowledge graph are received by the input sources 2401. This multi-modal data includes real-time sensor measurements from fabrication equipment, manufacturing specifications, and historical process information, establishing the foundation for both control decisions and their explanations. The core AI system processes the input data through multiple artificial intelligence algorithms 2402. The UCT optimization engine handles complex decision spaces, particle filters manage uncertainty in sensor data, and neural networks identify patterns in process variations, collectively generating optimized control decisions for the manufacturing process.

The Interpretability Engine processes intermediate states and parameters using multiple explanation algorithms 2403. These include SHAP for feature attribution, LIME for local interpretation, Grad-CAM for neural network visualization, and saliency mapping for highlighting critical regions. The engine executes these algorithms in response to operator requests, audit triggers, or anomaly alerts. The Knowledge Graph maintains a structured database of explanation nodes 2404. These nodes contain causal assertions documenting cause-effect relationships, model version information tracking AI system iterations, confidence values quantifying decision reliability, and explanatory links connecting process parameters to outcomes. This structure enables traceability from parameter changes to underlying causes.

The User Interface generates comprehensive visualization elements 2405. This includes saliency maps, color-coded wafer overlays, explanatory text, and confidence metrics. The interface employs color coding to denote critical regions, with red or orange indicating potential defects and green signifying stable zones, enabling rapid interpretation by operators. The lineage manager implements comprehensive audit and tracking functionality 2406. It ensures tamper-evident storage through cryptographic hashing and secure timestamps for each explanation record, maintaining a verifiable history of model updates and decision patterns for regulatory compliance.

A sophisticated scheduling algorithm manages the generation of explanations 2407, determining which require near real-time processing versus deferred batch processing. This prioritization ensures operators receive critical information without delay while managing system resources efficiently. Finally, the system generates complete explanations and documentation 2408 for operator review and regulatory compliance. This output includes detailed justifications for AI-driven decisions, enabling manufacturing professionals to understand, validate, and refine control signals while maintaining accountability and compliance requirements.

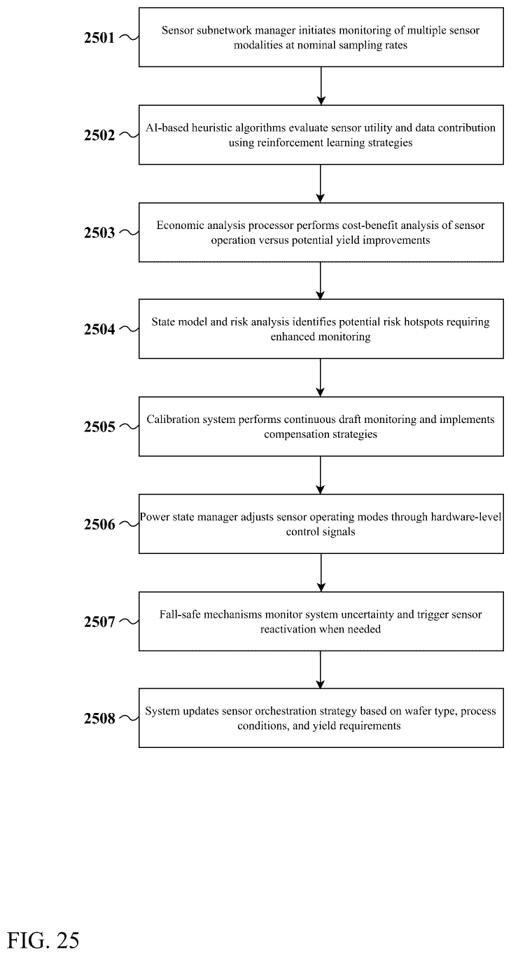

FIG. 25 is a method diagram illustrating the operational sequence of an energy-aware sensor orchestration system for adaptive power management and contextual activation in semiconductor manufacturing. This method demonstrates the step-by-step process of dynamically managing sensor usage while maintaining manufacturing quality and efficiency.

The sensor subnetwork manager initiates monitoring of multiple sensor modalities at nominal sampling rates 2501. This includes thermal, optical, positional, and chemical sensors, each operating as distinct nodes in the sensor network to establish baseline measurements for wafer processing parameters. AI-based heuristic algorithms evaluate sensor utility and data contribution using reinforcement learning strategies 2502. These algorithms, including Q-learning and policy-gradient methods, treat each sensor as an “arm” in a multi-armed bandit approach, calculating time-varying rewards based on each sensor's contribution to process parameter certainty and yield prediction accuracy.

The economic analysis processor performs continuous cost-benefit analysis of sensor operation 2503. This analysis considers sensor energy costs, maintenance overhead, and wafer value, assigning cost coefficients to sensors based on their calibration requirements and power consumption patterns. The system evaluates the economic justification for sensor activation based on potential yield improvements. The state model and risk analysis component identifies potential risk hotspots requiring enhanced monitoring 2504. This analysis enables “just-in-place” activation and “just-in-time” sampling strategies, particularly when the system detects increased probabilities of overlay misalignment, thermal runaway, or doping inconsistencies in specific regions.

The calibration system performs continuous drift monitoring and implements compensation strategies 2505. It compares real-time sensor data against reference baselines and cross-checks overlapping sensors, initiating automated recalibration procedures or transitioning affected sensors to lower activity states when significant deviations are detected. The power state manager adjusts sensor operating modes through hardware-level control signals 2506. These adjustments include transitions between fully powered operation, idle mode, and partial sleep states, with precise control over sampling rates and analog-to-digital converter configurations implemented through various communication protocols.

Fail-safe mechanisms monitor system uncertainty and trigger sensor reactivation when needed 2507. These mechanisms prevent excessive degradation of measurement accuracy and maintain robust fault management capabilities, especially during critical processing steps or when dealing with high-value wafers. The system continuously updates its sensor orchestration strategy based on wafer type, process conditions, and yield requirements 2508. This adaptive approach enables optimal balancing of power consumption, data fidelity, and manufacturing quality, ensuring efficient operation while maintaining necessary monitoring coverage for different product types and processing conditions.

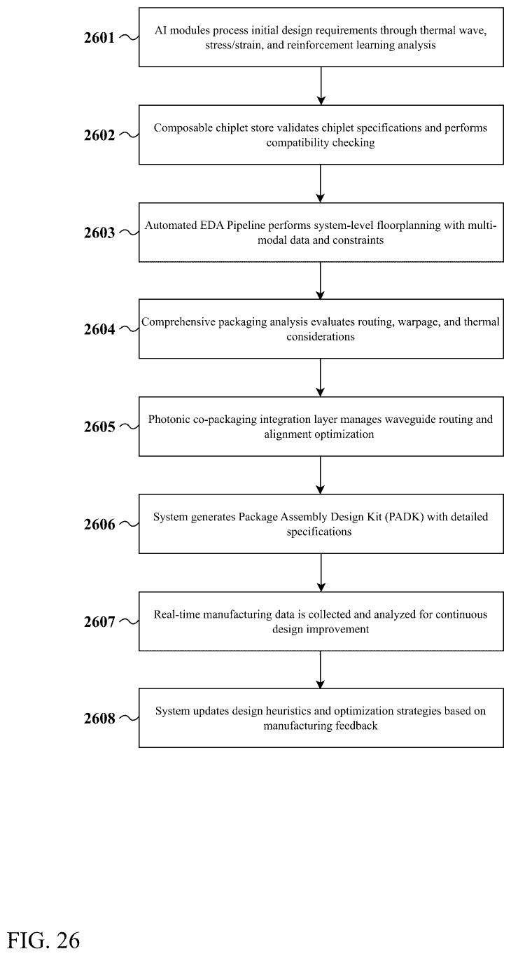

FIG. 26 is a method diagram illustrating the operational sequence of an AI-driven composable chiplet store and automated EDA pipeline system for semiconductor packaging applications. This method demonstrates the step-by-step process of integrating modular chiplet designs while ensuring compatibility and optimal performance.

The specialized AI modules process initial design requirements through multiple analytical approaches 2601. These include thermal wave modeling for heat behavior analysis, stress/strain evaluation for mechanical considerations, and reinforcement learning for continuous design optimization. The modules work in concert to evaluate how new chiplets will perform in 2.5D or 3D package environments. The composable chiplet store validates specifications and performs comprehensive compatibility checking 2602. This includes verification of interface specifications (UCIe or AIB), assessment of thermal and power profiles, evaluation of optical waveguide alignment requirements, and analysis of mechanical specifications such as bump pitch and warpage tolerances.

The automated EDA pipeline executes system-level floorplanning using multi-modal data and reinforcement learning 2603. This process arranges chiplets on interposers or in 3D stacks while adhering to various constraints including height limitations, waveguide alignment requirements for photonics, and thermal considerations for high-performance computing applications. Comprehensive packaging analysis evaluates multiple aspects of the design 2604. This includes automated 2.5D or 3D route planning, detailed warpage and stress evaluations, thermal wave simulation for temperature gradient analysis, and real-time design rule checks to ensure mechanical reliability.

The photonic co-packaging integration layer manages specialized optical I/O requirements 2605. This includes waveguide routing in the interposer, monitoring of alignment sensitivity and thermal drift, and exploration of alternative floorplans to maintain stable optical coupling across thermal cycles. The system generates a comprehensive Package Assembly Design Kit (PADK) 2606 that includes detailed bills of materials, precise component positioning specifications, and comprehensive coupling strategies for assembly and integration.

Real-time manufacturing data is collected and analyzed 2607 to provide feedback on actual performance and manufacturing outcomes. This data collection enables continuous validation and refinement of design decisions and optimization strategies. The system updates its design heuristics and optimization strategies 2608 based on manufacturing feedback, enabling continuous improvement of the design process. This feedback loop allows the system to refine its approach for future iterations, improving reliability and performance while maintaining flexibility for advancing packaging technologies.

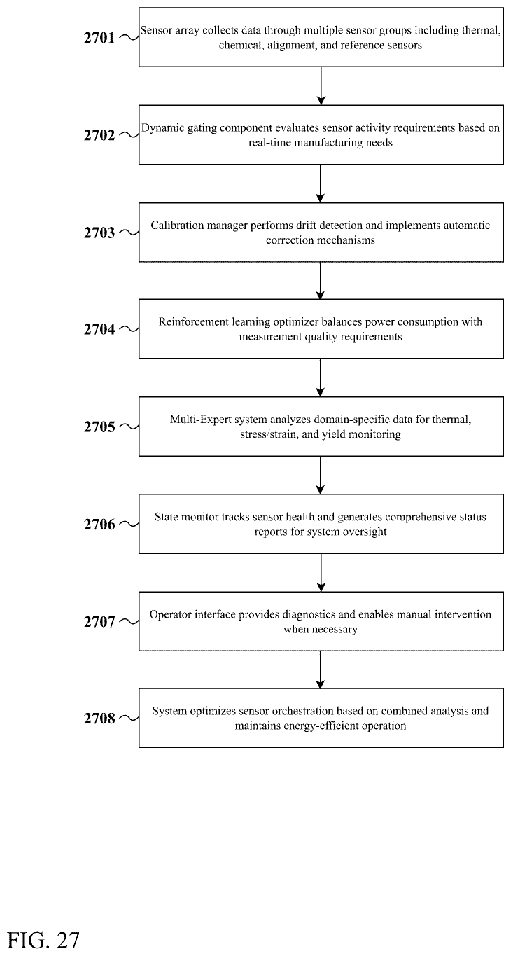

FIG. 27 is a method diagram illustrating the operational sequence of an intelligent sensor orchestration subsystem for semiconductor manufacturing control. This method demonstrates the step-by-step process of managing sensor arrays while optimizing power consumption and maintaining measurement accuracy.

The sensor array collects data through multiple functionally categorized sensor groups 2701. These include thermal sensors, chemical sensors, alignment sensors, and reference sensors, each operating with multiple power states for granular power management. The reference sensors provide calibration standards for system-wide accuracy verification. The dynamic gating component evaluates sensor activity requirements based on real-time manufacturing needs 2702. This manages both individual sensor control and cluster management, determining optimal sensor activation patterns to meet current process requirements while minimizing power consumption.

The calibration manager performs continuous drift detection and implements automatic correction mechanisms 2703. Through cross-correlation and particle filter-style state estimation, this component monitors sensor accuracy and initiates appropriate calibration responses when deviations are detected. The reinforcement learning optimizer balances power consumption with measurement quality requirements 2704. Using a custom reward function, this component discovers and implements optimal gating patterns that maintain necessary measurement fidelity while minimizing energy usage.

The multi-expert system analyzes domain-specific data across multiple process aspects 2705. This includes thermal modeling for heat distribution analysis, stress/strain analysis for mechanical deformation monitoring, yield monitoring for quality control, and process control for manufacturing optimization. The state monitor tracks sensor health and generates comprehensive status reports 2706. This component maintains oversight of the entire sensor network, ensuring proper functioning and providing early warning of potential issues or maintenance requirements.

The operator interface provides diagnostic capabilities and enables manual intervention when necessary 2707. Through this interface, human operators can observe system behavior, access real-time sensor health metrics, and implement manual overrides in response to special processing requirements. The system continuously optimizes sensor orchestration based on combined analysis from all components 2708. This optimization maintains energy-efficient operation while adapting to changing manufacturing conditions and preserving measurement accuracy through dynamic gating strategies, automated calibration mechanisms, and reinforcement learning optimization.

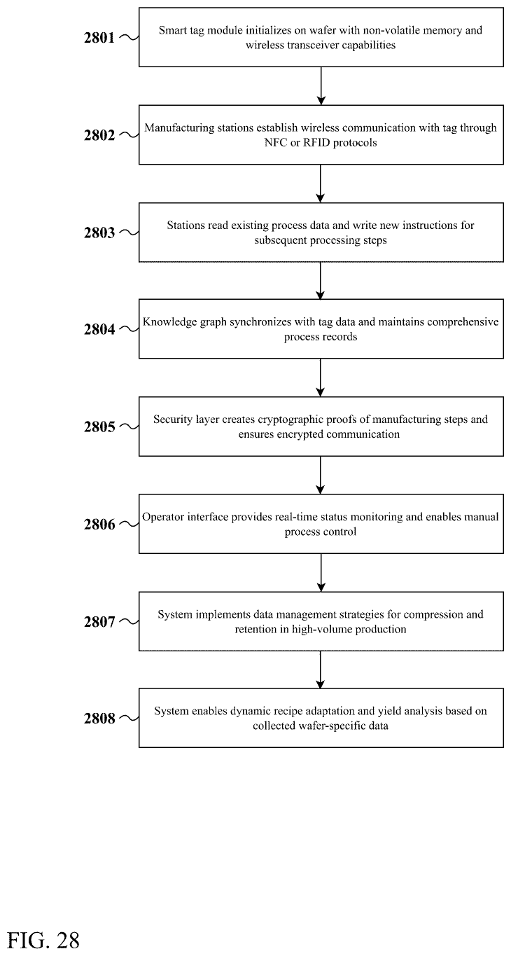

FIG. 28 is a method diagram illustrating the operational sequence of a wafer-level smart tag system for semiconductor manufacturing control. This method demonstrates the step-by-step process of implementing real-time identification, data capture, and lifecycle tracking throughout the manufacturing process. The smart tag module initializes on the wafer with non-volatile memory and wireless transceiver capabilities 2801. This ultra-thin, flexible module is positioned on or near the wafer surface and includes EEPROM or flash memory with sufficient capacity for storing essential parameters, sensor logs, and recipe instructions, along with optional embedded sensors for environmental monitoring. Manufacturing stations establish wireless communication with the tag through standardized protocols 2802. These stations employ NFC or RFID channels to create closed-loop communication mechanisms, enabling reliable data exchange between the wafer tag and processing equipment.

The stations read existing process data and write new instructions for subsequent processing steps 2803. This bidirectional communication ensures that each station has access to the wafer's current state and can update processing parameters based on accumulated manufacturing history. The Knowledge Graph synchronizes with tag data and maintains comprehensive process records 2804. This central repository stores long-term relationships and hierarchical process flows for each wafer, implementing sophisticated synchronization routines to maintain data consistency even during periods of intermittent network connectivity.

The security layer creates cryptographic proofs of manufacturing steps and ensures encrypted communication 2805. Through blockchain or distributed ledger technology, this component establishes an immutable record of the wafer's manufacturing journey while protecting intellectual property through authenticated data exchanges. The operator interface provides real-time status monitoring and enables manual process control 2806. Through this interface, operators can access comprehensive dashboards, implement necessary overrides, and manage process flows based on current wafer status and manufacturing requirements.

The system implements sophisticated data management strategies for high-volume production environments 2807. This includes data compression, rolling logs, and intelligent retention policies to maintain efficient operation while preserving critical manufacturing information. The system enables dynamic recipe adaptation and yield analysis based on collected wafer-specific data 2808. This comprehensive approach ensures unbroken data chain throughout the manufacturing lifecycle while enabling continuous process improvement through accumulated manufacturing intelligence.

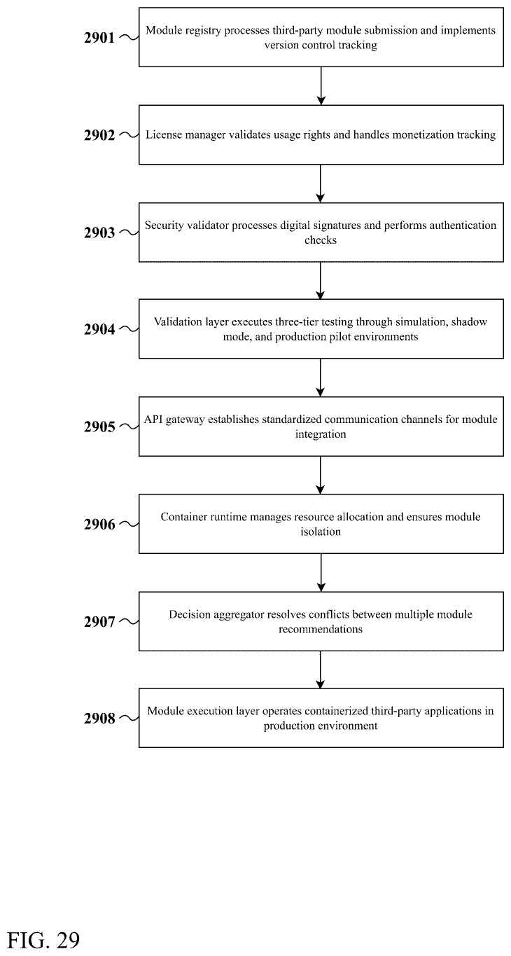

FIG. 29 is a method diagram illustrating the operational sequence of a modular app store architecture for integrating third-party process control extensions into semiconductor manufacturing platforms. This method demonstrates the step-by-step process of module validation, deployment, and execution while maintaining system security and reliability. The module registry processes third-party module submissions and implements version control tracking 2901. This component maintains comprehensive records of all submitted modules, their versions, and their development history, ensuring proper documentation and traceability throughout the module lifecycle. The license manager validates usage rights and handles monetization tracking 2902. This component manages module licensing, tracks usage metrics, and processes financial transactions, enabling a sustainable ecosystem for third-party development while ensuring proper compensation for module creators.

The Security Validator processes digital signatures and performs authentication checks 2903. Through rigorous security validation protocols, this component ensures that all modules meet security requirements and maintain the integrity of the manufacturing environment. The validation layer executes a comprehensive three-tier testing process 2904. Modules progress through simulation sandbox testing using historical data, shadow mode evaluation with real-time data streams, and limited production pilot deployment, ensuring thorough verification of module performance and reliability.

The API Gateway establishes standardized communication channels for module integration 2905. Supporting REST/gRPC endpoints and SEMI standards, this component enables consistent and reliable communication between modules and the platform while maintaining security protocols. The container runtime manages resource allocation and ensures module isolation 2906. This component handles the deployment and execution of containerized modules, maintaining proper resource utilization while preventing interference between different modules.

The decision aggregator resolves conflicts between multiple module recommendations 2907. When multiple modules provide competing suggestions, this component implements conflict resolution protocols and parameter optimization to ensure coherent system operation. The module execution layer operates containerized third-party applications in the production environment 2908. This foundation layer supports diverse applications ranging from overlay optimization to defect detection, while maintaining secure communication channels through standardized APIs and ensuring proper isolation of each module.

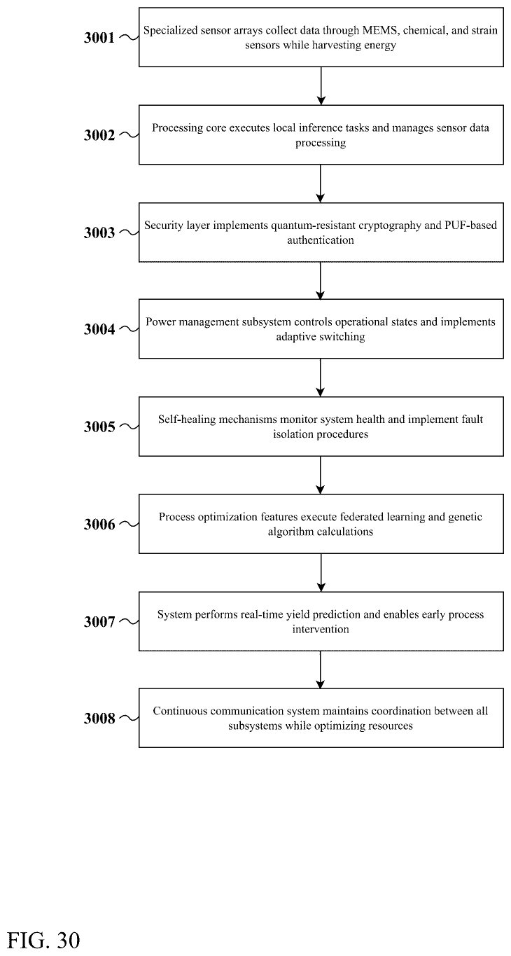

FIG. 30 is a method diagram illustrating the operational sequence of an enhanced smart tag system for semiconductor wafer tracking and process optimization. This method demonstrates the step-by-step process of implementing comprehensive wafer monitoring and control through multiple integrated subsystems. Specialized sensor arrays collect data through multiple sensing modalities while simultaneously harvesting energy 3001. These arrays include MEMS-based vibration and acceleration sensors for mechanical monitoring, chemical residue sensors using functionalized micro cantilevers, and distributed strain gauges for deformation measurement. Energy harvesting components capture power from RF emissions, thermal gradients, and mechanical vibrations. The processing core executes local inference tasks and manages sensor data processing 3002. Using a microcontroller or low-power FPGA, this component performs edge computing operations and neural network implementations, supporting multiple operational states from full active mode to low-power sleep states as required by processing conditions.

The security layer implements quantum-resistant cryptography and PUF-based authentication 3003. This includes physically unclonable function modules for unique wafer identification, secure enclaves for data protection, and advanced encryption mechanisms designed to resist both classical and quantum computing attacks. The power management subsystem controls operational states and implements adaptive switching 3004. Through sophisticated algorithms, the system dynamically adjusts power consumption based on process requirements, environmental conditions, and available energy harvesting opportunities, ensuring sustained operation during critical processing steps.

Self-healing mechanisms monitor system health and implement fault isolation procedures 3005. Through redundant memory banks with error-correction coding, fault isolation mechanisms, and adaptive reconfiguration capabilities, the system maintains operational integrity even when components are damaged or degraded. Process optimization features execute federated learning and genetic algorithm calculations 3006. The system participates in distributed learning schemes while maintaining data privacy, and employs genetic algorithms to optimize process parameters based on historical performance data. The system performs real-time yield prediction and enables early process intervention 3007. Through continuous analysis of sensor data and process parameters, the system can predict potential yield issues and initiate corrective actions before significant problems develop.

Continuous communication systems maintain coordination between all subsystems while optimizing resources 3008. This integrated approach ensures rapid response to anomalies while managing power consumption and processing resources efficiently, enabling comprehensive process optimization throughout the wafer manufacturing lifecycle.

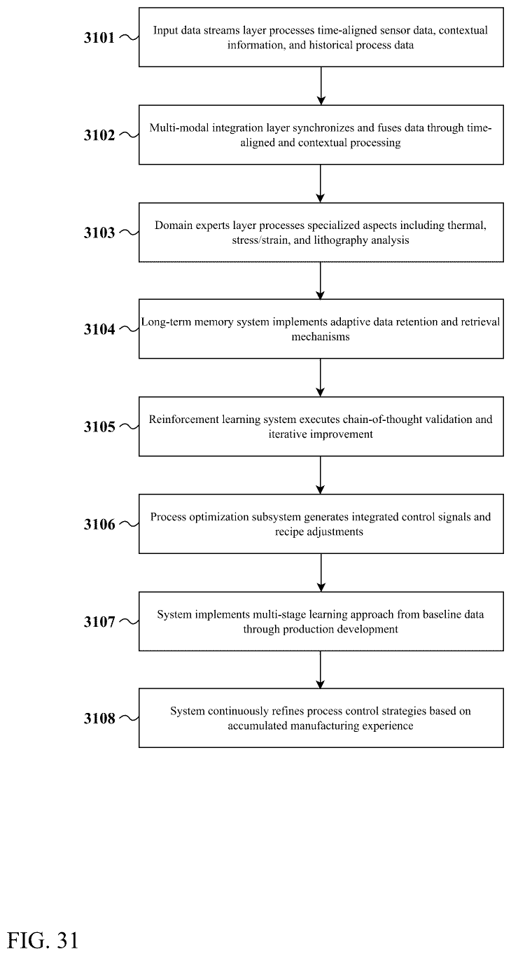

FIG. 31 is a method diagram illustrating the operational sequence of a temporal dynamics and multi-model integration system for semiconductor process control. This method demonstrates the step-by-step process of integrating multiple data streams and expert systems to enable sophisticated process control and optimization. The input data streams layer processes multiple types of information simultaneously 3101. This includes time-aligned sensor data comprising high-frequency measurements, contextual data including recipe specifications and engineering documentation, and historical process data from previous manufacturing runs, providing comprehensive coverage of the manufacturing process. The multi-modal integration layer synchronizes and fuses data through specialized processing components 3102. The time-aligned combiner processes high-frequency sensor data streams through chunk-based processing, while the contextual processor handles recipe information and log analysis, creating unified representations for downstream processing.

The domain experts layer processes specialized aspects of semiconductor manufacturing 3103. This includes thermal wave analysis for heat distribution, stress/strain evaluation for mechanical deformations, lithography expertise for precision patterning, and yield monitoring for manufacturing outcomes prediction, with each expert module maintaining specialized algorithms while sharing information through standardized interfaces. The long-term memory system implements adaptive data retention and retrieval mechanisms 3104. This system maintains historical knowledge of process parameters, anomalies, and outcomes, enabling the system to learn from past experiences and apply accumulated knowledge to current manufacturing operations.

The Reinforcement learning system executes chain-of-thought validation and iterative improvement 3105. Through sophisticated reward mechanisms based on manufacturing yields, quality metrics, and efficiency parameters, this component enables continuous optimization of process controls. The Process Optimization Subsystem generates integrated control signals and recipe adjustments 3106. This component combines recommendations from domain experts, historical insights from the memory system, and learned optimizations to produce coherent control decisions for manufacturing processes.

The system implements a multi-stage learning approach from baseline data through production deployment 3107. Beginning with standard domain expertise, the system progresses through reinforcement learning fine-tuning and ultimately distills knowledge into optimized models for edge computing applications. The system continuously refines process control strategies based on accumulated manufacturing experience 3108. Through this ongoing refinement process, the system maintains flexibility to accommodate new manufacturing technologies while ensuring continuous improvement in efficiency and yield through adaptive learning mechanisms.

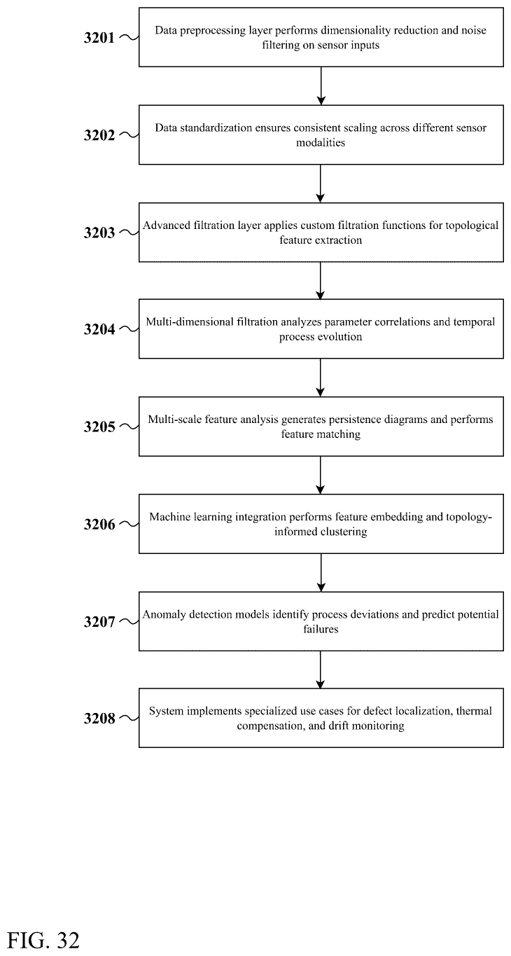

FIG. 32 is a method diagram illustrating the operational sequence of a persistent homology optimization system for semiconductor manufacturing control. This method demonstrates the step-by-step process of implementing topology-aware feature extraction and analysis for process monitoring and control. The data preprocessing layer performs dimensionality reduction and noise filtering on sensor inputs 3201. Using techniques such as Principal Component Analysis (PCA) or t-SNE, the system extracts relevant aspects of high-dimensional sensor data while employing wavelet transforms and Gaussian smoothing to enhance signal quality across various sensor types. Data standardization ensures consistent scaling across different sensor modalities 3202. This standardization process creates uniform data representations while edge detection algorithms process optical images to enhance feature clarity for subsequent topological analysis.

The Advanced Filtration Layer applies custom filtration functions designed specifically for semiconductor processes 3203. These functions incorporate temperature gradients, alignment error metrics, and defect density maps to identify and characterize topological features relevant to the manufacturing process. Multi-dimensional filtration analyzes parameter correlations and temporal process evolution 3204. This enables simultaneous analysis of multiple parameters such as temperature and pressure correlations, while capturing dynamic changes in the process across consecutive time steps.

Multi-Scale Feature Analysis generates persistence diagrams and performs feature matching 3205. The system identifies and tracks topological features including connected components, holes, and voids across multiple scales, integrating information from local, regional, and global perspectives. Machine learning integration performs feature embedding and topology-informed clustering 3206. Neural network-based approaches convert topological data into optimized feature spaces for predictive tasks, while clustering algorithms leverage topological features to identify regions with similar process characteristics. Anomaly detection models identify process deviations and predict potential failures 3207. Using supervised and unsupervised learning approaches, the system detects deviations from normal process behavior and anticipates possible manufacturing issues.

The system implements specialized use cases for semiconductor manufacturing applications 3208. These include defect localization through identification of stable high-defect-density regions, thermal compensation through analysis of topological features in thermal gradients, and process drift monitoring through tracking of persistent topological features across multiple batches.

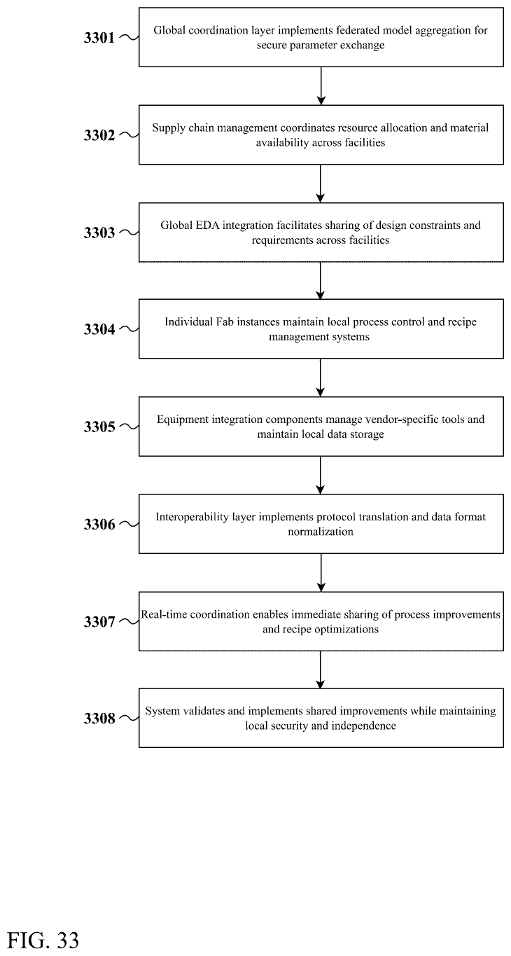

FIG. 33 is a method diagram illustrating the operational sequence of a multi-fab federated coordination system for semiconductor manufacturing. This method demonstrates the step-by-step process of implementing secure collaboration and process optimization across multiple fabrication facilities while maintaining local operational independence.

The global coordination layer implements federated model aggregation for secure parameter exchange 3301. This component manages the encrypted exchange of model parameters and training updates between facilities, enabling collective learning while protecting proprietary information through sophisticated encryption mechanisms. Supply chain management coordinates resource allocation and material availability across facilities 3302. This coordination enables dynamic adaptation to supply constraints and ensures efficient distribution of resources throughout the manufacturing network while maintaining optimal production schedules.

Global EDA Integration facilitates sharing of design constraints and requirements across facilities 3303. This integration ensures consistent implementation of complex manufacturing processes and enables standardized approaches to design and production challenges across multiple facilities. Individual fab instances maintain local process control and recipe management systems 3304. Each facility operates its own AI-driven optimization capabilities and recipe validation processes, ensuring autonomous control over manufacturing operations while participating in the broader federation. Equipment integration components manage vendor-specific tools and maintain local data storage 3305. These components handle the integration of diverse manufacturing equipment while ensuring secure storage of sensitive production data within each facility's controlled environment.

The interoperability layer implements protocol translation and data format normalization 3306. This foundation enables consistent operation across different vendor tools and facilitates communication between diverse systems and equipment types while maintaining data consistency across platforms. Real-time coordination enables immediate sharing of process improvements and recipe optimizations 3307. When facilities discover effective process modifications, such as improved doping schedules or thermal compensation strategies, these improvements can be securely shared with other facilities using compatible equipment.

The system validates and implements shared improvements while maintaining local security and independence 3308. Through sophisticated validation mechanisms, the system ensures that shared process improvements align with local capabilities and constraints before implementation, preserving operational security while enabling collective advancement.

In an additional embodiment, an advanced interconnect process control subsystem is integrated into the adaptive semiconductor process control platform to address the challenges emerging at the 10 Å node and below. As traditional copper interconnects reach their physical limits—exacerbating RC delay and power consumption—the subsystem dynamically manages the transition to alternative metals such as ruthenium and molybdenum. Ultra-high resolution sensors, including in situ metrology for film thickness, grain structure, and line width, capture real-time data on interconnect morphology and electrical properties. This sensor data is fed into a dedicated digital twin module that employs first-principles simulation techniques to model key phenomena such as grain boundary scattering and electron mean free path variations at nanoscale dimensions.

The digital twin leverages these simulations to predict electrical performance and thermal behavior of interconnects formed via both traditional damascene and subtractive etch processes. Process parameters—such as deposition rates, etch selectivity, and gap-fill strategies—are continuously adjusted based on these predictions to optimize the formation of barrier-less interconnects. A specialized Upper Confidence Tree (UCT) algorithm, enhanced with interconnect-specific economic and process parameters, evaluates trade-offs between process throughput, RC delay reduction, and yield stability. Reinforcement learning techniques further refine these adjustments by correlating early sensor deviations with long-term electrical performance outcomes.

For scalability and seamless integration, the interconnect subsystem is designed to operate hierarchically. Localized sensor data from individual interconnect regions is aggregated at the chip and wafer levels, allowing for both fine-grained and global process optimizations. This data aggregation supports adaptive retargeting of process flows—from copper-based deposition to ruthenium or molybdenum schemes—by dynamically switching between deposition techniques and etch recipes. Moreover, the subsystem interfaces with existing sensor orchestration and digital twin modules, ensuring that interconnect-specific adjustments are synchronized with overall fab process control and energy management strategies.

Complementary novel elements include an automated feedback loop that compares digital twin predictions with real-time metrology outputs, triggering immediate re-calibration cycles when discrepancies arise. This loop allows for on-the-fly adjustments in deposition and etch parameters to correct for variations that could adversely affect interconnect performance. Additionally, the subsystem incorporates an economic optimization layer that weighs factors such as yield impact and production costs, enabling dynamic prioritization of process adjustments. By holistically integrating technical and economic considerations, this embodiment provides a scalable, robust solution for achieving low-resistance, high-integrity interconnects in next-generation semiconductor devices.

In another embodiment, the control system is augmented with a dedicated quantum-enhanced simulation module designed to model nanoscale electron transport phenomena in alternative interconnect materials. This module employs quantum annealing techniques—potentially using hardware accelerators such as quantum annealers or quantum-inspired ASICs—to solve discretized models of electron movement through ultra-thin interconnect films. For instance, the module implements a quantum network model that maps grain boundary locations and electron scattering events to probabilistic distributions of electron mean free paths. Monte Carlo simulations, accelerated via GPU clusters or dedicated quantum processors, are then used to estimate the resistance variability and thermal behavior across ruthenium or molybdenum interconnects under varying process conditions. The outputs of these simulations, expressed as dynamic parameter distributions and risk metrics, are fed into an integrated digital twin module. This digital twin continuously updates deposition and etch process parameters—such as ALD cycle durations, etch selectivity ratios, and gap-fill recipes—in real time to achieve minimal RC delay and optimal yield. This feedback loop ensures that the physical process remains in tight alignment with the simulated optimal performance, bridging the gap between nanoscale physical phenomena and macro-scale process control.

Concurrently, an adaptive, AI-driven sensor fusion framework is integrated to continuously monitor multi-modal sensor data from in situ optical, thermal, and electron microscopy sensors. A deep autoencoder network is employed to compress high-dimensional sensor data into latent feature representations, which are then used for real-time anomaly detection. When the reconstruction error of the autoencoder exceeds a dynamically determined threshold—signaling sensor drift, misalignment, or other anomalies—a reinforcement learning (RL) agent is activated to initiate on-the-fly recalibration. This agent uses a Bayesian update mechanism to adjust sensor gains, recalibrate offset values, or modify sampling frequencies based on recent historical data and predicted process variations. Furthermore, the sensor fusion framework incorporates unsupervised clustering algorithms (e.g., Gaussian mixture models) to detect emerging patterns in the sensor streams that could indicate the onset of subtle process deviations. This layer of self-calibration ensures that the control system always receives high-fidelity data, which is critical for precise process parameter adjustments in ultra-scaled interconnect fabrication.

Complementing the above modules is a predictive defect detection system that leverages ensemble learning techniques for early identification of interconnect defects. This system combines outputs from convolutional neural networks (CNNs) trained on high-resolution in-line wafer imagery with gradient boosting models that process real-time sensor metrics. Multi-scale feature extraction is achieved through pyramid pooling networks, which capture both fine-grained defect signatures (such as void formation or line width variations) and broader morphological trends that affect the entire interconnect network. The ensemble model generates a risk score for each interconnect region based on both the simulated predictions from the quantum-enhanced module and the real-time sensor inputs. If the risk score exceeds a threshold—dynamically adjusted by an economic optimization layer that considers production throughput, yield impact, and energy consumption—the system automatically triggers targeted process adjustments. These adjustments might include modifying deposition thickness, altering etch parameters, or selectively reactivating additional sensor clusters for more granular data collection in affected areas.

Overall, this enhanced control system architecture fuses quantum-enhanced simulations, adaptive AI sensor fusion, and predictive defect analytics into a unified framework that dynamically optimizes interconnect fabrication. By aligning first-principles simulations with real-time process data and robust defect prediction algorithms, the system enables ultra-precise process control at the 10 Å node and beyond. The integration of these advanced modules not only mitigates the limitations of traditional copper interconnects but also provides a scalable, economically optimized pathway for transitioning to next-generation materials and process architectures in high-volume semiconductor manufacturing.

In one approach, a thin diamond film or micro-diamond substrate is embedded within the chip's package. During fabrication, metrology data—capturing critical process parameters, inspection results, and test metrics—is encoded in real time or post manufacturing from cached or persisted local data or cloud data onto the diamond substrate using a femtosecond laser system. The laser precisely induces controlled vacancy centers (GR1 centers) within the diamond lattice, with each storage unit's fluorescence intensity representing multi-bit information. These units are arranged in a high-density 3D array, achieving capacities on the order of terabits per cubic centimeter, as demonstrated in recent diamond data storage work. The diamond's inherent properties—exceptional thermal conductivity, chemical inertness, and resistance to radiation—ensure that the stored metrology trace is robust, long-lasting, and stable under the harsh conditions of semiconductor processing and operation. An integrated optical port or micro-optical interface within the package enables non-destructive, in-field readout of the stored trace, thus providing a tamper-proof record that is physically tied to the device.

Alternatively, a DNA-based storage embodiment can be utilized to achieve an ultra-high density, secure process trace. In this embodiment, a microfluidic compartment is integrated into the chip packaging to house synthetic DNA strands. Process data is first digitized and then encoded into DNA sequences using advanced error-correcting codes and constrained coding schemes tailored for DNA storage channels. These sequences are synthesized into DNA strands that are encapsulated in protective microcapsules or embedded in a stable polymer matrix. The resulting DNA archive, with its inherent durability and data density, serves as a complete, tamper-resistant log of the manufacturing, inspection, and test process. Data retrieval is performed by accessing the microfluidic compartment via a dedicated interface and then sequencing the DNA using miniaturized or external sequencing technology. This method ensures that even if the device is in the field, the full process trace remains physically available and can be used for post-mortem analysis or verification of manufacturing authenticity.

Both embodiments provide a scalable and robust solution for integrating process history directly into the physical chip package. The diamond-based solution leverages high-fidelity optical storage for ultra-durable, non-volatile data retention, while the DNA-based approach offers unparalleled storage density and a secure, molecular-level archive. These technologies not only enhance traceability and quality control but also create a physical record that is intrinsically linked to the device, offering significant advantages in counterfeiting prevention and long-term reliability verification.

In one embodiment, the advanced packaging system incorporates a dedicated thermal-mechanical simulation subsystem that dynamically integrates real-time metrology with physics-based thermal modeling. The subsystem comprises high-resolution digital image correlation (DIC) sensors strategically placed to capture minute surface deformations and 3D X-ray imaging modules that obtain volumetric data from die-to-die interfaces and photonic integration regions. The DIC sensors continuously monitor subtle strain variations across the package surface, while the 3D X-ray system detects internal structural details such as bonding quality and material discontinuities. These metrology outputs are fed into a central simulation engine that employs finite element analysis (FEA) and computational fluid dynamics (CFD) to generate detailed maps of thermal gradients and mechanical stresses across the advanced package.

A dynamic feedback loop then compares the simulated temperature and stress profiles with the real-time metrology data, enabling automatic calibration of simulation parameters such as thermal conductivity, material expansion coefficients, and cooling efficiency factors. This adaptive calibration is achieved using machine learning algorithms that iteratively refine the model based on discrepancies between predicted and measured values. The refined simulation outputs inform an integrated control module that actively adjusts cooling strategies—for example, by modulating micro-channel fluid flow or variable-speed fan settings—and optimizes die-to-die interface configurations. Additionally, the simulation subsystem factors in the impact of photonic integration by incorporating optical loss and wavelength shift parameters as functions of temperature, thereby providing comprehensive guidance to balance thermal management, mechanical integrity, and optical performance in next-generation advanced packaging.

In one embodiment, the chiplet ecosystem management module integrates a standardized interface architecture that explicitly supports both organic interposers and hybrid metal-organic interposer designs. The system employs a multi-sensor array and embedded diagnostic circuitry to continuously monitor interposer parameters—such as line spacing, dielectric constant, and material integrity—and dynamically adjust process parameters in real time. Advanced machine learning algorithms correlate these sensor outputs with simulation models to automatically retarget equipment between different node technologies (e.g., transitioning from 14 nm to 7 nm processes). The retargeting protocol adjusts operational parameters such as voltage, frequency, and cooling profiles based on calibrated interposer characteristics, ensuring that each manufacturing tool is optimized for the specific interposer configuration and target node. This real-time adaptation not only minimizes requalification downtime but also maintains signal integrity and process yield across heterogeneous chiplet designs.

Complementing this, a secure, containerized “app store” framework is incorporated to facilitate third-party module interoperability and ecosystem expansion. Each third-party module is encapsulated within an isolated container (e.g., Docker or OCI-compliant image) and communicates with the central control system via standardized APIs defined in protocols such as REST/JSON or gRPC. The framework includes robust authentication mechanisms—utilizing cryptographic signatures and hardware-based trust enclaves—to ensure that only verified modules are deployed, thereby safeguarding proprietary process data and operational integrity. Furthermore, the system supports dynamic module orchestration using container orchestration platforms (e.g., Kubernetes) to allocate computational resources based on real-time process demands. This modular design allows for plug-and-play integration of specialized functionalities—such as real-time interposer parameter adjustments, automated retargeting routines, and advanced process optimization heuristics-ensuring that the chiplet ecosystem remains agile, scalable, and fully interoperable with emerging industry standards.

In one embodiment, the semiconductor manufacturing control system integrates an advanced, dedicated hardware architecture designed specifically for real-time persistent homology computation. This embodiment is engineered to provide high-performance topological data analysis under the stringent timing and reliability constraints of modern semiconductor fabrication environments. The system architecture is comprised of several key subsystems, each optimized for efficiency, deterministic performance, and robustness in an industrial setting. At the core of the embodiment design is a Dedicated Topology Processing Unit (TPU), implemented as a custom application-specific integrated circuit (ASIC). The TPU features multiple homology computation cores that operate in parallel to accelerate the computation of persistent homology. Each core is equipped with 128 dedicated simplex processing units, enabling simultaneous evaluation of complex simplicial complexes. The TPU operates at a base clock frequency of 2.4 GHz, with dynamic boosting up to 3.8 GHz to meet peak computational demands. To support these high-speed operations, each core includes 256 KB of dedicated L1 cache, while an 8 MB shared L2 cache provides rapid access to commonly used data. The TPU's instruction set is enhanced with hardware-accelerated capabilities specifically tailored for topological computations; for example, it includes SIMD instructions optimized for parallel filtration computation, dedicated instructions for efficient boundary matrix reduction, and specialized hardware modules that accelerate the generation of persistence diagrams.

Complementing the TPU is a multi-level memory hierarchy designed to manage the substantial data throughput required for real-time processing. A high-bandwidth memory subsystem, implemented using HBM2E technology, provides a minimum capacity of 8 GB with bandwidth exceeding 900 GB/s and access latencies below 40 ns. This is augmented by an on-chip persistent homology cache that features a 512 KB dedicated filtration cache and a 256 KB persistence diagram cache, both of which are directly mapped to the TPU cores to minimize data transfer delays. These memory elements are tightly coupled with a zero-copy data path mechanism that ensures sensor data and intermediate computational results are delivered to the TPU with minimal overhead.

The real-time processing pipeline is another critical component of the architecture. At the input stage, the system employs parallel analog-to-digital converter (ADC) interfaces with a minimum resolution of 16 bits, ensuring high-fidelity capture of sensor signals. Hardware-based synchronization circuits guarantee that data streams from various sensors—operating at aggregate throughputs exceeding 10 GB/s—are coherently aligned in time. Downstream, 64 parallel filtration computation engines perform rapid distance function computations and dynamic threshold adjustments to construct the filtration required for persistent homology analysis. A dedicated matrix reduction accelerator then carries out parallel birth-death pair identification, culminating in real-time generation of persistence diagrams that capture the topological features of the manufacturing process in near-real time.

For system integration, the architecture leverages a PCIe Gen 5 interface configured with at least 16 lanes operating at 32 GT/s per lane, coupled with robust direct memory access (DMA) support to enable seamless data exchange with host processors. Internally, a mesh network topology featuring 256-bit wide buses interconnects the TPU cores and memory modules, with built-in Quality-of-Service (QoS) protocols ensuring that real-time deadlines are met even under heavy processing loads.

Recognizing the demanding manufacturing environment, the system incorporates a suite of manufacturing-specific features. Environmental hardening measures extend the operating temperature range from 0° C. to 85° C. and include comprehensive EMI shielding to mitigate interference in the factory floor setting. Redundant processing paths and hot-swappable components enhance fault tolerance, ensuring continuous operation even if individual modules encounter errors. The design guarantees deterministic computation with a maximum latency of 500 μs for a complete homology computation cycle, sustaining a throughput of over one million simplices per second, and is backed by hardware-assisted deadline monitoring and priority-based scheduling.

Algorithmic optimizations are further integrated into the hardware. For example, the system supports approximate persistence computation through a hardware-accelerated matrix reduction process that dynamically adapts precision—using configurable floating-point to fixed-point conversion—based on real-time manufacturing tolerances. This is illustrated by an optimized computation routine that performs sparse boundary matrix construction, iterative column reduction, and extraction of persistence pairs in parallel across the TPU cores.

Computational efficiency is enhanced through a multi-level parallelization strategy, with dynamic load balancing across TPU cores and hardware-assisted task scheduling that minimizes idle time. Memory management techniques such as predictive data prefetching and an optimized cache coherency protocol tailored for topological computations further ensure that sensor data flows uninterrupted from acquisition to analysis. To provide quality of service, the system supports multiple service levels that allow dynamic resource allocation based on the criticality of the manufacturing process being monitored, guaranteeing a minimum computation throughput under all operational conditions.

Finally, the architecture includes comprehensive built-in monitoring and diagnostic features. Hardware counters continuously measure key performance metrics such as computation time per filtration, cache hit/miss rates, and memory bandwidth utilization. In parallel, quality metrics such as the accuracy of persistence diagrams and the consistency of computation timing are monitored in real time. A robust system health monitoring module provides built-in self-test capabilities, error detection and correction, and thermal management, while automatic failover mechanisms and redundant processing paths ensure that any detected fault does not compromise overall system performance.

This ultra-detailed hardware architecture for real-time persistent homology computation thus balances the immense computational demands of advanced topological data analysis with the stringent real-time processing and reliability requirements of semiconductor manufacturing control. The design not only delivers exceptional performance through specialized ASIC implementations and high-speed memory architectures but also ensures deterministic, fault-tolerant operation in harsh manufacturing environments, making it a transformative tool for next-generation semiconductor process optimization.

### Exemplary Computing Environment

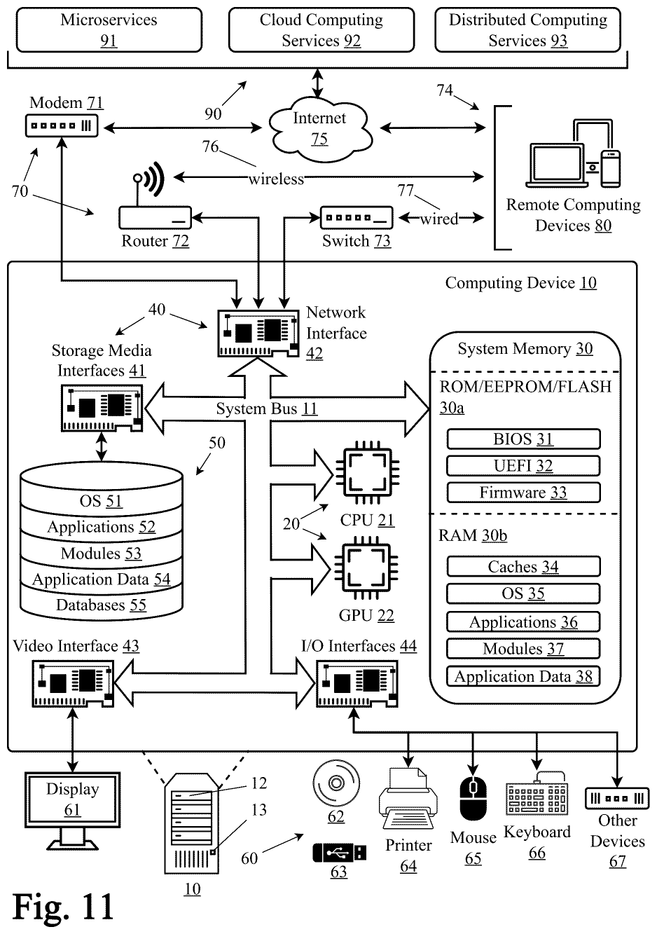

FIG. 11 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe (Non-Volatile Memory Express), and PCIe. SATA is the traditional interface for HDDs and SATA SSDs, while NVMe is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A semiconductor manufacturing control system comprising:
a plurality of sensors configured to collect multi-modal process data according to a dynamic measurement strategy;
a processor configured to:
maintain a state model using particle-based estimation from the multi-modal process data;
generate topology-aware features from the state model;
maintain a knowledge graph integrating process relationships and economic factors;
implement an upper confidence tree (UCT) optimization algorithm with super-exponential regret bounds; and
generate real-time control signals based on the optimization algorithm
a controller configured to adaptively adjust semiconductor manufacturing equipment based on the control signals.

2. The system of claim 1, wherein generating the topology-aware features from the state model comprises computing persistent homology at a plurality of scales and performing the feature matching with a confidence scoring to enable a hierarchical feature fusion.

3. The system of claim 1, wherein the UCT optimization algorithm adjusts a plurality of exploration factors dynamically while controlling a tree width progression based on a plurality of risk-weighted value calculations.

4. The system of claim 1, wherein the knowledge graph enables a vector similarity search and a graph traversal through a plurality of hybrid retrieval strategies.

5. The system of claim 1, wherein the dynamic measurement strategy comprises just-in-context measurements, just-in-time measurements, and just-in-place measurements for process control.

6. The system of claim 1, wherein the economic factors comprise a wafer value, a plurality of energy costs, and a plurality of maintenance costs integrated into the UCT optimization algorithm.

7. The system of claim 1, wherein the multi-modal process data comprises a plurality of thermal measurements, a plurality of position measurements, and a plurality of optical measurements collected during operation of the semiconductor manufacturing equipment.

8. A method for controlling semiconductor manufacturing equipment, the method comprising:
collecting multi-modal process data according to a dynamic measurement strategy using a plurality of sensors;
maintaining a state model using particle-based estimation from the multi-modal process data;
generating topology-aware features from the state model;
maintaining a knowledge graph integrating process relationships and economic factors;
implementing an upper confidence tree (UCT) optimization algorithm with super-exponential regret bounds;
generating real-time control signals based on the optimization algorithm; and
adaptively adjusting the semiconductor manufacturing equipment based on the control signals.

9. The method of claim 8, wherein generating the topology-aware features from the state model comprises computing persistent homology at a plurality of scales and performing the feature matching with a confidence scoring to enable a hierarchical feature fusion.

10. The method of claim 8, wherein implementing the UCT optimization algorithm comprises adjusting a plurality of exploration factors dynamically while controlling a tree width progression based on a plurality of risk-weighted value calculations.

11. The method of claim 8, wherein maintaining the knowledge graph comprises enabling a vector similarity search and a graph traversal through a plurality of hybrid retrieval strategies.

12. The method of claim 8, wherein the dynamic measurement strategy comprises just-in-context measurements, just-in-time measurements, and just-in-place measurements for process control.

13. The method of claim 8, wherein the economic factors comprise a wafer value, a plurality of energy costs, and a plurality of maintenance costs integrated into the UCT optimization algorithm.

14. The method of claim 8, wherein the multi-modal process data comprises a plurality of thermal measurements, a plurality of position measurements, and a plurality of optical measurements collected during operation of the semiconductor manufacturing equipment.

15. A method for automated equipment retargeting in semiconductor manufacturing, comprising:
collecting multi-modal sensor data through a dynamic measurement strategy that includes just-in-context, just-in-time, and just-in-place data acquisition;
accessing a knowledge graph storing node-specific calibration profiles and process parameters for multiple technology nodes;
executing an advanced scheduling algorithm to determine an optimal requalification window and retarget equipment from a first technology node to a second technology node;
loading partial calibration vectors and reference recipes retrieved from the knowledge graph corresponding to the second technology node;
employing a particle-based state estimation subsystem that tracks multi-hypothesis tool states during the transition, adaptively resampling to converge on new process parameters;
applying an upper confidence tree (UCT) optimization engine with super-exponential regret bounds to balance exploration of recalibration actions and exploitation of historical best-known methods; and
generating real-time control signals to finalize the retargeting and initiate high-volume production at the second technology node, wherein the re-ramp time is reduced compared to traditional node transition processes.

16. The method of claim 15, further comprising:
integrating economic factors in an economic analysis processor to decide whether an accelerated or gradual re-ramp is warranted based on wafer value, demand forecasts, energy costs, and maintenance considerations.
